(19) United States
(12) Patent Application Publication
(10) Pub. No.: US 2025/0287648 A1
(43) Pub. Date: Sep. 11, 2025

(54) SEMICONDUCTOR DEVICE, MEMORY DEVICE, AND ELECTRONIC DEVICE

(71) Applicant: Semiconductor Energy Laboratory Co., Ltd., Atsugi-shi, Kanagawa-ken (JP)

(72) Inventors: Tatsunori INOUE, Yamato (JP); Hiroki INOUE, Atsugi (JP)

(21) Appl. No.: 18/863,022

(22) PCT Filed: May 2, 2023
(86) PCT No.: PCT/IB2023/054529

§ 371 Date: Nov. 5, 2024

(30) Foreign Application Priority Data
May 16, 2022 (JP) 2022-080414
Jun. 29, 2022 (JP) 2022-104506
Sep. 26, 2022 (JP) 2022-152927

(51) Int. Cl. H10D 30/67; G11C 5/06; H10B 12/00

(52) U.S. Cl. CPC H10D 30/6755; G11C 5/063; H10B 12/50; H10D 30/6734; H10B 12/09

(57) ABSTRACT

A semiconductor device with a high memory density is used. The semiconductor device includes a first layer and a first insulator. The first layer includes a first oxide semiconductor, first to ninth conductors and second to fifth insulators. The first layer is located over the first insulator. The first oxide semiconductor is located above the first insulator. The first and sixth conductors are each located on a top surface and a side surface of the first oxide semiconductor and a top surface of the first insulator. The second and fourth conductors are each located on the top surface of the first oxide semiconductor. The second insulator and the third conductor are located between the first conductor and the second conductor, and the third insulator and the fifth conductor are located between the second conductor and the fourth conductor. The fourth insulator and the seventh conductor are located between the fourth conductor and the sixth conductor. The fifth insulator and the eighth conductor are located over the first conductor in a region that does not overlap with the first oxide. The ninth conductor is located over the second conductor.

### TECHNICAL FIELD

One embodiment of the present invention relates to a semiconductor device, a storage device, and an electronic device.

Note that one embodiment of the present invention is not limited to the above technical field. The technical field of the invention disclosed in this specification and the like relates to an object, an operation method, or a manufacturing method. Alternatively, one embodiment of the present invention relates to a process, a machine, manufacture, or a composition of matter. Therefore, specific examples of the technical field of one embodiment of the present invention disclosed in this specification include a semiconductor device, a display apparatus (including a liquid crystal display apparatus), a light-emitting apparatus, a power storage device, an imaging device, a memory device, a signal processing device, a sensor, a processor, an electronic device, a system, a driving method thereof, a manufacturing method thereof, and a testing method thereof.

### BACKGROUND ART

In recent years, the amount of data subjected to processing has been increasing, which makes a demand for a memory device having a higher memory capacity. To increase memory capacity per unit area, stacking memory cells as in the case of a 3D NAND memory device or the like is effective (see Patent Document 1 to Patent Document 3). Stacking memory cells can increase memory capacity per unit area in accordance with the number of stacked memory cells.

### REFERENCE

### Patent Document

[Patent Document 1] United States Patent Application Publication No. 2011/0065270
[Patent Document 2] United States Patent Application Publication No. 2016/0149004
[Patent Document 3] United States Patent Application Publication No. 2013/0069052

### SUMMARY OF THE INVENTION

### Problems to be Solved by the Invention

An object of one embodiment of the present invention is to provide a semiconductor device with high memory capacity. Another object of one embodiment of the present invention is to provide a semiconductor device having high memory density. Another object of one embodiment of the present invention is to provide a novel semiconductor device. Another object of one embodiment of the present invention is to provide a novel memory device including the above semiconductor device. Another object of one embodiment of the present invention is to provide a novel electronic device including the above memory device.

Note that the objects of one embodiment of the present invention are not limited to the above objects. The above objects do not preclude the presence of other objects. Note that the other objects are objects that are not described in this section and are described below. The objects that are not described in this section are derived from the description of the specification, the drawings, and the like and can be extracted as appropriate from the description by those skilled in the art. Note that one embodiment of the present invention is to achieve at least one of the above objects and the other objects. Note that one embodiment of the present invention does not necessarily achieve all of the above objects and the other objects.

### Means for Solving the Problems

(1)

One embodiment of the present invention is a semiconductor device including a first layer and a first insulator. The first layer includes a first oxide semiconductor, a first conductor, a second conductor, a third conductor, a fourth conductor, a fifth conductor, a sixth conductor, a seventh conductor, an eighth conductor, a ninth conductor, a second insulator, a third insulator, a fourth insulator, and a fifth insulator.

The first layer is located over the first insulator. The first oxide semiconductor is located above the first insulator. The first conductor is located on a top surface and a side surface of the first oxide semiconductor and a top surface of the first insulator, and the second conductor is located on the top surface of the first oxide semiconductor. The second insulator is located between the first conductor and the second conductor and on the top surface of the first oxide semiconductor in a cross-sectional view, and the third conductor is located on a top surface of the second insulator. The fourth conductor is located on the top surface of the first oxide semiconductor. The third insulator is located between the second conductor and the fourth conductor and on the top surface of the first oxide semiconductor in the cross-sectional view, and the fifth conductor is located on a top surface of the third insulator. The sixth conductor is located on the top surface and the side surface of the first oxide semiconductor and the top surface of the first insulator. In addition, the fourth insulator is located between the fourth conductor and the sixth conductor and on the top surface of the first oxide semiconductor in the cross-sectional view, and the seventh conductor is located on a top surface of the fourth insulator. The fifth insulator is located over the first conductor in a region that overlaps with the first insulator and does not overlap with the first oxide semiconductor, and the eighth conductor is located over the fifth insulator. The ninth conductor is located over the second conductor.

(2)

Another embodiment of the present invention may have a structure in which the first layer includes a second oxide semiconductor, a tenth conductor, an eleventh conductor, a twelfth conductor, a thirteenth conductor, and a sixth insulator in the above (1). Preferably, the second oxide semiconductor is located above the first insulator, the tenth conductor is located on a top surface and a side surface of the second oxide semiconductor and the top surface of the first insulator, and the eleventh conductor is located on the top surface of the second oxide semiconductor. Preferably, the sixth insulator is located between the tenth conductor and the eleventh conductor and on the top surface of the second oxide semiconductor in the cross-sectional view, and the twelfth conductor is located over the sixth insulator. The thirteenth conductor is preferably located over the first conductor and the twelfth conductor.

(3)

Another embodiment of the present invention may have a structure in which a second layer and a seventh insulator are included in the above (2). In particular, the second layer preferably includes a third oxide semiconductor, a fourteenth conductor, a seventh insulator, and an eighth insulator. Preferably, the seventh insulator is located over the first layer, and the second layer is located over the seventh insulator. Preferably, the third oxide semiconductor includes a region overlapping with the eighth conductor and the thirteenth conductor, the eighth insulator overlaps with the eighth conductor and is located on a top surface of the third oxide semiconductor, and the fourteenth conductor is located over the eighth insulator.

(4)

Another embodiment of the present invention may have a structure in which the first oxide semiconductor, the second oxide semiconductor, and the third oxide semiconductor each include one or more selected from indium, zinc, and an element Min the above (3).

Note that the element M is one or more selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, cobalt, magnesium, and antimony.

(5)

Another embodiment of the present invention is a memory device including the semiconductor device according to any one of the above (1) to (4) and a driver circuit. The first insulator is located above the driver circuit.

(6)

Another embodiment of the present invention is an electronic device including the memory device according to the above (5) and a housing.

(7)

Another embodiment of the present invention is a semiconductor device including a first layer, a second layer, a first insulator, a second insulator, and a first conductor. In addition, each of the first layer and the second layer includes a first oxide semiconductor, a second conductor, a third conductor, a fourth conductor, a fifth conductor, a sixth conductor, a seventh conductor, an eighth conductor, a ninth conductor, a tenth conductor, a fourth insulator, a fifth insulator, a sixth insulator, and a seventh insulator. The first layer is located over the first insulator, the second insulator is located over the first layer, and the second layer is located over the second insulator.

In each of the first layer and the second layer, the second conductor is located on a top surface and a side surface of the first oxide semiconductor and in a region not overlapping with the first oxide semiconductor, and the third conductor is located on the top surface of the first oxide semiconductor. The fourth insulator is located between the second conductor and the third conductor and on the top surface of the first oxide semiconductor in a cross-sectional view, and the fourth conductor is located on a top surface of the fourth insulator. The fifth conductor is located on the top surface of the first oxide semiconductor, the fifth insulator is located between the third conductor and the fifth conductor and on the top surface of the first oxide semiconductor in the cross-sectional view, and the sixth conductor is located on a top surface of the fifth insulator. The seventh conductor is located on the top surface and the side surface of the first oxide semiconductor and in a region not overlapping with the first oxide semiconductor, the sixth insulator is located between the fifth conductor and the seventh conductor and on the top surface of the first oxide semiconductor in the cross-sectional view, and the eighth conductor is located on a top surface of the sixth insulator. The seventh insulator is located in a region of the top surface of the seventh conductor that does not overlap with the first oxide semiconductor, the ninth conductor is located on a top surface of the seventh insulator; and the tenth conductor is located on a top surface of the fifth conductor.

The second insulator includes an opening, and the first conductor is located in the opening. The first conductor is located on a top surface of the fourth conductor in the first layer, and a part of the seventh conductor in the second layer is located on a top surface of the first conductor.

(8)

Another embodiment of the present invention is a semiconductor device including a first layer, a second layer, a third layer, a first insulator, a second insulator, a third insulator, and a first conductor. In addition, each of the first layer, the second layer, and the third layer includes a first oxide semiconductor, a second conductor, a third conductor, a fourth conductor, a fifth conductor, a sixth conductor, a seventh conductor, an eighth conductor, a ninth conductor, a tenth conductor, a fourth insulator, a fifth insulator, a sixth insulator, and a seventh insulator. The first layer is located over the first insulator. The second insulator is located over the first layer, the second layer is located over the second insulator, the third insulator is located over the second layer, and the third layer is located over the third insulator.

In each of the first layer, the second layer, and the third layer, the second conductor is located on a top surface and a side surface of the first oxide semiconductor and in a region not overlapping with the first oxide semiconductor, and the third conductor is located on the top surface of the first oxide semiconductor. The fourth insulator is located between the second conductor and the third conductor and on the top surface of the first oxide semiconductor in a cross-sectional view, and the fourth conductor is located on a top surface of the fourth insulator. The fifth conductor is located on the top surface of the first oxide semiconductor, the fifth insulator is located between the third conductor and the fifth conductor and on the top surface of the first oxide semiconductor in the cross-sectional view, and the sixth conductor is located on a top surface of the fifth insulator. The seventh conductor is located on the top surface and the side surface of the first oxide semiconductor and in a region not overlapping with the first oxide semiconductor, the sixth insulator is located between the fifth conductor and the seventh conductor and on the top surface of the first oxide semiconductor in the cross-sectional view, and the eighth conductor is located on a top surface of the sixth insulator. The seventh insulator is located in a region of the top surface of the seventh conductor that does not overlap with the first oxide semiconductor, the ninth conductor is located on a top surface of the seventh insulator, and the tenth conductor is located on a top surface of the fifth conductor.

The second insulator includes an opening, and the first conductor is located in the opening. The first conductor is located on a top surface of the fourth conductor in the first layer, and a part of the seventh conductor in the second layer is located on a top surface of the first conductor. The ninth conductor in the second layer is located in a region overlapping with the eighth conductor in the third layer.

(9)

Another embodiment of the present invention is a semiconductor device including a first layer, a second layer, a first insulator, a second insulator, and a first conductor, which has a different structure from that of the above (7). In addition, each of the first layer and the second layer includes a first oxide semiconductor, a second conductor, a third conductor, a fourth conductor, a fifth conductor, a sixth conductor, a seventh conductor, an eighth conductor, a ninth conductor, a tenth conductor, a fourth insulator, a fifth insulator, a sixth insulator, and a seventh insulator. The first layer is located over the first insulator, the second insulator is located over the first layer, and the second layer is located over the second insulator.

In each of the first layer and the second layer, the second conductor is located on a top surface and a side surface of the first oxide semiconductor and in a region not overlapping with the first oxide semiconductor, and the third conductor is located on the top surface of the first oxide semiconductor. The fourth insulator is located between the second conductor and the third conductor and on the top surface of the first oxide semiconductor in a cross-sectional view, the fourth conductor is located on a top surface of the fourth insulator, the fifth conductor is located on the top surface of the first oxide semiconductor, the fifth insulator is located between the third conductor and the fifth conductor and on the top surface of the first oxide semiconductor in the cross-sectional view, and the sixth conductor is located on a top surface of the fifth insulator. The seventh conductor is located on the top surface and the side surface of the first oxide semiconductor and in a region not overlapping with the first oxide semiconductor, the sixth insulator is located between the fifth conductor and the seventh conductor and on the top surface of the first oxide semiconductor in the cross-sectional view, and the eighth conductor is located on a top surface of the sixth insulator. The seventh insulator is located in a region of the top surface of the seventh conductor that does not overlap with the first oxide semiconductor, the ninth conductor is located on a top surface of the seventh insulator, and the tenth conductor is located on a top surface of the fifth conductor.

The second insulator includes an opening, and the first conductor is located in the opening. The first conductor is located on a top surface of the sixth conductor in the first layer, and a part of the seventh conductor in the second layer is located on a top surface of the first conductor.

(10)

Another embodiment of the present invention is a semiconductor device including a first layer, a second layer, a third layer, a first insulator, a second insulator, a third insulator, and a first conductor, which has a different structure from that of the above (8). In addition, each of the first layer, the second layer, and the third layer includes a first oxide semiconductor, a second conductor, a third conductor, a fourth conductor, a fifth conductor, a sixth conductor, a seventh conductor, an eighth conductor, a ninth conductor, a tenth conductor, a fourth insulator, a fifth insulator, a sixth insulator, and a seventh insulator. The first layer is located over the first insulator, the second insulator is located over the first layer, the second layer is located over the second insulator, the third insulator is located over the second layer, and the third layer is located over the third insulator,

In each of the first layer, the second layer, and the third layer, the second conductor is located on a top surface and a side surface of the first oxide semiconductor and in a region not overlapping with the first oxide semiconductor, and the third conductor is located on the top surface of the first oxide semiconductor. The fourth insulator is located between the second conductor and the third conductor and on the top surface of the first oxide semiconductor in a cross-sectional view, and the fourth conductor is located on a top surface of the fourth insulator. The fifth conductor is located on the top surface of the first oxide semiconductor, the fifth insulator is located between the third conductor and the fifth conductor and on the top surface of the first oxide semiconductor in the cross-sectional view, and the sixth conductor is located on a top surface of the fifth insulator. The seventh conductor is located on the top surface and the side surface of the first oxide semiconductor and in a region not overlapping with the first oxide semiconductor, the sixth insulator is located between the fifth conductor and the seventh conductor and on the top surface of the first oxide semiconductor in the cross-sectional view, and the eighth conductor is located on a top surface of the sixth insulator. The seventh insulator is located in a region of the top surface of the seventh conductor that does not overlap with the first oxide semiconductor, the ninth conductor is located on a top surface of the seventh insulator, and the tenth conductor is located on a top surface of the fifth conductor.

The second insulator includes an opening, and the first conductor is located in the opening. The first conductor is located on a top surface of the sixth conductor in the first layer, and a part of the seventh conductor in the second layer is located on a top surface of the first conductor. In addition, the ninth conductor in the second layer is located in a region overlapping with the eighth conductor in the third layer.

(11)

Another embodiment of the present invention may have a structure in which the first oxide semiconductor includes one or more selected from indium, zinc, and an element M in any one of the above (7) to (10).

Note that the element M is one or more selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, cobalt, magnesium, and antimony.

(12)

Another embodiment of the present invention is a memory device including the semiconductor device according to the above (11) and a driver circuit. The first insulator is located above the driver circuit.

(13)

Another embodiment of the present invention is an electronic device including the memory device according to the above (12) and a housing.

### Effect of the Invention

According to one embodiment of the present invention, a semiconductor device with high memory capacity can be provided. Another embodiment of the present invention can provide a semiconductor device having high memory density. According to another embodiment of the present invention, a novel semiconductor device can be provided. According to another embodiment of the present invention, a novel memory device including the above semiconductor device can be provided. According to another embodiment of the present invention, a novel electronic device including the above memory device can be provided.

Note that the effects of one embodiment of the present invention are not limited to the effects listed above. The effects described above do not preclude the presence of other effects. The other effects are effects that are not described in this section and will be described below. The effects that are not described in this section can be derived from the description of the specification, the drawings, and the like and can be extracted as appropriate from the description by those skilled in the art. One embodiment of the present invention has at least one of the above effects and the other effects. Accordingly, one embodiment of the present invention does not have the above effects in some cases.

### BRIEF DESCRIPTION OF THE DRAWINGS

FIG. 1 is a circuit diagram illustrating a structure example of a semiconductor device.

FIG. 2 is a schematic cross-sectional view illustrating a structure example of a semiconductor device.

FIG. 3 is a schematic cross-sectional view illustrating a structure example of a semiconductor device.

FIG. 4 is a schematic perspective view illustrating a structure example of a semiconductor device.

FIG. 5 is a schematic cross-sectional view illustrating a structure example of a semiconductor device.

FIG. 6 is a schematic perspective view illustrating a structure example of a semiconductor device.

FIG. 7 is a layout view illustrating a structure example of a semiconductor device.

FIG. 8A is a schematic plan view illustrating a structure example of a semiconductor device, and FIG. 8B to FIG. 8D are schematic cross-sectional views illustrating the structure example of the semiconductor device.

FIG. 9A is a schematic plan view illustrating an example of a method for manufacturing a semiconductor device, and FIG. 9B to FIG. 9D are schematic cross-sectional views illustrating the example of the method for manufacturing the semiconductor device.

FIG. 10A is a schematic plan view illustrating an example of a method for manufacturing a semiconductor device, and FIG. 10B to FIG. 10D are schematic cross-sectional views illustrating the example of the method for manufacturing the semiconductor device.

FIG. 11A is a schematic plan view illustrating an example of a method for manufacturing a semiconductor device, and FIG. 11B to FIG. 11D are schematic cross-sectional views illustrating the example of the method for manufacturing the semiconductor device.

FIG. 12A is a schematic plan view illustrating an example of a method for manufacturing a semiconductor device, and FIG. 12B to FIG. 12D are schematic cross-sectional views illustrating the example of the method for manufacturing the semiconductor device.

FIG. 13A is a schematic plan view illustrating an example of a method for manufacturing a semiconductor device, and FIG. 13B to FIG. 13D are schematic cross-sectional views illustrating the example of the method for manufacturing the semiconductor device.

FIG. 14A is a schematic plan view illustrating an example of a method for manufacturing a semiconductor device, and FIG. 14B to FIG. 14D are schematic cross-sectional views illustrating the example of the method for manufacturing the semiconductor device.

FIG. 15A is a schematic plan view illustrating an example of a method for manufacturing a semiconductor device, and FIG. 15B to FIG. 15D are schematic cross-sectional views illustrating the example of the method for manufacturing the semiconductor device.

FIG. 16A is a schematic plan view illustrating an example of a method for manufacturing a semiconductor device, and FIG. 16B to FIG. 16D are schematic cross-sectional views illustrating the example of the method for manufacturing the semiconductor device.

FIG. 17A is a schematic plan view illustrating an example of a method for manufacturing a semiconductor device, and FIG. 17B to FIG. 17D are schematic cross-sectional views illustrating the example of the method for manufacturing the semiconductor device.

FIG. 18A is a schematic plan view illustrating an example of a method for manufacturing a semiconductor device, and FIG. 18B to FIG. 18D are schematic cross-sectional views illustrating the example of the method for manufacturing the semiconductor device.

FIG. 19A is a schematic plan view illustrating an example of a method for manufacturing a semiconductor device, and FIG. 19B to FIG. 19D are schematic cross-sectional views illustrating the example of the method for manufacturing the semiconductor device.

FIG. 20A is a schematic plan view illustrating an example of a method for manufacturing a semiconductor device, and FIG. 20B to FIG. 20D are schematic cross-sectional views illustrating the example of the method for manufacturing the semiconductor device.

FIG. 21A is a schematic plan view illustrating an example of a method for manufacturing a semiconductor device, and FIG. 21B to FIG. 21D are schematic cross-sectional views illustrating the example of the method for manufacturing the semiconductor device.

FIG. 22A is a schematic plan view illustrating an example of a method for manufacturing a semiconductor device, and FIG. 22B to FIG. 22D are schematic cross-sectional views illustrating the example of the method for manufacturing the semiconductor device.

FIG. 23 is a circuit diagram illustrating a structure example of a semiconductor device.

FIG. 24 is a schematic cross-sectional view illustrating a structure example of a semiconductor device.

FIG. 25 is a schematic cross-sectional view illustrating a structure example of a semiconductor device.

FIG. 26 is a schematic perspective view illustrating a structure example of a semiconductor device.

FIG. 27 is a schematic cross-sectional view illustrating a structure example of a semiconductor device.

FIG. 28 is a schematic cross-sectional view illustrating a structure example of a semiconductor device.

FIG. 29A and FIG. 29B are schematic cross-sectional views illustrating an example of a method for manufacturing a semiconductor device.

FIG. 30A and FIG. 30B are schematic cross-sectional views illustrating an example of a method for manufacturing a semiconductor device.

FIG. 31 is a schematic cross-sectional view illustrating an example of a method for manufacturing a semiconductor device.

FIG. 32A is a perspective view illustrating a structure example of a memory device, and FIG. 32B is a block diagram illustrating a structure example of a semiconductor device.

FIG. 33 is a block diagram illustrating a structure example of a memory device.

FIG. 34 is a schematic cross-sectional view illustrating a structure example of a memory device.

FIG. 35A to FIG. 35B are diagrams illustrating examples of electronic components.

FIG. 36A and FIG. 36B are diagrams illustrating examples of electronic devices, and FIG. 36C to FIG. 36E are diagrams illustrating an example of a large computer.

FIG. 37 is a diagram illustrating an example of space equipment.

FIG. 38 is a diagram illustrating an example of a storage system that can be used in a data center.

FIG. 39A is a graph showing source-drain withstand voltage characteristics of transistors, and FIG. 39B is a graph showing gate withstand voltage characteristics of the transistors.

FIG. 40 is a circuit diagram illustrating a memory cell in Example.

FIG. 41 is a circuit diagram illustrating a memory device in Example.

FIG. 42 is a timing chart showing an operation example of a memory device in Example.

FIG. 43 is a top view photograph of a memory die including a memory device.

FIG. 44A is a graph showing a relation between a voltage written to a memory device and a voltage read from the memory device. FIG. 44B is a graph showing a relation between a voltage written to a memory device and a value three times the standard deviation 6 at a voltage read from the memory device.

FIG. 45A and FIG. 45B are schematic diagrams of the threshold voltage distribution of write voltages to a memory device.

FIG. 46A is a graph showing variations in read voltages over retention time in a memory device to which voltages are written, and FIG. 46B is a graph showing a relation between initial read voltages and a variation in read voltages after a certain period of time, in the memory device to which voltages are written.

FIG. 47A and FIG. 47B are schematic diagrams of the threshold voltage distribution of write voltages to a memory device.

### MODE FOR CARRYING OUT THE INVENTION

In this specification and the like, a semiconductor device refers to a device that utilizes semiconductor characteristics, and means a circuit including a semiconductor element (e.g., a transistor, a diode, and a photodiode), or a device including the circuit. The semiconductor device also means all devices that can function by utilizing semiconductor characteristics. For example, an integrated circuit, a chip including an integrated circuit, and an electronic component including a chip in a package are each an example of the semiconductor device. Moreover, a memory device, a display apparatus, a light-emitting apparatus, a lighting device, an electronic device, and the like themselves are semiconductor devices in some cases and include semiconductor devices in other cases.

In the case where there is description “X and Y are connected” in this specification and the like, the case where X and Y are electrically connected, the case where X and Y are functionally connected, and the case where X and Y are directly connected are regarded as being disclosed in this specification and the like. Accordingly, without being limited to a predetermined connection relation, for example, a connection relation shown in drawings or texts, a connection relation other than one shown in drawings or texts is regarded as being disclosed in the drawings or the texts. Each of X and Y denotes an object (e.g., a device, an element, a circuit, a wiring, an electrode, a terminal, a conductive film, or a layer).

For example, in the case where X and Y are electrically connected, one or more elements that allow electrical connection between X and Y (e.g., a switch, a transistor, a capacitor, an inductor, a resistor, a diode, a display device, a light-emitting device, and a load) can be connected between X and Y. Note that a switch has a function of being controlled to be turned on or off. That is, the switch has a function of being in a conducting state (on state) or a non-conducting state (off state) to control whether current flows or not.

In the case where an element and a power supply line (e.g., a wiring supplying VDD (high power supply potential), VSS (low power supply potential), GND (the ground potential), or a desired potential) are both provided between X and Y, X and Y are not defined as being electrically connected. In the case where only a power supply line is provided between X and Y, there is no element between X and Y; therefore, X and Y are directly connected. Accordingly, in the case where only a power supply line is provided between X and Y, X and Y can be expressed as being “electrically connected”. However, in the case where an element and a power supply line are both provided between X and Y, X and Y are not defined as being electrically connected, although X and the power supply line are electrically connected (through the element) and Y and the power supply line are electrically connected. Note that in the case where a gate and a source of a transistor are provided between X and Y, X and Y are not defined as being electrically connected. Note that in the case where a gate and a drain of a transistor are provided between X and Y, X and Y are not defined as being electrically connected. That is, in the case where a drain and a source of a transistor are provided between X and Y, X and Y are defined as being electrically connected. Note that in the case where a capacitor is provided between X and Y, X and Y are defined as being electrically connected in some cases and not defined in other cases. For example, in the case where a capacitor is provided between X and Y in a structure of a digital circuit or a logic circuit, X and Y are not defined as being electrically connected in some cases. On the other hand, for example, in the case where a capacitor is provided between X and Y in a structure of an analog circuit, X and Y are defined as being electrically connected in some cases.

For example, in the case where X and Y are functionally connected, one or more circuits that allow functional connection between X and Y (e.g., a logic circuit (e.g., an inverter, a NAND circuit, or a NOR circuit); a signal converter circuit (e.g., a digital-analog converter circuit, an analog-digital converter circuit, or a gamma correction circuit); a potential level converter circuit (e.g., a power supply circuit such as a step-up circuit or a step-down circuit, or a level shifter circuit for changing the potential level of a signal); a voltage source; a current source; a switching circuit; an amplifier circuit (e.g., a circuit that can increase signal amplitude, the amount of a current, or the like, an operational amplifier, a differential amplifier circuit, a source follower circuit, or a buffer circuit); a signal generation circuit; a memory circuit; or a control circuit) can be connected between X and Y. For instance, even if another circuit is provided between X and Y, X and Y are regarded as being functionally connected when a signal output from X is transmitted to Y.

Note that an explicit description “X and Y are electrically connected” includes the case where X and Y are electrically connected (i.e., the case where X and Y are connected with another element or another circuit provided therebetween) and the case where X and Y are directly connected (i.e., the case where X and Y are connected without another element or another circuit provided therebetween).

For example, an expression “X, Y, a source (sometimes called one of a first terminal and a second terminal) of a transistor, and a drain (sometimes called the other of the first terminal and the second terminal) of the transistor are electrically connected to each other, and X, the source of the transistor, the drain of the transistor, and Y are electrically connected to each other in this order” can be used. Alternatively, an expression “a source of a transistor is electrically connected to X; a drain of the transistor is electrically connected to Y; and X, the source of the transistor, the drain of the transistor, and Y are electrically connected to each other in this order” can be used. Alternatively, the expression “X is electrically connected to Y through a source and a drain of a transistor, and X, the source of the transistor, the drain of the transistor, and Y are provided in this connection order” can be used. When the connection order in a circuit structure is defined by an expression like the above examples, a source and a drain of a transistor can be distinguished from each other to specify the technical scope. Note that these expressions are non-limiting examples. Here, X and Y each denote an object (e.g., a device, an element, a circuit, a wiring, an electrode, a terminal, a conductive film, or a layer).

Even when independent components are electrically connected to each other in a circuit diagram, one component has functions of a plurality of components in some cases. For example, when part of a wiring also functions as an electrode, one conductive film has both functions of a wiring and an electrode. Thus, electrical connection in this specification includes, in its category, such a case where one conductive film has functions of a plurality of components.

In this specification and the like, a “resistor” can be, for example, a circuit element having a resistance value higher than 0Ω or a wiring having a resistance value higher than 0Ω. Therefore, in this specification and the like, a “resistor” includes a wiring having a resistance value, a transistor in which a current flows between a source and a drain, a diode, and a coil. Thus, the term “resistor” can sometimes be replaced with the terms “resistance”, “load”, or “region having a resistance value”. Conversely, the terms “resistance”, “load”, or “region having a resistance value” can sometimes be replaced with the term “resistor”. The resistance value can be, for example, preferably higher than or equal to 1 mΩ and lower than or equal to 10Ω, further preferably higher than or equal to 5 mΩ and lower than or equal to 5Ω, still further preferably higher than or equal to 10 mΩ and lower than or equal to 1Ω. For another example, the resistance value may be higher than or equal to 1Ω and lower than or equal to 1×10⁹Ω.

In this specification and the like, a “capacitor” can be, for example, a circuit element having an electrostatic capacitance value higher than 0 F, a region of a wiring having an electrostatic capacitance value higher than 0 F, parasitic capacitance, or gate capacitance of a transistor. The term “capacitor”, “parasitic capacitance”, or “gate capacitance” can be replaced with the term “capacitance” in some cases. Conversely, the term “capacitance” can be replaced with the term “capacitor”, “parasitic capacitance”, or “gate capacitance” in some cases. In addition, a “capacitor” (including a “capacitor” with three or more terminals) includes an insulator and a pair of conductors between which the insulator is interposed. Thus, the term “pair of conductors” of “capacitor” can be replaced with “pair of electrodes”, “pair of conductive regions”, “pair of regions”, or “pair of terminals”. In addition, the terms “one of a pair of terminals” and “the other of the pair of terminals” are referred to as a first terminal and a second terminal, respectively, in some cases. Note that the electrostatic capacitance value can be higher than or equal to 0.05 fF and lower than or equal to 10 pF, for example. For another example, the electrostatic capacitance value may be higher than or equal to 1 pF and lower than or equal to 10 μF.

In this specification and the like, a transistor includes three terminals called a gate, a source, and a drain. The gate is a control terminal for controlling the conduction state of the transistor. Two terminals functioning as the source and the drain are input/output terminals of the transistor. One of the two input/output terminals serves as the source and the other serves as the drain on the basis of the conductivity type (n-channel type or p-channel type) of the transistor and the levels of potentials applied to the three terminals of the transistor. Thus, the terms “source” and “drain” can sometimes be replaced with each other in this specification and the like. In this specification and the like, expressions “one of a source and a drain” (or a first electrode or a first terminal) and “the other of the source and the drain” (or a second electrode or a second terminal) are used in description of the connection relation of a transistor. Depending on the transistor structure, a transistor may include a back gate in addition to the above three terminals. In that case, in this specification and the like, one of the gate and the back gate of the transistor may be referred to as a first gate and the other of the gate and the back gate of the transistor may be referred to as a second gate. Moreover, the terms “gate” and “back gate” can be replaced with each other in one transistor in some cases. In the case where a transistor includes three or more gates, the gates may be referred to as a first gate, a second gate, a third gate, and the like in this specification and the like.

In this specification and the like, for example, a transistor with a multi-gate structure having two or more gate electrodes can be used as the transistor. With the multi-gate structure, channel formation regions are connected in series; accordingly, a plurality of transistors are connected in series. Thus, with the multi-gate structure, the amount of an off-state current can be reduced, and the breakdown voltage of the transistor can be increased (the reliability can be improved). Alternatively, with the multi-gate structure, drain-source current does not change very much even if drain-source voltage changes at the time of an operation in a saturation region, so that a flat slope of voltage-current characteristics can be obtained. By utilizing the flat slope of the voltage-current characteristics, an ideal current source circuit or an active load having an extremely high resistance value can be obtained. Accordingly, a differential circuit, a current mirror circuit, and the like having excellent properties can be obtained.

The case where a single circuit element is illustrated in a circuit diagram may include a case where the circuit element includes a plurality of circuit elements. For example, the case where a single resistor is illustrated in a circuit diagram may include a case where two or more resistors are electrically connected to each other in series. For another example, the case where a single capacitor is illustrated in a circuit diagram may include a case where two or more capacitors are electrically connected to each other in parallel. For another example, the case where a single transistor is illustrated in a circuit diagram may include a case where two or more transistors are electrically connected to each other in series and their gates are electrically connected to each other. Similarly, for another example, the case where a single switch is illustrated in a circuit diagram may include a case where the switch includes two or more transistors which are electrically connected to each other in series or in parallel and whose gates are electrically connected to each other.

In this specification and the like, a node can be referred to as a terminal, a wiring, an electrode, a conductive layer, a conductor, or an impurity region depending on the circuit structure and the device structure. Furthermore, a terminal, a wiring, or the like can be referred to as a node.

In this specification and the like, a “voltage” and a “potential” can be replaced with each other as appropriate. A “voltage” refers to a potential difference from a reference potential, and when the reference potential is a ground potential, for example, a “voltage” can be replaced with a “potential”. Note that the ground potential does not necessarily mean 0 V. Moreover, potentials are relative values, and a potential supplied to a wiring, a potential applied to a circuit or the like, and a potential output from a circuit or the like, for example, change with a change of the reference potential.

In this specification and the like, the terms “high-level potential” and “low-level potential” do not mean a particular potential. For example, in the case where two wirings are both described as “functioning as a wiring for supplying a high-level potential”, the levels of the high-level potentials supplied from the wirings are not necessarily equal to each other. Similarly, in the case where two wirings are both described as “functioning as a wiring for supplying a low-level potential”, the levels of the low-level potentials supplied from the wirings are not necessarily equal to each other.

A “current” means a charge transfer phenomenon (electrical conduction); for example, the description “electrical conduction of positively charged particles occurs” can be rephrased as “electrical conduction of negatively charged particles occurs in the opposite direction”. Therefore, unless otherwise specified, a “current” in this specification and the like refers to a charge transfer phenomenon (electrical conduction) accompanying carrier movement. Examples of a carrier here include an electron, a hole, an anion, a cation, and a complex ion, and the type of carrier differs between current flow systems (e.g., a semiconductor, a metal, an electrolyte solution, and a vacuum). The “direction of a current” in a wiring or the like refers to the direction in which a carrier with positive charge moves, and the amount of the current is expressed as a positive value. In other words, the direction in which a carrier with negative charge moves is opposite to the direction of a current, and the amount of the current is expressed as a negative value. Thus, in the case where the polarity of a current (or the direction of a current) is not specified in this specification and the like, the description “a current flows from element A to element B” can be rephrased as “a current flows from element B to element A”. The description “a current is input to element A” can be rephrased as “a current is output from element A”.

Ordinal numbers such as “first”, “second”, and “third” in this specification and the like are used in order to avoid confusion among components. Thus, the terms do not limit the number of components. The terms do not limit the order of components, either. For example, a “first” component in one embodiment in this specification and the like can be referred to as a “second” component in other embodiments or the scope of claims. For another example, a “first” component in one embodiment in this specification and the like can be omitted in other embodiments or the scope of claims.

In this specification and the like, the terms for describing positioning, such as “over” and “under”, are sometimes used for convenience to describe the positional relation between components with reference to drawings. The positional relationship between components is changed as appropriate in accordance with the direction in which the components are described. Thus, the positional relation is not limited to the terms described in the specification and the like, and can be described with another term as appropriate depending on the situation. For example, the expression “an insulator located over (on) a top surface of a conductor” can be replaced with the expression “an insulator located under (on) a bottom surface of a conductor” when the direction of a drawing illustrating these components is rotated by 180°.

Furthermore, the terms “over” and “under” do not necessarily mean that a component is placed directly over or directly under and in direct contact with another component. For example, the expression “electrode B over insulating layer A” does not necessarily mean that the electrode B is formed over and in direct contact with the insulating layer A, and does not exclude the case where another component is provided between the insulating layer A and the electrode B. Similarly, for example, the expression “electrode B above insulating layer A” does not necessarily mean that the electrode B is formed above and in direct contact with the insulating layer A, and does not exclude the case where another component is provided between the insulating layer A and the electrode B. Similarly, for example, the expression “electrode B under insulating layer A” does not necessarily mean that the electrode B is formed under and in direct contact with the insulating layer A, and does not exclude the case where another component is provided between the insulating layer A and the electrode B.

In this specification and the like, components arranged in a matrix and their positional relationship are sometimes described using terms such as “row” and “column”. The positional relationship between components is changed as appropriate in accordance with the direction in which the components are described. Thus, the positional relationship is not limited to the terms described in the specification and the like, and can be described with another term as appropriate depending on the situation. For example, the term “row direction” can be replaced with the term “column direction” when the direction of the diagram is rotated by 90°.

In this specification and the like, the terms “film” and “layer” can be interchanged with each other depending on the situation. For example, the term “conductive layer” can be replaced with the term “conductive film” in some cases. For another example, the term “insulating film” can be changed into the term “insulating layer” in some cases. Alternatively, the terms “film” and “layer” are not used and can be interchanged with another term depending on the case or the situation. For example, the term “conductive layer” or “conductive film” can be changed into the term “conductor” in some cases. Furthermore, for example, the term “insulating layer” or “insulating film” can be changed into the term “insulator” in some cases.

In this specification and the like, the terms “electrode”, “wiring”, “terminal”, and the like do not limit the functions of such components. For example, an “electrode” is used as part of a “wiring” in some cases, and vice versa. Furthermore, the term “electrode” or “wiring” also includes, for example, the case where a plurality of “electrodes” or “wirings” are formed in an integrated manner. For example, a “terminal” is used as part of a “wiring” or an “electrode” in some cases, and vice versa. Furthermore, the term “terminal” also includes the case where one or more selected from “electrodes”, “wirings”, and “terminals” are formed in an integrated manner, for example. Therefore, for example, an “electrode” can be part of a “wiring” or a “terminal”, and a “terminal” can be part of a “wiring” or an “electrode”. Moreover, the term “electrode”, “wiring”, or “terminal” is sometimes replaced with the term “region” depending on the case.

In this specification and the like, the terms “wiring”, “signal line”, and “power supply line” can be interchanged with each other depending on the case or the situation. For example, the term “wiring” can be changed into the term “signal line” in some cases. For another example, the term “wiring” can be changed into the term “power supply line” or the like in some cases. Conversely, the term “signal line” or “power supply line” can be changed into the term “wiring” in some cases. The term “power supply line” can be changed into the term “signal line” in some cases. Similarly, the term “signal line” can be changed into the term “power supply line” in some cases. The term “potential” that is applied to a wiring can be changed into the term “signal” depending on the case or the situation. Conversely, the term “signal” can be changed into the term “potential” in some cases.

In this specification and the like, a timing chart is used in some cases to describe an operation method of a semiconductor device. In this specification and the like, the timing chart shows an ideal operation example and a period, a level of a signal (e.g., a potential or a current), and a timing described in the timing chart are not limited unless otherwise specified. In the timing chart described in this specification and the like, the level of a signal (e.g., a potential or a current) input to a wiring (including a node) and a timing can be changed depending on the situation. For example, even when two periods are shown to have an equal length, the two periods have different lengths in some cases. Furthermore, for example, even when one of two periods is shown long and the other is shown short, the two periods can have the equal length in some cases, or the one period has a short length and the other has a long length in other cases.

In this specification and the like, a metal oxide is an oxide of a metal in a broad sense. Metal oxides are classified into an oxide insulator, an oxide conductor (including a transparent oxide conductor), an oxide semiconductor (also simply referred to as an OS), and the like. For example, in the case where a metal oxide is included in a channel formation region of a transistor, the metal oxide is referred to as an oxide semiconductor in some cases. That is, when a metal oxide can form a channel formation region of a transistor that has at least one of an amplifying function, a rectifying function, and a switching function, the metal oxide can be referred to as a metal oxide semiconductor. In the case where an OS transistor is mentioned, the OS transistor can also be referred to as a transistor including a metal oxide or an oxide semiconductor.

In this specification and the like, a metal oxide containing nitrogen is also referred to as a metal oxide in some cases. Alternatively, a metal oxide containing nitrogen may be called a metal oxynitride.

In this specification and the like, an impurity in a semiconductor refers to, for example, an element other than a main component of a semiconductor layer. For example, an element with a concentration of lower than 0.1 atomic % is an impurity. When an impurity is contained, for example, one or more of an increase in the density of defect states in a semiconductor, a decrease in carrier mobility, and a decrease in crystallinity occur in some cases. In the case where the semiconductor is an oxide semiconductor, examples of an impurity that changes characteristics of the semiconductor include Group 1 elements, Group 2 elements, Group 13 elements, Group 14 elements, Group 15 elements, and transition metals other than the main components; specific examples are hydrogen (contained also in water), lithium, sodium, silicon, boron, phosphorus, carbon, and nitrogen. In the case where the semiconductor is a silicon layer, examples of an impurity that changes characteristics of the semiconductor include Group 1 elements, Group 2 elements, Group 13 elements, and Group 15 elements (except oxygen and hydrogen).

In this specification and the like, a switch has a function of being in a conducting state (on state) or a non-conducting state (off state) to control whether current flows or not. Alternatively, a switch has a function of selecting and changing a current path. Thus, a switch may have two terminals or three or more terminals through which current flows, in addition to a control terminal. For example, an electrical switch or a mechanical switch can be used. That is, a switch can be any element capable of controlling current, and is not limited to a particular element.

Examples of an electrical switch include a transistor (e.g., a bipolar transistor and a MOS transistor), a diode (e.g., a PN diode, a PIN diode, a Schottky diode, a MIM (Metal Insulator Metal) diode, a MIS (Metal Insulator Semiconductor) diode, and a diode-connected transistor), and a logic circuit in which such elements are combined. Note that in the case of using a transistor as a switch, a “conducting state” of the transistor refers to a state where a source electrode and a drain electrode of the transistor can be regarded as being electrically short-circuited or a state where a current can be made to flow between the source electrode and the drain electrode. Furthermore, a “non-conducting state” of the transistor refers to a state where the source electrode and the drain electrode of the transistor can be regarded as being electrically disconnected. Note that in the case where a transistor operates just as a switch, there is no particular limitation on the polarity (conductivity type) of the transistor.

In this specification, “parallel” indicates a state where two straight lines are placed at an angle greater than or equal to −10° and less than or equal to 10°. Thus, the case where the angle is greater than or equal to −5° and less than or equal to 5° is also included. In addition, “approximately parallel” or “substantially parallel” indicates a state where two straight lines are placed at an angle greater than or equal to −30° and less than or equal to 30°. Moreover, “perpendicular” indicates a state where two straight lines are placed at an angle greater than or equal to 80° and less than or equal to 100°. Thus, the case where the angle is greater than or equal to 85° and less than or equal to 950 is also included. Furthermore, “approximately perpendicular” or “substantially perpendicular” indicates a state where two straight lines are placed at an angle greater than or equal to 60° and less than or equal to 120°.

In this specification and the like, one embodiment of the present invention can be constituted by appropriately combining a structure described in an embodiment with any of the structures described in the other embodiments. In addition, in the case where a plurality of structure examples are described in one embodiment, the structure examples can be combined as appropriate.

Note that a content (or part of the content) described in one embodiment can be applied to, combined with, or replaced with at least one of another content (or part of the content) in the embodiment and a content (or part of the content) described in one or a plurality of different embodiments.

Note that in each embodiment, a content described in the embodiment is a content described using a variety of diagrams or a content described with text disclosed in the specification.

Note that by combining a diagram (or part thereof) described in one embodiment with at least one of another part of the diagram, a different diagram (or part thereof) described in the embodiment, and a diagram (or part thereof) described in one or a plurality of different embodiments, much more diagrams can be provided.

Embodiments described in this specification are described with reference to the drawings. Note that the embodiments can be implemented in many different modes, and it will be readily appreciated by those skilled in the art that modes and details can be changed in various ways without departing from the spirit and scope thereof. Thus, the present invention should not be interpreted as being limited to the description in the embodiments. Note that in the structures of the invention in the embodiments, the same portions or portions having similar functions are denoted by the same reference numerals in different drawings, and repeated description thereof is omitted in some cases. In perspective views and the like, illustration of some components may be omitted for clarity of the drawings.

In this specification and the like, when a plurality of components are denoted with the same reference numerals, and in particular need to be distinguished from each other, an identification sign such as “_1”, “[n]”, or “[m,n]” is sometimes added to the reference numerals. Components denoted with identification signs such as “_1”, “[n]”, and “[m,n]” in the drawings and the like are sometimes described without such identification signs in this specification and the like when the components do not need to be distinguished from each other.

In the drawings in this specification, the size, the layer thickness, or the region is exaggerated for clarity in some cases. Therefore, the size, the layer thickness, or the region is not limited to the illustrated scale. The drawings are schematic views showing ideal examples, and embodiments of the present invention are not limited to shapes, values, or the like shown in the drawings. For example, variations in a signal, a voltage, or a current due to noise, variations in a signal, a voltage, or a current due to difference in timing, or the like can be included.

### Embodiment 1

In this embodiment, a semiconductor device of one embodiment of the present invention is described.

### <Circuit Structure Example of Semiconductor Device>

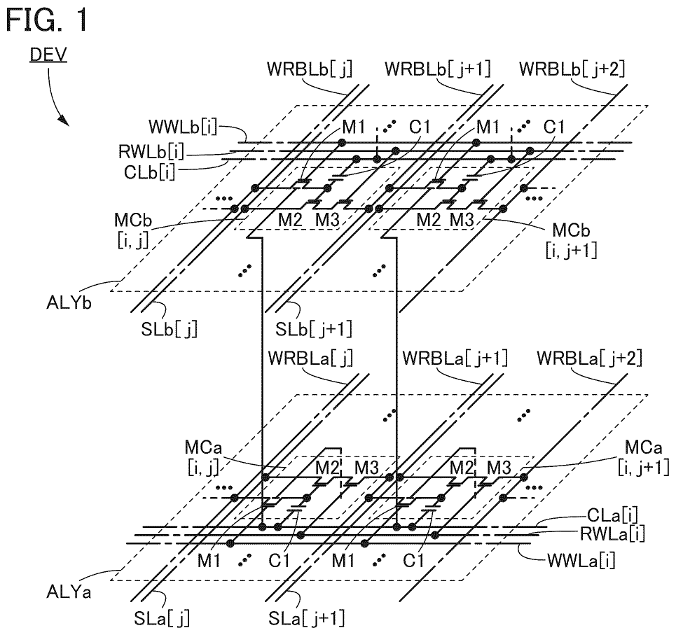

FIG. 1 is a circuit diagram illustrating a structure example of a semiconductor device DEV of one embodiment of the present invention. The semiconductor device DEV includes a memory layer ALYa and a memory layer ALYb, for example. Note that the memory layer ALYb is located above the memory layer ALYa in FIG. 1.

The memory layer ALYa and the memory layer ALYb each include a plurality of memory cells. Specifically, in each of the memory layer ALYa and the memory layer ALYb, a plurality of memory cells are arranged in an array in an example. In FIG. 1, for example, the memory cells MCa are arranged in a matrix of m rows and n columns (m is an integer of 1 or more and n is an integer of 1 or more) in the memory layer ALYa. Similarly, in FIG. 1, for example, the memory cells MCb are arranged in a matrix of m rows and n columns (m is an integer of 1 or more and n is an integer of 1 or more) in the memory layer ALYb.

Note that in this specification and drawings, for example, a memory cell located at the first column and the first row of the matrix of the memory layer ALYa is referred to as a memory cell MCa[1,1], and a memory cell located at the m-th row and the n-th column of the matrix of the memory layer ALYb is referred to as a memory cell MCb[m,n]. For example, FIG. 1 illustrates a memory cell MCa[i,j] located at the i-th row and the j-th column (i is an integer greater than or equal to 1 and less than or equal to m and j is an integer greater than or equal to 1 and less than or equal to n−1) and a memory cell MCa[i,j+1] located at the i-th row and the j+1-th column in the matrix of the memory layer ALYa. A memory cell MCb[i,j] located at the i-th row and the j-th column and a memory cell MCb[i,j+1] located at the i-th row and the j+1-th column in the matrix of the memory layer ALYb are also illustrated.

In FIG. 1, the memory cell MCa and the memory cell MCb have similar circuit structures. Therefore, in the description common to the memory cell MCa and the memory cell MCb in this specification and the drawings, the memory cell MCa and the memory cell MCb are each described as a memory cell MC.

Note that the number of rows and the number of columns in the matrix of the memory layer ALYa may be the same as or different from the number of rows and the number of columns in the matrix of the memory layer ALYb.

Note that the memory cell MC illustrated in FIG. 1 is an example of a memory cell called a gain cell and includes a transistor M1, a transistor M2, a transistor M3, and a capacitor C1. In particular, in this specification and the like, the structure of the memory cell MC in which OS transistors are used as the transistor M1 to the transistor M3 is referred to as a NOSRAM (registered trademark) (Nonvolatile Oxide Semiconductor Random Access Memory) in some cases.

OS transistors are preferably used as the transistor M1 to the transistor M3, for example. Specific examples of a metal oxide included in a channel formation region of the OS transistor include indium oxide, gallium oxide, and zinc oxide. The metal oxide preferably includes one or more selected from indium, an element M, and zinc. The element M is one or more selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, cobalt, magnesium, and antimony. In particular, the element M is preferably one or more selected from aluminum, gallium, yttrium, and tin.

In particular, an oxide containing indium (In), gallium (Ga), and zinc (Zn) (also referred to as IGZO) is preferably used as the metal oxide used for a semiconductor layer. Alternatively, it is preferable to use an oxide containing indium (In), tin (Sn), and zinc (Zn) (also referred to as ITZO (registered trademark)). Alternatively, it is preferable to use an oxide containing indium (In), gallium (Ga), tin (Sn), and zinc (Zn). Alternatively, it is preferable to use an oxide containing indium (In), aluminum (Al), and zinc (Zn) (also referred to as IAZO). Alternatively, it is preferable to use an oxide containing indium (In), aluminum (Al), gallium (Ga), and zinc (Zn) (also referred to as IAGZO). Note that the OS transistor will be described in detail in description of a cross-sectional structure example of the semiconductor device.

Transistors other than OS transistors may be used as the transistor M1 to the transistor M3. For example, transistors including silicon in channel formation regions (hereinafter referred to as Si transistors) can be employed as the transistor M1 to the transistor M3. As the silicon, single crystal silicon, amorphous silicon (sometimes referred to as hydrogenated amorphous silicon), microcrystalline silicon, or polycrystalline silicon (including low-temperature polycrystalline silicon) can be used, for example.

Examples of a transistor that can be used as each of the transistor M1 to the transistor M3 other than an OS transistor and a Si transistor include a transistor including germanium in a channel formation region, a transistor including a compound semiconductor, such as zinc selenide, cadmium sulfide, gallium arsenide, indium phosphide, gallium nitride, or silicon germanium, in a channel formation region, a transistor including a carbon nanotube in a channel formation region, and a transistor including an organic semiconductor in a channel formation region.

Although the transistor M1 to the transistor M3 illustrated in FIG. 1 are n-channel transistors, the transistor M1 to the transistor M3 may be p-channel transistors depending on the situation or the case. In the case where n-channel transistors are replaced with p-channel transistors, a potential or the like input to the memory cell MC needs to be appropriately changed so that the memory cell MC normally operates. Note that the same applies to transistors described in other parts of the specification and transistors illustrated in other drawings, not only to that in FIG. 1. In this embodiment, the structure of the memory cell MC is described assuming that the transistor M1 to the transistor M3 are n-channel transistors.

Each of the transistor M1 to the transistor M3 in an on state preferably operates in a saturation region. For example, in the case where the gate-source voltage of any one of the transistor M1 to the transistor M3 is constant, a current flowing between the source and the drain of the one of the transistors is higher than that in the case where the one of the transistors operates in a linear region. Thus, when the amount of current is increased, the transmission speed of a signal is increased; as a result, the operation speed of the circuit can be increased.

Depending on the situation, one or more of the transistor M1 to the transistor M3 may operate in a linear region. In addition, one or more of the transistor M1 to the transistor M3 may operate in a subthreshold region.

The transistor M1 is, for example, a transistor having a structure including a pair of gates with a channel sandwiched therebetween; the transistor M1 includes a first gate and a second gate. For convenience, the first gate is referred to as a gate (sometimes referred to as a front gate) and the second gate is referred to as a back gate so that they are distinguished from each other, for example; however, the first gate and the second gate can be interchanged with each other. As a specific example, a connection structure in which “a gate is electrically connected to a first wiring and a back gate is electrically connected to a second wiring” can be replaced with a connection structure in which “a back gate is electrically connected to the first wiring and a gate is electrically connected to the second wiring”.

Note that the transistor M2 and the transistor M3 may each have a transistor structure not including a back gate.

Note that the above description of the transistor applies to not only the transistor M1 to the transistor M3 but also transistors described in other parts of the specification and transistors shown in the drawings.

Next, circuit structures of the memory cell MCa[i,j] to a memory cell MCa[i,j+1] are described.

In each of the memory cell MCa[i,j] and the memory cell MCa[i,j+1] in the memory layer ALYa, the first terminal of the transistor M1 is electrically connected to a gate of the transistor M2 and a first terminal of the capacitor C1. The first terminal of the transistor M2 is electrically connected to a first terminal of the transistor M3.

In the memory cell MCa[i,j] in the memory layer ALYa, a second terminal of the transistor M1 is electrically connected to a wiring WRBLa[U], a second terminal of the transistor M2 is electrically connected to a wiring SLa[j], and a second terminal of the transistor M3 is electrically connected to a wiring WRBLa[j+1]. A gate of the transistor M1 is electrically connected to a wiring WWLa[i], a second terminal of the capacitor C1 is electrically connected to a wiring CLa[i], and a gate of the transistor M3 is electrically connected to a wiring RWLa[i].

In the memory cell MCa[i,j+1] in the memory layer ALYa, the second terminal of the transistor M1 is electrically connected to the wiring WRBLa[j+1], the second terminal of the transistor M2 is electrically connected to a wiring SLa[j+1], and the second terminal of the transistor M3 is electrically connected to a wiring WRBLa[j+2]. The gate of the transistor M1 is electrically connected to the wiring WWLa[i], the second terminal of the capacitor C1 is electrically connected to the wiring CLa[i], and the gate of the transistor M3 is electrically connected to the wiring RWLa[i].

Note that the back gate of the transistor M1 included in each of the memory cell MCa[i,j] and the memory cell MCa[i,j+1] placed in the memory layer ALYa may be electrically connected to a wiring extending below the memory layer ALYa (not illustrated), for example.

For example, the wiring WWLa[i] functions as a write word line for the memory cell MCa[i,j] and the memory cell MCa[i,j+1] included in the memory layer ALYa. That is, the wiring WWLa[i] functions as a wiring that transmits a selection signal (which may be a current, a variable potential, or a pulse voltage) for selecting the memory cell MCa on which writing is to be performed. Note that the wiring WWLa[i] may function as a wiring that supply a constant potential depending on the situation.

For example, the wiring RWLa[i] functions as a read word line for the memory cell MCa[i,j] and the memory cell MCa[i,j+1] included in the memory layer ALYa. That is, the wiring RWLa[i] functions as a wiring that transmits a selection signal (which may be a current, a variable potential, or a pulse voltage) for selecting the memory cell MCa on which reading is to be performed. Note that wiring RWLa[i] may function as a wiring that supply a constant potential depending on the situation.

For example, the wiring WRBLa[j] functions as a write bit line for the memory cell MCa[i,j] included in the memory layer ALYa. That is, the wiring WRBLa[j] functions as a wiring that transmits write data to the selected memory cell MCa[i,j]. The wiring WRBLa[j+1] functions as a write bit line for the memory cell MCa[i,j+1] included in the memory layer ALYa. That is, the wiring WRBLa[j+1] functions as a wiring that transmits write data to the selected memory cell MCa[i,j+1].

For example, the wiring WRBLa[j+1] functions as a read bit line for the memory cell MCa[i,j] included in the memory layer ALYa. That is, the wiring WRBLa[j+1] functions as a wiring that transmits read data from the selected memory cell MCa[i,j]. The wiring WRBLa[j+2] functions as a write bit line for the memory cell MCa[i,j+1] included in the memory layer ALYa. That is, the wiring WRBLa[j+2] functions as a wiring that transmits read data from the selected memory cell MCa[i,j+1].

Note that the wiring WRBLa[j] functions as a read bit line for a memory cell MCa[i,j−1](not illustrated in FIG. 1, and j is an integer greater than or equal to 2) included in the memory layer ALYa, for example. In addition, the wiring WRBLa[j+1] functions as a write bit line for a memory cell MCa[i,j+2](not illustrated in FIG. 1, and j is an integer less than or equal to n−2) included in the memory layer ALYa, for example.

That is, the wiring WRBLa functions as a write bit line for one of the adjacent memory cells with the wiring WRBLa therebetween and functions as a read bit line for the other of the adjacent memory cells with the wiring WRBLa therebetween.

Note that the wiring WRBLa[j] to the wiring WRBLa[j+2] may function as wirings that supply a constant potential depending on the situation.

The wiring SLa[j] functions as a wiring for supplying a fixed potential to the memory cell MCa[i,j] included in the memory layer ALYa, for example. The wiring SLa[j+1] functions as a wiring for supplying a fixed potential to the memory cell MCa[i,j+1] included in the memory layer ALYa, for example. Note that each of the wiring SLa[j] and the wiring SLa[j+1] may function as a wiring for supplying a variable potential depending on the situation.

For example, the wiring CLa[i] functions as a wiring that supply a constant potential to the memory cell MCa[i,j] and the memory cell MCa[i,j+1] included in the memory layer ALYa. Note that the wiring CLa[i] may function as a wiring for supplying a variable potential depending on the situation.

Note that as illustrated in FIG. 1, the structure of the memory layer ALYb can be the same as that of the memory layer ALYa. Thus, the structure of the memory cell MCb can be a structure in which the wiring WWLa[i] in the memory cell MCa is replaced with a wiring WWLb[i], the wiring RWLa[i] in the memory cell MCa is replaced with a wiring RWLb[i], the wiring WRBLa[U] to the wiring WRBLa[j+2] in the memory cell MCa are replaced with a wiring WRBLb[j] to a wiring WRBLb[j+2], the wiring SLa[j] and the wiring SLa[j+1] in the memory cell MCa are replaced with a wiring SLb[j] and a wiring SLb[j+1], and the wiring CLa[i] in the memory cell MCa is replaced with a wiring CLb[i].

Note that the back gate of the transistor M1 included in each of the memory cell MCb[i,j] and the memory cell MCb[i,j+1] placed in the memory layer ALYb may be electrically connected to the wiring CLa extending in the memory layer ALYa, for example. The second terminal of the capacitor C1 included in each of the memory cell MCb[i,j] and the memory cell MCb[i,j+1] placed in the memory layer ALYb may be electrically connected to a wiring extending a memory layer (not illustrated) above the memory layer ALYb, for example.

Next, data writing to the memory cells MC in the semiconductor device DEV illustrated in FIG. 1 and data reading from the memory cells MC are described. Here, as an example, data writing to the memory cell MCa[i,j] and data reading from the memory cell MCa[i,j] in the memory layer ALYa of the semiconductor device DEV are described.

To write data to the memory cell MCa[i,j] in the semiconductor device DEV illustrated in FIG. 1, first, a first potential (e.g., a ground potential) is supplied to the wiring CLa[i], for example. Next, a high-level potential is supplied to the wiring WWLa[i] to turn on the transistor M1 included in the memory cell MCa[i,j], and a low-level potential is supplied to a wiring WWLa[1] to a wiring WWLa[m] excluding the wiring WWLa[i] to turn off the transistors M1 included in the memory cells MCa of the first row to the m-th row excluding the i-th row. In addition, a low-level potential is supplied to a wiring RWLa[1] to a wiring RWLa[m] to turn off the transistor M3 included in the memory cell MCa[i,j].

Then, data for writing is transmitted to the wiring WRBLa[U] to write a potential corresponding to the data to the first terminal of the capacitor C1 of the memory cell MCa[i,j]. After the data is written to the first terminal of the capacitor C1 in the memory cell MCa[i,j], a low-level potential is supplied to the wiring WWLa[i] to turn off the transistor M1 included in the memory cell MCa[i,j]. Accordingly, the operation of writing data to the memory cell MCa[i,j] ends.

To read data from the memory cell MCa[i,j] in the semiconductor device DEV illustrated in FIG. 1, a second potential (e.g., a high-level potential higher than the first potential) is supplied to the wiring WRBLa[j+1] first. Then, a high-level potential is supplied to the wiring RWLa[i] to turn on the transistor M3 included in the memory cell MCa[i,j]. At this time, in the case where the transistor M2 in the memory cell MCa[i,j] operates in a saturation region, a current corresponding to the gate-source voltage of the transistor M2 (a potential difference between the potential of the gate of the transistor M2 and the potential of the wiring SLa[U]) flows. In this manner, the current flows from the wiring WRBLa[j+1] to the wiring SLa[U] through the transistor M2. By inputting the current flowing through the wiring WRBLa[j+1] to the reading circuit, data written to the memory cell MCa[i,j] can be read. Note that although data written to the memory cell MCa[i,j] is read from the amount of current here, data written to the memory cell MCa[i,j] may be read from a change in the voltage of the wiring WRBLa[j+1].

Note that data can be written to and read from another memory cell MCa by the operation similar to the above.

Note that the circuit structure of the semiconductor device of one embodiment of the present invention is not limited to the structure in FIG. 1. The circuit structure of the semiconductor device may be changed depending on the situation.

For example, in the semiconductor device DEV illustrated in FIG. 1, the wiring SLa[j] and the wiring SLa[j+1] extend in the column direction of the matrix of the memory layer ALYa; however, the wiring SLa[j] and the wiring SLa[j+1] may extend in the row direction of the matrix of the memory layer ALYa. Similarly, the wiring extending in one of the row direction and the column direction may be changed to extending in the other of the row direction and the column direction.

### <Cross-Sectional Structure Example of Semiconductor Device>

Next, a structure example of the semiconductor device DEV is described.

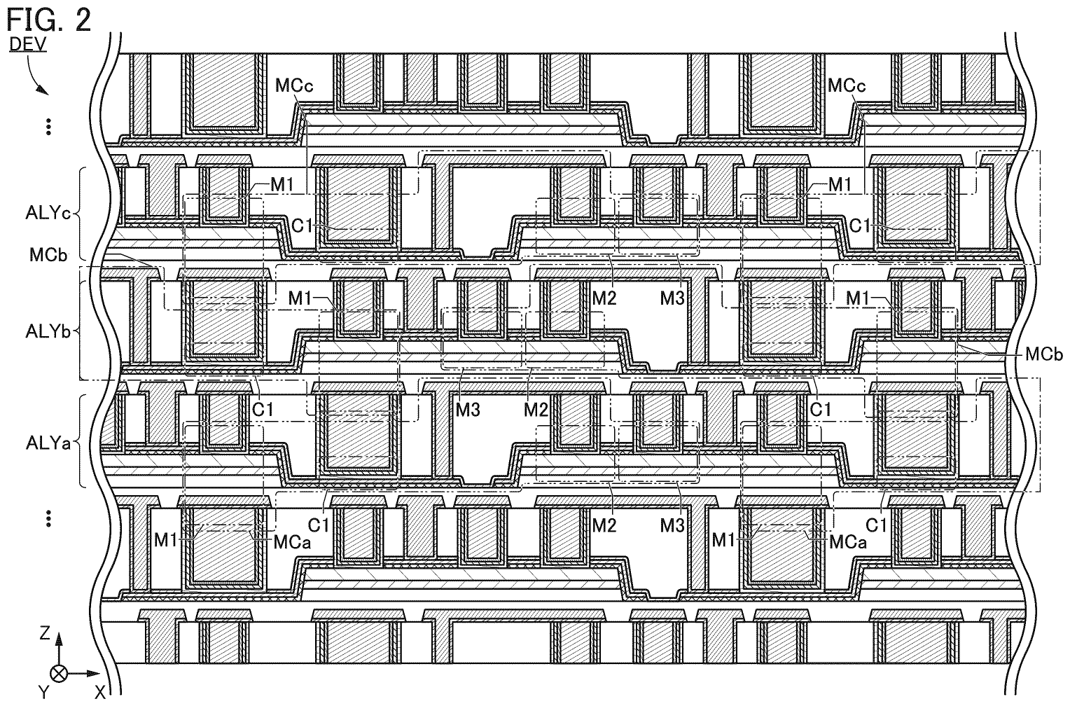

FIG. 2 is a schematic cross-sectional view illustrating a structure example of the semiconductor device DEV of one embodiment of the present invention. In FIG. 2, the semiconductor device DEV includes not only the memory layer ALYa and the memory layer ALYb but also a memory layer ALYc provided above the memory layer ALYb. Note that the memory layer ALYc includes a memory cell MCc having a structure similar to those of the memory cell MCa and the memory cell MCb. In FIG. 2, in the semiconductor device DEV, memory layers are provided below the memory layer ALYa and above the memory layer ALYc.

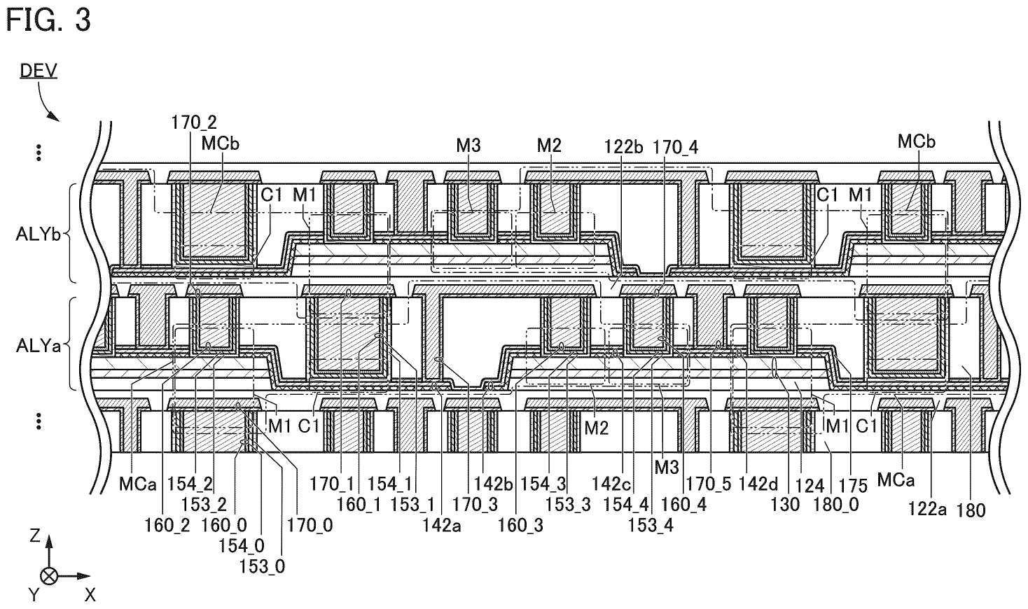

FIG. 3 is a schematic cross-sectional view mainly illustrating the memory layer ALYa and the memory layer ALYb in the structure example of the DEV of the semiconductor device in FIG. 2, and in the schematic cross-sectional view in FIG. 3, reference numerals showing components of the memory layer ALYa and the memory layer ALYb are shown as an example.

FIG. 3 illustrates a structure example in which the memory layer ALYa is provided over an insulator 122a, an insulator 122b is provided over the memory layer ALYa, and the memory layer ALYb is provided over the insulator 122b. Note that the insulator 122a and the insulator 122b will be described in detail later.

The X direction shown in FIG. 2 to FIG. 22D is parallel to the channel length directions of the transistor M1, the transistor M2, and the transistor M3, the Y direction is perpendicular to the X direction, and the Z direction is perpendicular to the X direction and the Y direction. The X direction, the Y direction, and the Z direction shown in FIG. 2 to FIG. 22D form a right-handed system.

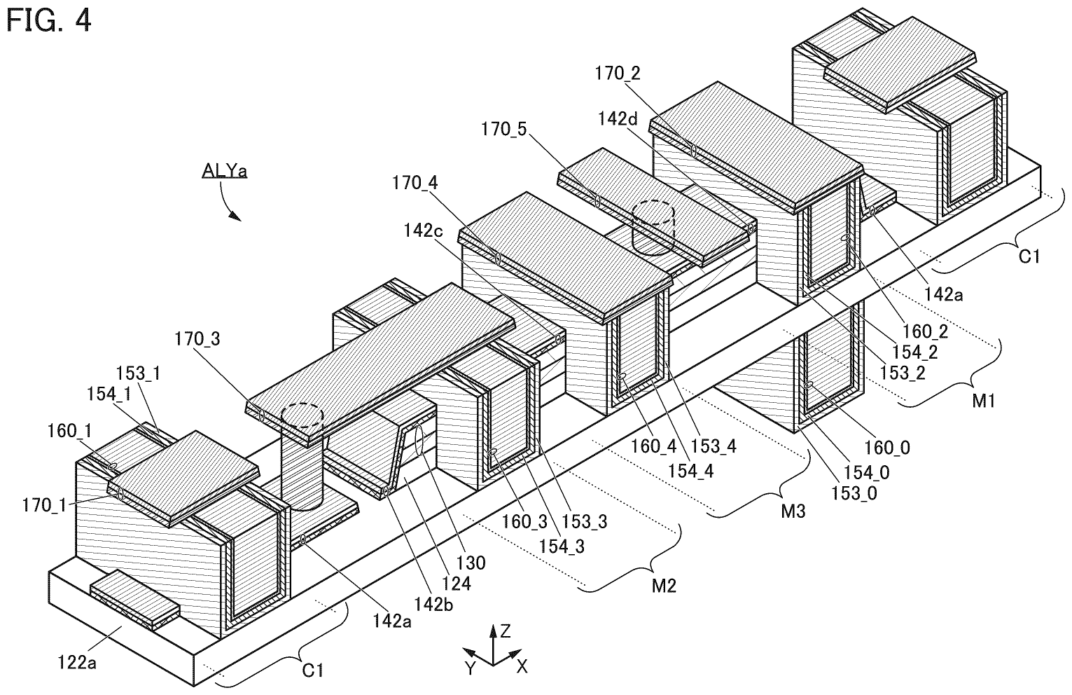

FIG. 4 is a schematic perspective view illustrating a partial structure example of the memory layer ALYa of the semiconductor device DEV in FIG. 3. Note that in FIG. 4, the insulator 122b, an insulator 180, an insulator 180_0, and an insulator 175 are not illustrated so that the structure of the memory layer ALYa can be seen easily. Note that the details of the insulator 122b, the insulator 180, the insulator 180_0, and the insulator 175 are described later.

In the memory layer ALYa in FIG. 4, a conductor 1600, a conductor 1601, a conductor 160_2, a conductor 160_3, a conductor 160_4, a conductor 170_2, a conductor 170_4, and a conductor 170_5, which are described later, are extended in the Y direction, for example.

In order to briefly describe the structure example of the semiconductor device DEV, attention is focused first on the memory layer ALYa in FIG. 3.

In the memory layer ALYa, the memory cell MCa is provided over the insulator 122a.

As described in the circuit structure example, the memory cell MCa includes the transistor M1, the transistor M2, the transistor M3, and the capacitor C1. Note that in FIG. 3, the transistor M1 to the transistor M3 are OS transistors, for example. That is, the semiconductor layer of each of the transistor M1 to the transistor M3 includes a metal oxide.

In FIG. 3, each of the transistor M1 to the transistor M3 includes an insulator 124 and an oxide 130. The transistor M1 includes a conductor 142a, a conductor 142d, the conductor 160_2, a conductor 1700, the conductor 160_0, an insulator 153_2, and an insulator 154_2. The transistor M2 includes a conductor 142b, a conductor 142c, the conductor 160_3, an insulator 153_3, and an insulator 154_3. The transistor M3 includes the conductor 142c, the conductor 142d, the conductor 160_4, an insulator 153_4, and an insulator 154_4. The capacitor C1 includes the conductor 142a, the conductor 160_1, an insulator 153_1, and an insulator 154_1.

Each of the conductor 160_2 to the conductor 160_4 is provided to overlap with the oxide 130, for example. Note that the conductor 160_2 to the conductor 160_4 are provided in order in the X direction so as not to overlap with each other. The conductor 160_2 functions as the gate of the transistor M1, the conductor 160_3 functions as the gate of the transistor M2, and the conductor 160_4 functions as the gate of the transistor M3. Note that the gates are each referred to as a first gate in some cases. In this specification and the like, the conductor 160_2 to the conductor 160_4 are each referred to as a gate electrode or a first gate electrode in some cases. The conductor 160_2 functions as the wiring WWLa[i] in FIG. 1, for example. The conductor 160_4 functions as the wiring RWLa[i] in FIG. 1, for example.

The insulator 153_2 and the insulator 154_2 function as a first gate insulating film of the transistor M1. The insulator 153_3 and the insulator 154_3 function as a first gate insulating film of the transistor M2. The insulator 153_4 and the insulator 154_4 function as a first gate insulating film of the transistor M3.

The insulator 124 is provided over the insulator 122a. The insulator 122a and the insulator 124 function as a second gate insulating film of the transistor M1.

The oxide 130 is provided over the insulator 124, for example. The oxide 130 functions as a semiconductor included in the channel formation region of each of the transistor M1 to the transistor M3.

The conductor 160_0 and the conductor 170_0 function as the back gate (sometimes referred to as a second gate) of the transistor M1. Therefore, in this specification and the like, the conductor 160_0 and the conductor 170_0 are each referred to as a back gate electrode or a second gate electrode in some cases. The conductor 160_0 and the conductor 170_0 also function as one of a pair of electrodes of a capacitor included in a memory cell of the memory layer located below the memory layer ALYa.

Note that FIG. 3 illustrates an insulator 153_0 and an insulator 154_0 formed in the periphery of the conductor 160_0 in the memory layer located below the memory layer ALYa, and the insulator 1800 (sometimes referred to as a planarization film or an interlayer film) where the insulator 153_0 and the insulator 154_0 are embedded.

In the transistor M1, the conductor 142a is provided on a top surface and a side surface of the oxide 130 and in a region not overlapping with the oxide 130, for example.

Specifically, the conductor 142a is provided over part of the oxide 130 and part of the insulator 122a. The conductor 142d is provided over part of the oxide 130, for example. In particular, the conductor 142a and the conductor 142d are physically separated from each other by the insulator 153_2 and the insulator 154_2. The conductor 142a functions as one of a source and a drain of the transistor M1, and the conductor 142d functions as the other of the source and the drain of the transistor M1. Therefore, in this specification and the like, the conductor 142a may be referred to as one of a source electrode and a drain electrode, and the conductor 142d may be referred to as the other of the source electrode and the drain electrode. The conductor 142d functions as any one of the wiring WRBLa[U], the wiring WRBLa[j+1], and the wiring WRBLa[j+2] in FIG. 1 or a conductor electrically connected to the wiring. Note that the insulator 175 for preventing diffusion of oxygen into the conductor 142a and the conductor 142d is provided over the conductor 142a and the conductor 142d.

In the transistor M2, the conductor 142b is provided on a top surface and a side surface of the oxide 130 and in a region not overlapping with the oxide 130, for example. Specifically, the conductor 142b is provided over part of the oxide 130 and part of the insulator 122a. Similarly, the conductor 142c is provided over part of the oxide 130, for example. In particular, the conductor 142b and the conductor 142c are physically separated from each other by the insulator 153_3 and the insulator 154_3. The conductor 142b functions as one of a source and a drain of the transistor M2, and the conductor 142c functions as the other of the source and the drain of the transistor M2. The conductor 142b functions as one of the wiring SLa[j] and the wiring SLa[j+1] in FIG. 1 or a conductor electrically connected to the wiring SLa. Note that the insulator 175 for preventing diffusion of oxygen into the conductor 142b and the conductor 142c is provided over the conductor 142b and the conductor 142c.

In the transistor M3, the conductor 142c is provided over part of the oxide 130, for example. Similarly, the conductor 142d is provided over part of the oxide 130, for example. In particular, the conductor 142c and the conductor 142d are physically separated from each other by the insulator 153_4 and the insulator 154_4. The conductor 142c functions as one of a source and a drain of the transistor M3, and the conductor 142d functions as the other of the source and the drain of the transistor M3.

The insulator 153_1, the insulator 154_1, and the conductor 160_1 are provided in order in a region of the top surface of the conductor 142a that does not overlap with the oxide 130. In particular, the capacitor C1 is formed in a region where the conductor 142a and the conductor 160_1 overlap with each other with the insulator 153_1 and the insulator 154_1 therebetween. That is, part of the conductor 142a functions as one of a pair of electrodes of the capacitor C1, and part of the conductor 160_1 functions as the other of the pair of electrodes of the capacitor C1. In that case, part of the insulator 153_1 and part of the insulator 154_1 function as the dielectrics of the capacitor C1.

Note that the conductor 160_1 to the conductor 160_4 may be formed in different steps or concurrently in the same step.

The memory layer ALYa includes the insulator 180 functioning as a planarization film or an interlayer film. The insulator 180 is formed to cover the transistor M1 to the transistor M3. The conductor 160_1 to the conductor 160_4 are formed to be embedded in the insulator 180.

The same insulating material can be used for the insulator 180_0 and the insulator 180. Specific insulating materials that are usable for the insulator 180_0 and the insulator 180 are described later.

The insulator 180 has a first opening in a region that overlaps with the conductor 142a and does not overlap with the oxide 130. A conductor 170_3 is provided in the first opening and over part of the insulator 180. The conductor 170_3 is electrically connected to the conductor 160_3.

The insulator 180 includes a second opening in a region overlapping with the conductor 142d. The conductor 170_5 is provided in the second opening and over part of the insulator 180. The conductor 170_5 functions as any one of the wiring WRBLa[j], the wiring WRBLa[j+1], and the wiring WRBLa[j+2] in FIG. 1, for example.

The conductor 170_1 is provided over the insulator 180, the insulator 153_1, the insulator 1541, and the conductor 160_1. The conductor 170_1 or the conductor 160_1 functions as the wiring CLa[i] in FIG. 1, for example. Furthermore, the conductor 170_1 also functions as the back gate electrode of the transistor M1 included in the memory layer ALYb.

The conductor 170_2 is provided over the insulator 180, the insulator 153_2, the insulator 154_2, and the conductor 160_2. The conductor 170_2 or the conductor 160_2 functions as the wiring WWLa[i] in FIG. 1, for example.

The conductor 170_4 is provided over the insulator 180, the insulator 153_4, the insulator 154_4, and the conductor 160_4. The conductor 170_4 or the conductor 160_4 functions as the wiring RWLa[i] in FIG. 1, for example.

Note that the conductor 170_1 to the conductor 170_5 may be formed in different steps or concurrently in the same step.

The insulator 122b is provided above the insulator 180 and the conductor 170_1 to the conductor 170_5.

The same insulating material can be used for the insulator 122a and the insulator 122b. Specific insulating materials that are usable for the insulator 122a and the insulator 122b are described later.

The memory layer ALYb is provided over the insulator 122b.

In FIG. 2 and FIG. 3, the memory layer ALYb can be formed in a manner similar to that of the memory layer ALYa. In particular, the memory layer ALYb is formed such that the conductor 170_1 overlaps with the gate electrode of the transistor M1 (corresponding to the conductor 160_2 in the memory layer ALYa) in the memory layer ALYb. Note that in FIG. 2 and FIG. 3, the cross-sectional structure of the memory layer ALYb is a structure in which the cross-sectional structure of the memory layer ALYa is rotated by 180° on the X-Y plane.

In the case of the structure of the semiconductor device DEV illustrated in FIG. 2 and FIG. 3, the conductor corresponding to the back gate electrode of the transistor M1 in the memory layer ALYb and the conductor corresponding to the other of the pair of electrodes of the capacitor C1 in the memory layer ALYa can be formed concurrently. That is, the structure illustrated in FIG. 2 and FIG. 3 offers the following advantages: the number of photomasks for manufacturing the semiconductor device DEV is reduced as compared with that in the case of a conventional structure, and the manufacturing process of the semiconductor device DEV is shortened.

The structure of the semiconductor device DEV in FIG. 2 may be changed depending on the situation. For example, the semiconductor device DEV illustrated in FIG. 2 includes a plurality of memory layers; however, the semiconductor device DEV of one embodiment of the present invention may include only one memory layer.

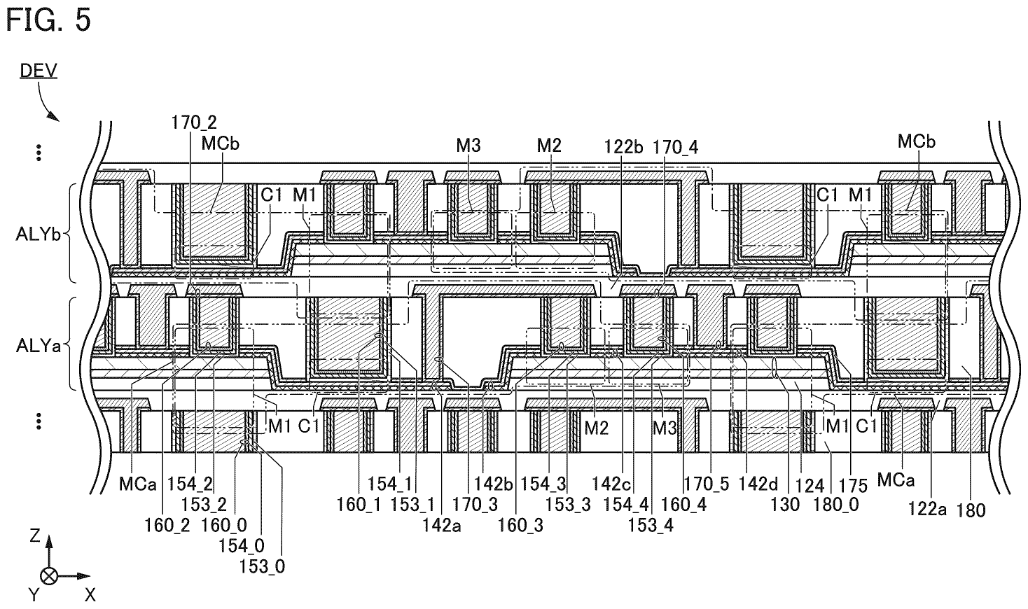

The structure of the semiconductor device DEV in FIG. 2 (FIG. 3) may be changed to that of the semiconductor device DEV illustrated in FIG. 5, for example. The semiconductor device DEV in FIG. 5 is different from the semiconductor device DEV in FIG. 2 (FIG. 3) in that the conductor 170_1 is not provided over the conductor 1601 (the conductor 170_0 is not provided over the conductor 160_0). As described above, in FIG. 2 (FIG. 3), the conductor 1701 (the conductor 170_0) functions as the back gate electrode of the transistor M1; however, in the case where the conductor 1601 (the conductor 160_0) alone functions as the back gate electrode of the transistor M1, the conductor 1701 (the conductor 170_0) may be omitted as in the structure of the semiconductor device DEV in FIG. 5.

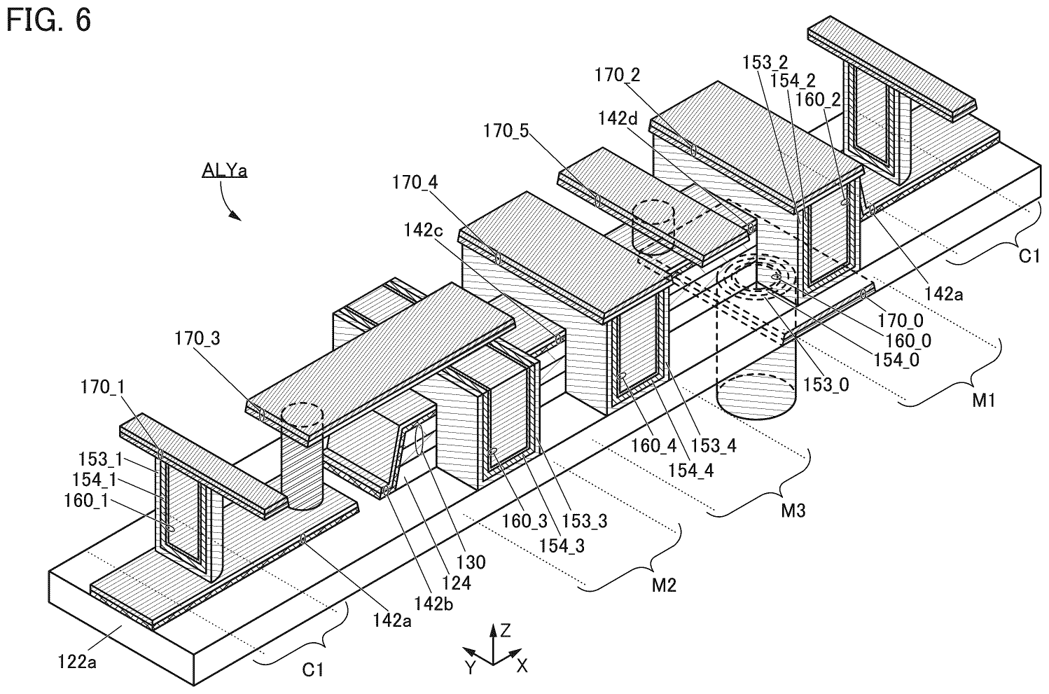

Alternatively, for example, the structure of the memory layer ALYa in FIG. 4 may be modified to that of the memory layer ALYa in FIG. 6. The memory layer ALYa in FIG. 4 has a structure in which the conductor 160_1 extends in the Y direction; however, in the memory layer ALYa in FIG. 6, not the conductor 160_1 but the conductor 170_1 extends in the Y direction. Incidentally, in the memory layer ALYa in FIG. 6, the insulator 153_1, the insulator 1541, and the conductor 160_1 are formed inside the opening portion of the insulator 180 (not illustrated) overlapping with the insulator 122a.

As illustrated in FIG. 2 and FIG. 3, for example, one of the pair of electrodes of the capacitor C1 in the memory layer ALYa is used in common with the back gate electrode of the transistor M1 in the memory layer ALYb, whereby the area occupied by the memory cell MC can be reduced. Accordingly, the semiconductor device can be scaled down or highly integrated, resulting in an increase in memory density.

When three transistors are formed in one oxide 130 as illustrated in FIG. 2 and FIG. 3, the area occupied by the transistors can be reduced. Specifically, three transistors share the oxide 130, the second terminal of the transistor M1 and the second terminal of the transistor M3 share the conductor 142d, and the first terminal of the transistor M2 and the first terminal of the transistor M3 share the conductor 142c; the transistor M1 to the transistor M3 can be formed in a smaller area (e.g., an area for 2.5 transistors) than the area for three transistors. In the case where a plurality of transistors are electrically connected to each other, a wiring for a gate, a source, a drain, or the like (sometimes referred to as an electrode or a terminal) and a contact hole (sometimes referred to as a via) for electrical connection to the wiring need to be provided, for example. For example, in the case where a source of the first transistor and a drain of the second transistor are electrically connected to each other, a first contact hole is formed over a wiring corresponding to the source of the first transistor, a second contact hole is formed over a wiring corresponding to the drain of the second transistor, and a wiring electrically connecting the first contact hole and the second contact hole is formed. Meanwhile, when three transistors are formed in one oxide 130 as illustrated in FIG. 2 and FIG. 3, the above-described contact holes or the like can be reduced. Accordingly, the area occupied by the memory cell can be reduced, so that the semiconductor device can be miniaturized or highly integrated, resulting in an increase in memory density.

### <Layout Example of Semiconductor Device>

Next, the layout of the memory layer included in the semiconductor device DEV is described.

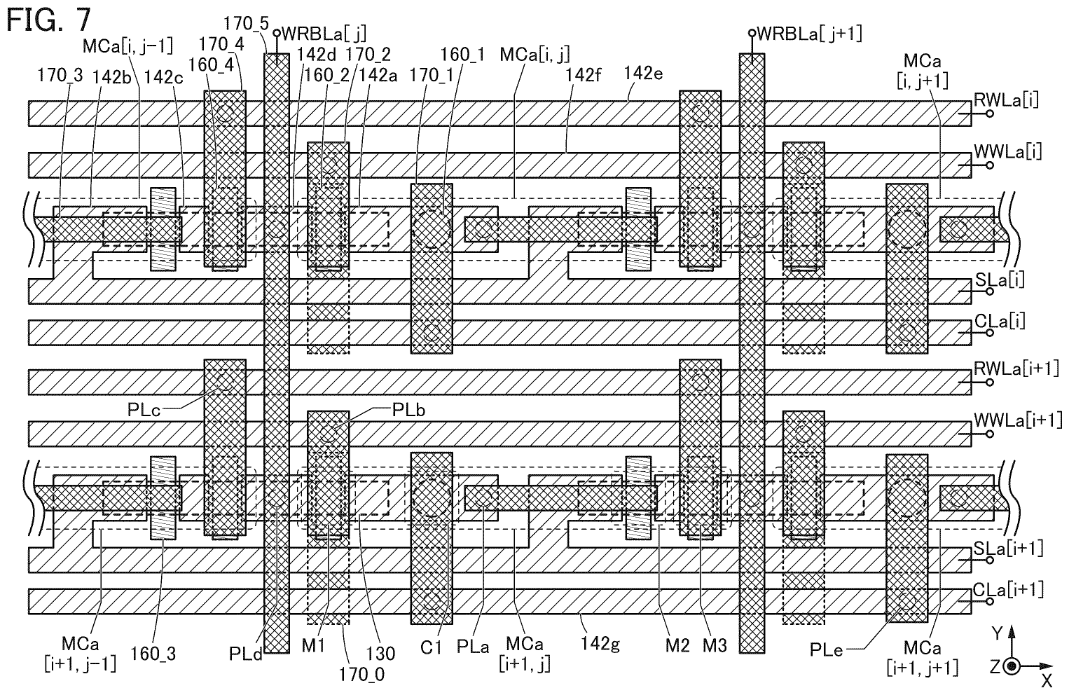

FIG. 7 is a layout diagram (plan view) example illustrating the circuit structure of the memory layer ALYa of the semiconductor device DEV illustrated in FIG. 6. In particular, FIG. 7 selectively illustrates the memory cell MCa[i,j], the memory cell MCa[i+1,j], part of the memory cell MCa[i,j−1], part of a memory cell MCa[i+1,j−1], part of the memory cell MCa[i,j+1], part of a memory cell MCa[i+1,j+1], and the vicinity thereof. For convenience, FIG. 7 also illustrates a wiring (conductor 170_0) extending below the memory layer ALYa. In addition, the insulators included in the semiconductor device DEV are not illustrated in FIG. 7.

In the plan view illustrated in FIG. 7, the conductor 170_0 is provided below the memory layer ALYa. The oxide 130 is provided over a region including the conductor 170_0. The conductor 142a and the conductor 142d are provided to cover part of the oxide 130. The conductor 160_2 is provided above the region including the region where the conductor 170_0 and the oxide 130 overlap with each other, between the conductor 142a and the conductor 142d. Thus, the transistor M1 is formed. The conductor 170_2 is provided over the conductor 160_2.

An opening PLa provided in an interlayer film (not illustrated) is located over the conductor 142a. An opening PLd provided in an interlayer film is located over the conductor 142d. The conductor 170_3 is embedded in the opening PLa, and the conductor 170_5 is embedded in the opening PLd. Thus, the conductor 170_3 embedded in the opening PLa and the conductor 170_5 embedded in the opening PLd each function as a wiring or a plug. In particular, the conductor 170_5 extends along the Y direction.

In the plan view illustrated in FIG. 7, the conductor 142b and the conductor 142c are provided to cover part of the oxide 130. The conductor 160_3 is provided in a region that is between the conductor 142b and the conductor 142c and that overlaps with the oxide 130. Thus, the transistor M2 is formed. The conductor 170_3 is provided over the conductor 160_3.

In the plan view illustrated in FIG. 7, the conductor 160_4 is provided in a region that is between the conductor 142c and the conductor 142d and that overlaps with the oxide 130. In this manner, the transistor M3 is formed. The conductor 170_4 is provided over the conductor 160_4.

In the plan view illustrated in FIG. 7, an insulator (not illustrated) is provided over part of the conductor 142a, and the conductor 160_1 is provided over the insulator. When the insulator functions as a dielectric, the capacitor C1 including part of the conductor 142a and the conductor 160_1 as a pair of electrodes is formed. The conductor 1701 is provided over the conductor 160_1.

The conductor 170_1 included in the memory layer ALYa also functions as the back gate of the transistor M1 included in the memory layer ALYb.

In the plan view of FIG. 7, a conductor 142e, a conductor 142f, and a conductor 142g are extended in the row direction in the memory layer ALYa. The conductor 142a of the transistor M1 also has a region extending in the row direction. Note that the conductor 142e, the conductor 142f, and the conductor 142g can be formed concurrently with the conductor 142a, the conductor 142b, the conductor 142c, and the conductor 142d.

An opening PLc provided in an interlayer film (not illustrated) is located over the conductor 142e. The conductor 170_4 is embedded in the opening PLc. Thus, the conductor 170_4 embedded in the opening PLc functions as a wiring or a plug. Accordingly, the conductor 142e is electrically connected to the conductor 160_4 of the transistor M3.

An opening PLb provided in an interlayer film (not illustrated) is located over the conductor 142f. The conductor 170_2 is embedded in the opening PLb. Thus, the conductor 170_2 embedded in the opening PLb functions as a wiring or a plug. Accordingly, the conductor 142f is electrically connected to the conductor 160_2 of the transistor M1.

An opening PLe provided in an interlayer film (not illustrated) is located over the conductor 142g. The conductor 170_1 is embedded in the opening PLe. Thus, the conductor 170_1 embedded in the opening functions as a wiring or a plug. In this manner, the conductor 142g is electrically connected to the conductor 160_1 of the capacitor CL.

As illustrated in FIG. 7, the conductor 142e functions as the wiring RWLa[i] or a wiring RWLa[i+1] extending in the row direction.

As illustrated in FIG. 7, the conductor 142f functions as the wiring WWLa[i] or a wiring WWLa[i+1] that extend in the row direction.

As illustrated in FIG. 7, the conductor 142g functions as the wiring CLa[i] or a wiring CLa[i+1] extending in the row direction.

Although the wiring SLa[j] and the wiring SLa[j+1] are described as wirings extending in the column direction in FIG. 1, the wiring SLa may be extended not in the column direction but in the row direction. For example, as illustrated in FIG. 7, the conductor 142b of the transistor M2 may function as the wiring SLa[i] and the wiring SLa[i+1] extending in the row direction.

As illustrated in FIG. 7, the conductor 170_5 functions as the wiring WRBLa[j] and the wiring WRBLa[j+1] extending in the column direction.

The oxide 130, the conductor 142a, the conductor 142b, the conductor 142c, the conductor 142d, the conductor 142e, the conductor 142f, the conductor 142g, the conductor 160_1 to the conductor 160_4, and the conductor 170_1 to the conductor 170_5 can each be formed by a lithography method, for example. Specifically, for example, in the case where the conductor 142a is formed, a conductive material to be the conductor 142a is formed by one or more of a sputtering method, a CVD (Chemical Vapor Deposition) method, a PLD (Pulsed Laser Deposition) method, and an ALD (Atomic Layer Deposition) method, and then a desired pattern is formed by a lithography method. The oxide 130, the conductor 142b, the conductor 142c, the conductor 142d, the conductor 142e, the conductor 142f, the conductor 142g, the conductor 160_1 to the conductor 160_4, and the conductor 170_1 to the conductor 170_5 can also be formed by a method similar to the above-described method.

For example, an insulator may be provided each between the oxide 130 and the conductor 160_2, between the oxide 130 and the conductor 160_3, and between the oxide 130 and the conductor 160_4. In particular, the insulator functions as a first gate insulating film (sometimes referred to as a gate insulating film or a front gate insulating film) in some cases.

In a process of forming the memory layer ALYa, planarization treatment using a chemical mechanical polishing (CMP) method or the like may be performed in order that the heights of film surfaces on which one or more selected from an insulator, a conductor, and a semiconductor are formed can be equal to each other.

### <<Structure Example of Memory Cell>>

Next, a structure example of the memory layer ALYa of the semiconductor device DEV illustrated in FIG. 3 is described.

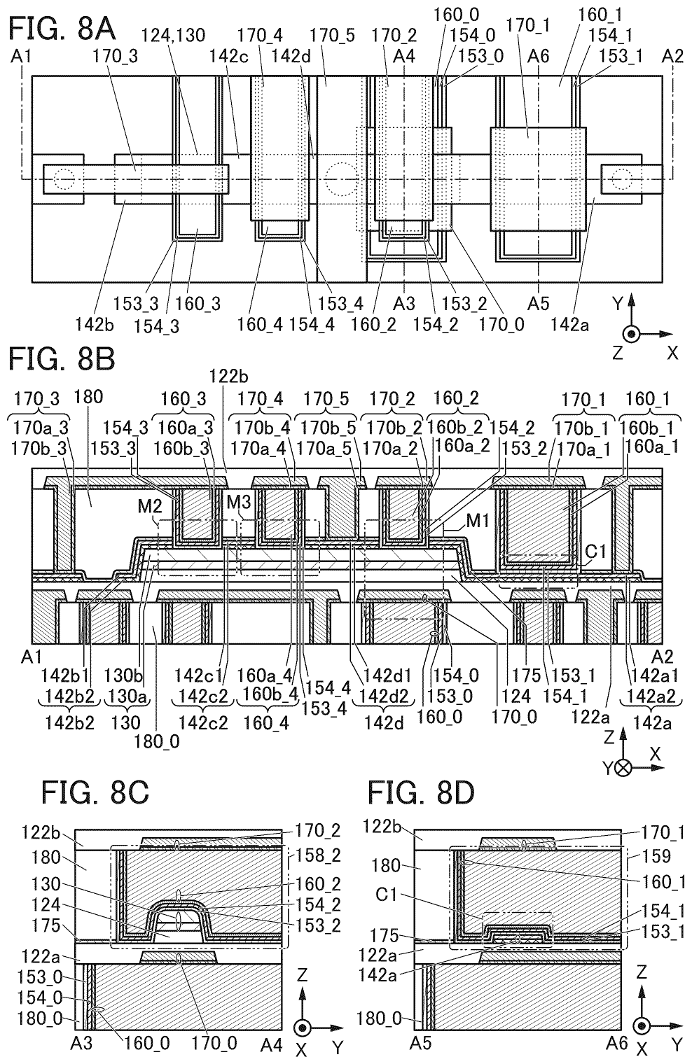

FIG. 8A to FIG. 8D are a schematic plan view and schematic cross-sectional views of the memory layer ALYa including the transistor M1, the transistor M2, the transistor M3, and the capacitor C1 in the semiconductor device DEV in FIG. 3. FIG. 8A is a schematic plan view of the memory layer ALYa. FIG. 8B to FIG. 8D are schematic cross-sectional views of the memory layer ALYa. Here, FIG. 8B is a cross-sectional view of a portion along dashed-dotted line A1-A2 illustrated in FIG. 8A, and is a cross-sectional view of the transistor M1 in the channel length direction. FIG. 8C is a schematic cross-sectional view of a portion along dashed-dotted line A3-A4 illustrated in FIG. 8A, and is a schematic cross-sectional view of the transistor M1 in the channel width direction. FIG. 8D is a cross-sectional view of a portion along dashed-dotted line A5-A6 illustrated in FIG. 8A, and is a schematic cross-sectional view of the capacitor C1. Note that some components are omitted in the plan view of FIG. 8A for clarity of the drawing.

A memory layer located below the memory layer ALYa includes the insulator 180_0, the insulator 1530, the insulator 154_0, and the conductor 160_0 over a substrate (not illustrated). FIG. 8B also illustrates a first gate electrode and a first gate insulating film of a transistor included in the memory layer located below the memory layer ALYa.

The semiconductor device DEV includes the conductor 170_0 over part of the conductor and part of the insulator 180_0 in the memory layer located below the memory layer ALYa. The semiconductor device DEV includes the insulator 122a covering the insulator 1800, a conductor located over the insulator 180_0, the insulator 153_0, the insulator 154_0, the conductor 1600, and the conductor 170_0.

The memory layer ALYa includes, over the insulator 122a, the insulator 124 located in a region including a range overlapping with the conductor 1600, the oxide 130 (an oxide 130a and an oxide 130b) located on the top surface of the insulator 124, the conductor 142a (a conductor 142al and a conductor 142a2) located on the top surface and the side surface of the oxide 130, the conductor 142b (a conductor 142b1 and a conductor 142b2) located on the top surface and the side surface of the oxide 130, the conductor 142c (a conductor 142c1 and a conductor 142c2) located on the top surface of the oxide 130, and the conductor 142d (a conductor 142d1 and a conductor 142d2) located on the top surface of the oxide 130. The memory layer ALYa includes the insulator 175 located on the top surface of the insulator 122a, the top surface of the conductor 142a, the top surface of the conductor 142b, the top surface of the conductor 142c, and the top surface of the conductor 142d, and the insulator 180 located on the top surface of the insulator 175.

The memory layer ALYa includes the insulator 153_2 located on the top surface and the side surface of the oxide 130, the insulator 154_2 located on the top surface of the insulator 1532, and the conductor 160_2 (a conductor 160a_2 and a conductor 160b_2) located on the top surface of the insulator 154_2. The memory layer ALYa includes the conductor 170_2 (a conductor 170a_2 and a conductor 170b_2) located on the top surface of the insulator 153_2, the top surface of the insulator 154_2, the top surface of the conductor 160_2, and the top surface of the insulator 180. The memory layer ALYa includes the insulator 153_3 located on the top surface and the side surface of the oxide 130, the insulator 154_3 located on the top surface of the insulator 153_3, and the conductor 160_3 (a conductor 160a_3 and a conductor 160b_3) located on the top surface of the insulator 154_3. The memory layer ALYa includes the conductor 170_3 (a conductor 170a_3 and a conductor 170b_3) located on the top surface of the insulator 153_3, the top surface of the insulator 154_3, the top surface of the conductor 160_3, and the top surface of the insulator 180. The memory layer ALYa includes the insulator 153_4 located on the top surface and the side surface of the oxide 130, the insulator 154_4 located on the top surface of the insulator 153_4, and the conductor 160_4 (a conductor 160a_4 and a conductor 160b_4) located on the top surface of the insulator 154_4. The memory layer ALYa includes the conductor 170_4 (a conductor 170a_4 and a conductor 170b_4) located on the top surface of the insulator 153_4, the top surface of the insulator 1544, the top surface of the conductor 160_4, and the top surface of the insulator 180. The memory layer ALYa includes the insulator 153_1 located in a region overlapping with the insulator 122a and not overlapping with the oxide 130, the insulator 154_1 located on the top surface of the insulator 153_1, and the conductor 1601 (a conductor 160a_1 and a conductor 160b_1) located on the top surface of the insulator 154_1. The memory layer ALYa includes the conductor 170_1 (a conductor 170a_1 and a conductor 170b_1) located on the top surface of the insulator 153_1, the top surface of the insulator 154_1, the top surface of the conductor 160_1, and the top surface of the insulator 180.

In the memory layer ALYa, the insulator 180 has an opening in a region that overlaps with the conductor 142a and does not overlap with the oxide 130. The conductor 170_3 (the conductor 170a_3 and the conductor 170b_3) is located in the opening and on the top surface of the insulator 180. In the memory layer ALYa, the insulator 180 also has an opening in a region overlapping with the conductor 142d. The conductor 170_5 (a conductor 170a_5 and a conductor 170b_5) is located in the opening and on the top surface of the insulator 180.

In particular, the transistor M1, the transistor M2, the transistor M3, and the capacitor C1 are provided to be embedded in the insulator 180.

In the region where the transistor M1 is formed, an opening 158_2 reaching the oxide 130b is provided in the insulator 180 and the insulator 175. In other words, the opening 158_2 includes a region overlapping with the oxide 130b. It can also be said that the insulator 175 includes an opening overlapping with the opening included in the insulator 180. That is, the opening 158_2 includes the opening included in the insulator 180 and the opening included in the insulator 175.

The insulator 153_2, the insulator 154_2, and the conductor 160_2 are provided in the opening 158_2. That is, the conductor 160_2 includes a region overlapping with the oxide 130b with the insulator 153 and the insulator 154 therebetween. The conductor 160_2, the insulator 153_2, and the insulator 154_2 are provided between the conductor 142a and the conductor 142d in the channel length direction of the transistor M1 (or the transistor M2). The insulator 154_2 includes a region in contact with a side surface of the conductor 160_2 and a region in contact with the bottom surface of the conductor 160_2. As illustrated in FIG. 8C, the insulator 122a and the insulator 153_2 are in contact with each other in a region of the opening 158_2 that does not overlap with the oxide 130.

Although not illustrated in FIG. 8A to FIG. 8D, an opening 158_3 reaching the oxide 130b is provided in the insulator 180 and the insulator 175 in the region where the transistor M2 is formed, and an opening 158_4 reaching the oxide 130b is provided in the insulator 180 and the insulator 175 in the region where the transistor M3 is formed. It can be said that the opening 158_3 and the opening 158_4 include the opening included in the insulator 180 and the opening included in the insulator 175, as in the opening 158_2. As in the opening 158_2, the insulator 153_3, the insulator 154_3, and the conductor 160_3 are provided in the opening 158_3, and the insulator 153_4, the insulator 154_4, and the conductor 160_4 are provided in the opening 158_4. For the structures of the channel widths of the transistor M2 and the transistor M3, the cross-sectional view of the channel width of the transistor M1 illustrated in FIG. 8C can be referred to.

The oxide 130 preferably includes the oxide 130a provided over the insulator 124 and the oxide 130b provided over the oxide 130a. Including the oxide 130a under the oxide 130b makes it possible to inhibit diffusion of impurities into the oxide 130b from components formed below the oxide 130a.

Although the two-layer stacked-structure having the oxide 130a and the oxide 130b in the transistor M1 to the transistor M3 is described, the present invention is not limited thereto. For example, the oxide 130 may have a single-layer structure of the oxide 130b or a stacked-layer structure of three or more layers, or the oxide 130a and the oxide 130b may each have a stacked-layer structure.

In FIG. 8A to FIG. 8D, the transistor M1 includes the oxide 130 functioning as a semiconductor layer, the conductor 160_2 functioning as a first gate (also referred to as a gate, a top gate, or a front gate) electrode, the conductor 170_0 functioning as a second gate (also referred to as a back gate) electrode, the conductor 142a functioning as one of a source electrode and a drain electrode, and the conductor 142d functioning as the other of the source electrode and the drain electrode. The insulator 153_2 and the insulator 154_2 functioning as a first gate insulator are also included. The insulator 122a and the insulator 124 functioning as a second gate insulator are also included. Note that the gate insulator is also referred to as a gate insulating layer or a gate insulating film in some cases. At least part of a region of the oxide 130 overlapping with the conductor 160_2 functions as a channel formation region.

The first gate electrode and the first gate insulating film are placed in the opening 158_2 formed in the insulator 180 and the insulator 175. That is, the conductor 160_2, the insulator 154_2, and the insulator 153_2 are placed in the opening 158_2.

In addition, the transistor M2 includes the oxide 130 functioning as a semiconductor layer, the conductor 160_3 functioning as a gate (also referred to as a top gate or a front gate) electrode, the conductor 142b functioning as one of a source electrode and a drain electrode, and the conductor 142c functioning as the other of the source electrode and the drain electrode. The insulator 153_3 and the insulator 154_3 each functioning as a gate insulator are also included. The insulator 122a and the insulator 124 are also included. At least part of a region of the oxide 130 overlapping with the conductor 160_3 functions as a channel formation region.

In addition, the transistor M3 includes the oxide 130 functioning as a semiconductor layer, the conductor 160_4 functioning as a gate (also referred to as a top gate or a front gate) electrode, the conductor 142c functioning as one of a source electrode and a drain electrode, and the conductor 142d functioning as the other of the source electrode and the drain electrode. The insulator 153_4 and the insulator 154_4 functioning as a gate insulator are also included. The insulator 122a and the insulator 124 are also included. At least part of a region of the oxide 130 overlapping with the conductor 160_4 functions as a channel formation region.

The capacitor C1 includes the conductor 142a functioning as a lower electrode, the insulator 153_1 and the insulator 154_1 functioning as a dielectric, and the conductor 160_1 functioning as an upper electrode. That is, the capacitor C1 forms a MIM (Metal-Insulator-Metal) capacitor.

The upper electrode and the dielectric of the capacitor C1 are placed in an opening 159 formed in the insulator 180 and the insulator 175. That is, the conductor 160_1, the insulator 153_1, and the insulator 154_1 are placed in the opening 159.

An opening in the insulator 175 and the insulator 180 reaching the conductor 142a is provided in a region of the conductor 142a that overlaps with neither the insulator 124 nor the oxide 130b. The conductor 170_3 (the conductor 170a_3 and the conductor 170b_3) is placed in the opening. The conductor 170_3 functions as a wiring or a plug.

As described above, the conductor 170_3 is also located over the insulator 180, the insulator 153_3, the insulator 154_3, and the conductor 160_3. Thus, the conductor 170_3 and the conductor 160_3 are electrically connected to each other.

An opening in the insulator 175 and the insulator 180 reaching the conductor 142d is provided on the top surface of the conductor 142d. The conductor 170_5 (the conductor 170a_5 and the conductor 170b_5) is placed in the opening. The conductor 170_5 functions as a wiring or a plug.

As described above, the conductor 170_2 is located over the insulator 180, the insulator 153_2, the insulator 154_2, and the conductor 160_2. Thus, the conductor 170_2 and the conductor 160_2 are electrically connected to each other. The conductor 170_2 functions as a wiring or a plug.

Similarly, as described above, the conductor 170_4 is located over the insulator 180, the insulator 153_4, the insulator 154_4, and the conductor 160_4. Thus, the conductor 170_4 and the conductor 160_4 are electrically connected to each other. The conductor 170_4 functions as a wiring or a plug.

The memory layer ALYa including the transistor M1, the transistor M2, the transistor M3, and the capacitor C1, which is described in this embodiment, can be used in a memory device.

<<Example of manufacturing method of semiconductor device>>

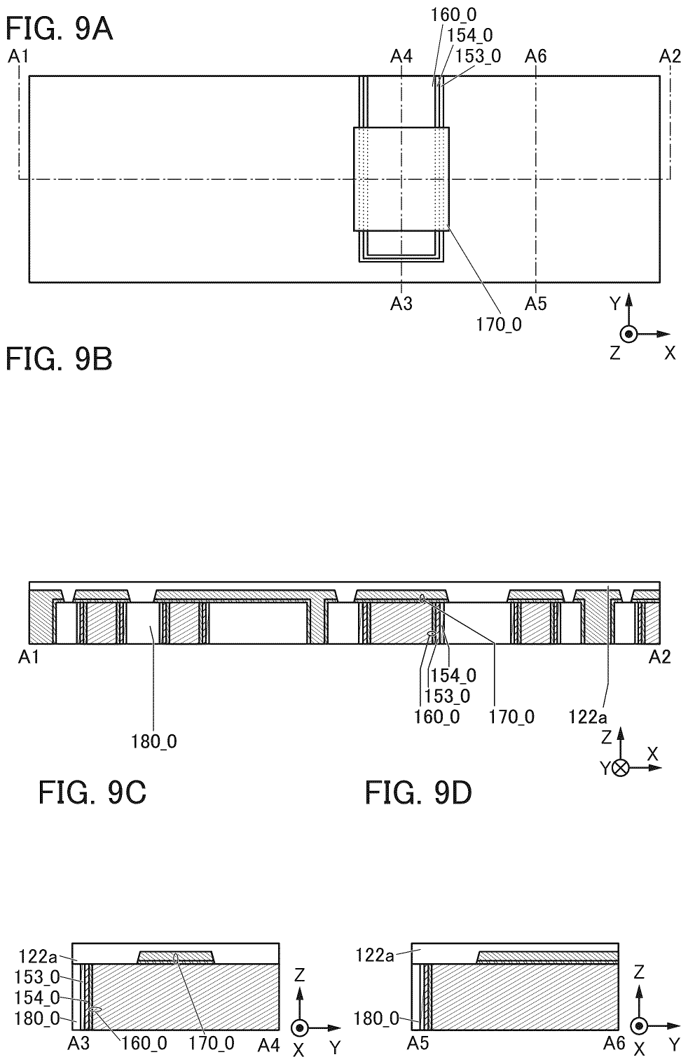

Next, an example of a method for manufacturing the memory layer ALYa of the semiconductor device DEV illustrated in FIG. 8A to FIG. 8D is described. Referring to FIG. 9A to FIG. 22D, the example of the manufacturing method is described.

In each of FIG. 9A to FIG. 22D, A of each drawing illustrates a schematic plan view. Moreover, B of each drawing is a schematic cross-sectional view illustrating a portion along the dashed-dotted line A1-A2 illustrated in A of the corresponding drawing, and is also a schematic cross-sectional view of the transistor M1 to the transistor M3 in the channel length direction. Furthermore, C of each drawing is a schematic cross-sectional view illustrating a portion along the dashed-dotted line A3-A4 illustrated in A of the corresponding drawing, and is also a schematic cross-sectional view of the transistor M1 in the channel width direction. In addition, D of each drawing is a schematic cross-sectional view of a portion along dashed-dotted line A5-A6 in A of the corresponding drawing. Note that for clarity of the drawing, some components are not illustrated in the schematic plan view of A of each drawing.

Hereinafter, an insulating material for forming an insulator, a conductive material for forming a conductor, or a semiconductor material for forming a semiconductor can be deposited by a film-formation method such as a sputtering method, a CVD method, an MBE (Molecular Beam Epitaxy) method, a PLD method, or an ALD method as appropriate.

First, a substrate (not illustrated) is prepared, and a memory layer below the memory layer ALYa is formed over the substrate. For example, the insulator 180_0, the insulator 1530, the insulator 1540, the conductor 1600, the conductor 1700, and the insulator 122a are formed over the substrate (see FIG. 9A to FIG. 9D). Note that FIG. 9A to FIG. 9D illustrate a first gate electrode and a first gate insulating film of each of the transistor M1 to the transistor M3 included in the memory layer below the memory layer ALYa, in addition to the insulator 1800, the insulator 1530, the insulator 1540, the conductor 1600, the conductor 170_0, and the insulator 122a.

For example, the insulator 180_0 is formed over the substrate, and then an opening is formed in the insulator 180_0 in a region where the insulator 153_0, the insulator 154_0, and the conductor 160_0 are to be formed. After the opening is formed, a first insulating film to be the insulator 1530, a second insulating film to be the insulator 1540, and a first conductive film to be the conductor 1600 are sequentially formed in the opening, and then planarization treatment such as a chemical mechanical polishing method is performed to remove parts of the first insulating film, the second insulating film, and the first conductive film, so that the insulator 180_0 is exposed. Thus, the insulator 153_0, the insulator 154_0, and the conductor 160_0 can be formed only in the opening formed in the insulator 180_0.

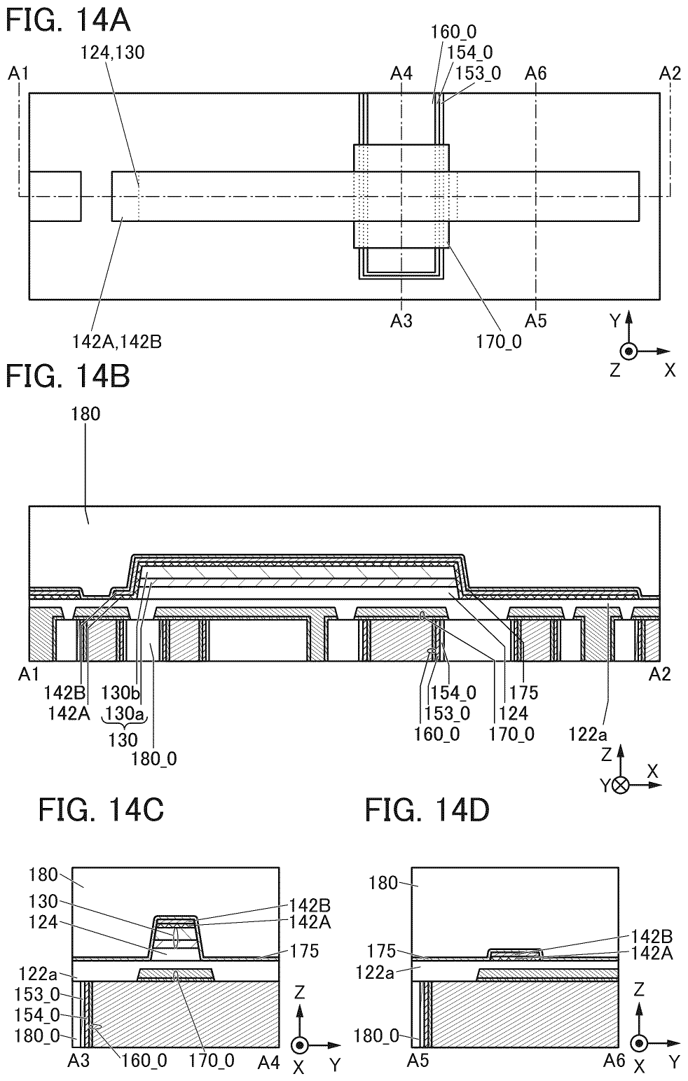

For methods for forming the insulator 1800, the insulator 1530, the insulator 1540, and the conductor 160_0, later-described methods for forming the insulator 180, the insulator 153_1 to the insulator 153_4, the insulator 154_1 to the insulator 154_4, and the conductor 160_1 to the conductor 160_4 are referred to (see FIG. 14A to FIG. 19D).

Note that the first gate electrode and the first gate insulating film included in each of the transistor M1 to the transistor M3 included in the memory layer below the memory layer ALYa can also be formed in a manner similar to the above. The first gate insulating film of each of the transistor M1 to the transistor M3 can be formed concurrently with the insulator 153_0 and the insulator 154_0. The first gate electrodes of the transistor M1 to the transistor M3 can be formed concurrently with the conductor 160_0.

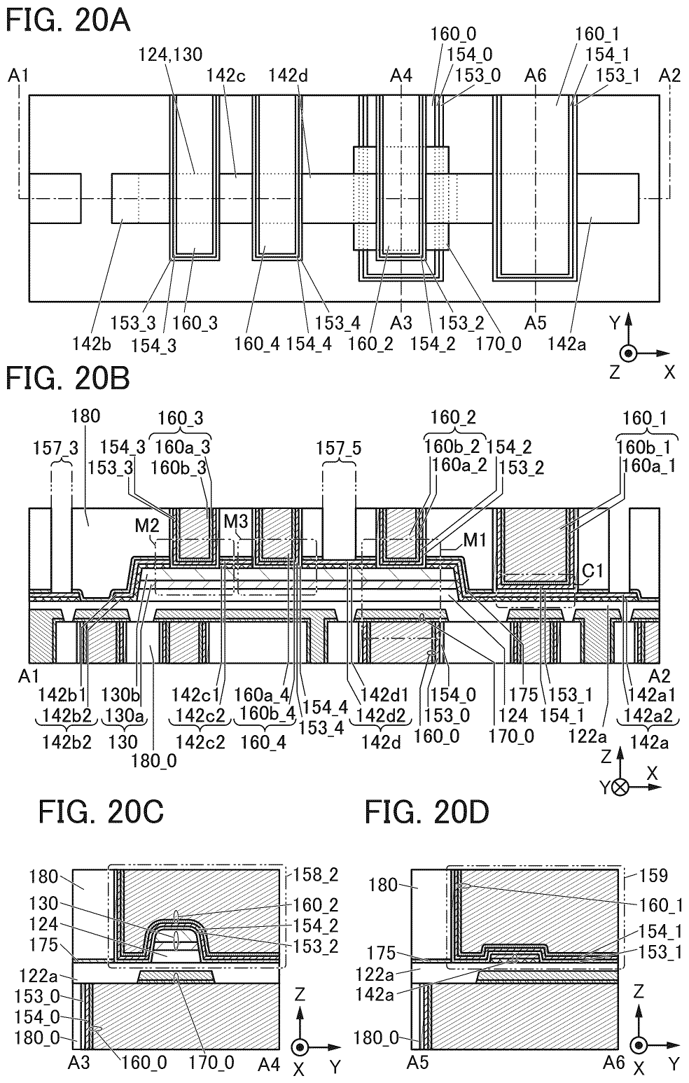

After that, a second conductive film to be the conductor 170_0 is formed over the top surfaces of the insulator 1800, the insulator 1530, the insulator 1540, and the conductor 1600, and the second conductive film is processed by a lithography method, whereby the conductor 170_0 can be formed. Note that a later-described method for forming the conductor 170_1 to the conductor 170_5 is referred to for the formation of the conductor 1700 (see FIG. 20A to FIG. 22D).

Next, the insulator 122a is deposited over the insulator 180_0, the insulator 153_0, the insulator 1540, the conductor 1600, and the conductor 1700 (see FIG. 9A to FIG. 9D). An insulator containing an oxide of one or both of aluminum and hafnium can be used for the insulator 122a. Note that as the insulator containing an oxide of one or both of aluminum and hafnium, aluminum oxide, hafnium oxide, an oxide containing aluminum and hafnium (hafnium aluminate), or the like is preferably used. Alternatively, hafnium-zirconium oxide is preferably used. The insulator containing an oxide of one or both of aluminum and hafnium has a barrier property against oxygen, hydrogen, and water. When the insulator 122a has a barrier property against hydrogen and water, hydrogen and water contained in components provided around the transistor M1 to the transistor M3 are inhibited from diffusing into the transistor M1 to the transistor M3 through the insulator 122a, and generation of oxygen vacancies in the oxide 130 can be inhibited.

The insulator 122a can be formed by a film-formation method such as a sputtering method, a CVD method, an MBE method, a PLD method, or an ALD method. In this embodiment, for the insulator 122a, hafnium oxide is deposited by an ALD method. It is particularly preferable to use a method for forming hafnium oxide with a reduced hydrogen concentration.

Note that a high-k material with a high dielectric constant may be used as the insulating material used for the insulator 122a. Examples of the high-k material with a high dielectric constant include a metal oxide containing one kind or two or more kinds selected from aluminum, gallium, yttrium, zirconium, tungsten, titanium, tantalum, nickel, germanium, and magnesium in addition to the above-described hafnium oxide. Alternatively, aluminum oxide, hafnium oxide, and an oxide containing aluminum and hafnium (hafnium aluminate), which are insulators each containing an oxide of one or both of aluminum and hafnium, may be used for the insulator 122a. Alternatively, the insulator 122a may be formed using any of the materials that can be used for the insulator 153_1 to the insulator 153_4 or the insulator 154_1 to the insulator 154_4 described later. The insulator 122a may have a stacked-layer structure including two or more selected from the above-described materials.

Subsequently, heat treatment is preferably performed. The heat treatment is performed at higher than or equal to 250° C. and lower than or equal to 650° C., preferably higher than or equal to 300° C. and lower than or equal to 500° C., further preferably higher than or equal to 320° C. and lower than or equal to 450° C. Note that the heat treatment is performed in a nitrogen gas or inert gas atmosphere, or an atmosphere containing an oxidizing gas at higher than or equal to 10 ppm, higher than or equal to 1%, or higher than or equal to 10%. For example, in the case where the heat treatment is performed in a mixed atmosphere of a nitrogen gas and an oxygen gas, the proportion of the oxygen gas is approximately 20%. The heat treatment may be performed under reduced pressure. Alternatively, the heat treatment may be performed in an atmosphere containing an oxidizing gas at 10 ppm or more, 1% or more, or 10% or more in order to compensate for oxygen released, after heat treatment is performed in a nitrogen gas or inert gas atmosphere.

The gas used in the above heat treatment is preferably highly purified. For example, the amount of moisture contained in the gas used in the above heat treatment is less than or equal to 1 ppb, preferably less than or equal to 0.1 ppb, further preferably less than or equal to 0.05 ppb. The heat treatment using a highly purified gas can prevent entry of moisture or the like into the insulator 122a and the like as much as possible.

In this embodiment, as the heat treatment, treatment is performed at 400° C. for one hour with a flow rate ratio of a nitrogen gas to an oxygen gas of 4:1 after the formation of the insulator 122a. Through the heat treatment, impurities such as water or hydrogen contained in the insulator 122a can be removed, for example. In the case where an oxide containing hafnium is used for the insulator 122a, the insulator 122a is partly crystallized by the heat treatment in some cases. The heat treatment can also be performed after the formation of the insulator 124, for example.

The transistor M1 to the transistor M3 and the capacitor C1 are formed over the insulator 122a through later steps. Therefore, planarization treatment such as a CMP method is preferably performed on the insulator 122a.

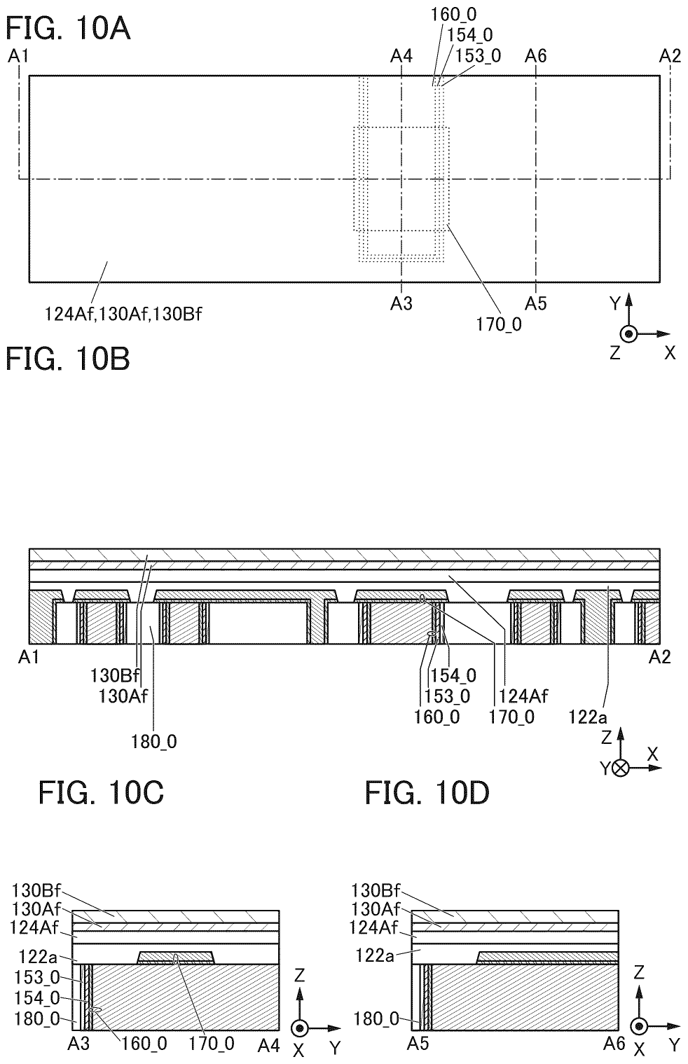

Next, an insulating film 124Af is formed over the insulator 122a (see FIG. 10A to FIG. 10D). The insulating film 124Af can be formed by a film-formation method such as a sputtering method, a CVD method, an MBE method, a PLD method, or an ALD method. In this embodiment, as the insulating film 124Af, silicon oxide is deposited by a sputtering method. By using a sputtering method that does not need to use a molecule containing hydrogen as a deposition gas, the hydrogen concentration in the insulating film 124Af can be reduced. The hydrogen concentration in the insulating film 124Af is preferably reduced in this manner because the insulating film 124Af is in contact with the oxide 130a in a later step.

Other than silicon oxide, an insulating material such as silicon oxynitride may be used for the insulating film 124Af, for example.

Note that in this specification and the like, oxynitride refers to a material that contains more oxygen than nitrogen in its composition, and nitride oxide refers to a material that contains more nitrogen than oxygen in its composition. For example, in the case where silicon oxynitride is described, it refers to a material that contains more oxygen than nitrogen in its composition. In the case where silicon nitride oxide is described, it refers to a material that contains more nitrogen than oxygen in its composition.

Next, an oxide film 130Af and an oxide film 130Bf are formed in order over the insulating film 124Af (see FIG. 10A to FIG. 10D). Note that the oxide film 130Af and the oxide film 130Bf are preferably formed successively without being exposed to an atmospheric environment. Through the formation without exposure to an atmospheric environment, impurities from an atmospheric environment or moisture can be prevented from being attached onto the oxide film 130Af and the oxide film 130Bf, so that the vicinity of an interface between the oxide film 130Af and the oxide film 130Bf can be kept clean.

The oxide film 130Af and the oxide film 130Bf can be formed by a film-formation method such as a sputtering method, a CVD method, an MBE method, a PLD method, or an ALD method. In this embodiment, the oxide film 130Af and the oxide film 130Bf are formed by a sputtering method.

For example, in the case where the oxide film 130Af and the oxide film 130Bf are formed by a sputtering method, oxygen or a mixed gas of oxygen and a noble gas is used as a sputtering gas. Increasing the proportion of oxygen contained in the sputtering gas can increase the amount of excess oxygen in the formed oxide films. In the case where the oxide films are formed by a sputtering method, the above In-M-Zn oxide target or the like can be used.

In particular, when the oxide film 130Af is formed, part of oxygen contained in the sputtering gas is supplied to the insulating film 124Af in some cases. Thus, the proportion of oxygen contained in the sputtering gas is higher than or equal to 70%, preferably higher than or equal to 80%, further preferably 100%.

In the case where the oxide film 130Bf is formed by a sputtering method and the proportion of oxygen contained in the sputtering gas for deposition is higher than 30% and lower than or equal to 100%, preferably higher than or equal to 70% and lower than or equal to 100%, an oxygen-excess oxide semiconductor is formed. In a transistor using an oxygen-excess oxide semiconductor in its channel formation region, relatively high reliability can be obtained. Note that one embodiment of the present invention is not limited thereto. In the case where the oxide film 130Bf is formed by a sputtering method and the proportion of oxygen contained in the sputtering gas for deposition is higher than or equal to 1% and lower than or equal to 30%, preferably higher than or equal to 5% and lower than or equal to 20%, an oxygen-deficient oxide semiconductor is formed. In a transistor using an oxygen-deficient oxide semiconductor in its channel formation region, relatively high field-effect mobility can be obtained. Furthermore, when the deposition is performed while the substrate is being heated, the crystallinity of the oxide film can be improved.

In this embodiment, for example, the oxide film 130Af is formed by a sputtering method using an oxide target with In:Ga:Zn=1:3:4 [atomic ratio]. The oxide film 130Bf is formed by a sputtering method using an oxide target with In:Ga:Zn=4:2:4.1 [atomic ratio], an oxide target with In:Ga:Zn=1:1:1 [atomic ratio], an oxide target with In:Ga:Zn=1:1:1.2 [atomic ratio], or an oxide target with In:Ga:Zn=1:1:2 [atomic ratio]. Note that each of the oxide films is preferably formed so as to have characteristics required for the oxide 130a and the oxide 130b by selecting the deposition conditions and the atomic ratios as appropriate.

Note that the insulating film 124Af, the oxide film 130Af, and the oxide film 130Bf are preferably formed by a sputtering method without exposure to the air. For example, a multi-chamber film-formation apparatus is used. As a result, entry of hydrogen into the insulating film 124Af, the oxide film 130Af, and the oxide film 130Bf in intervals between deposition steps can be inhibited.

Note that the oxide film 130Af and the oxide film 130Bf may be formed by an ALD method. When the oxide film 130Af and the oxide film 130Bf are formed by an ALD method, the films with uniform thicknesses can be formed even in a groove or an opening having a high aspect ratio. When a PEALD (Plasma Enhanced Atomic Layer Deposition) method is used, the oxide film 130Af and the oxide film 130Bf can be formed at a lower temperature than that in the case of employing a thermal ALD method.

Next, heat treatment is preferably performed. The heat treatment can be performed in a temperature range where the oxide film 130Af and the oxide film 130Bf do not become polycrystals, i.e., at higher than or equal to 250° C. and lower than or equal to 650° C., preferably higher than or equal to 400° C. and lower than or equal to 600° C. Note that the heat treatment is performed in a nitrogen gas or inert gas atmosphere, or an atmosphere containing an oxidizing gas at 10 ppm or more, 1% or more, or 10% or more. For example, in the case where the heat treatment is performed in a mixed atmosphere of a nitrogen gas and an oxygen gas, the proportion of the oxygen gas is approximately 20%. The heat treatment may be performed under reduced pressure. Alternatively, the heat treatment may be performed in an atmosphere containing an oxidizing gas at 10 ppm or more, 1% or more, or 10% or more in order to compensate for oxygen released, after heat treatment is performed in a nitrogen gas or inert gas atmosphere.

The gas used in the above heat treatment is preferably highly purified. For example, the amount of moisture contained in the gas used in the above heat treatment is less than or equal to 1 ppb, preferably less than or equal to 0.1 ppb, further preferably less than or equal to 0.05 ppb. The heat treatment using a highly purified gas can prevent entry of moisture or the like into the oxide film 130Af, the oxide film 130Bf, and the like as much as possible.

In this embodiment, the heat treatment is performed at 400° C. for one hour with a flow rate ratio of a nitrogen gas to an oxygen gas being 4:1. Through such heat treatment using an oxygen gas, an impurity such as carbon, water, and hydrogen in the oxide film 130Af and the oxide film 130Bf can be reduced. The reduction of an impurity in the films improves the crystallinity of the oxide film 130Bf, thereby offering a dense structure with higher density. Thus, crystalline regions in the oxide film 130Af and the oxide film 130Bf are expanded, so that in-plane variations of the crystalline regions in the oxide film 130Af and the oxide film 130Bf can be reduced. Accordingly, an in-plane variation of electrical characteristics of the transistor M1 to the transistor M3 can be reduced.

By performing the heat treatment, hydrogen in the insulating film 124Af, the oxide film 130Af, and the oxide film 130Bf moves into the insulator 122a and is absorbed by the insulator 122a. In other words, hydrogen in the insulating film 124Af, the oxide film 130Af, and the oxide film 130Bf diffuses into the insulator 122a. Accordingly, the hydrogen concentration in the insulator 122a increases, while the hydrogen concentrations in the insulating film 124Af, the oxide film 130Af, and the oxide film 130Bf decrease.

In particular, the insulating film 124Af functions as a gate insulator of the transistor M1. Depending on the case, the insulating film 124Af also functions as gate insulators of the transistor M2 and the transistor M3 in some cases. The oxide film 130Af and the oxide film 130Bf function as channel formation regions of the transistor M1 to the transistor M3. Thus, the transistor M1 to the transistor M3 including the insulating film 124Af, the oxide film 130Af, and the oxide film 130Bf with reduced hydrogen concentrations are preferable because the transistor M1 to the transistor M3 have favorable reliability.

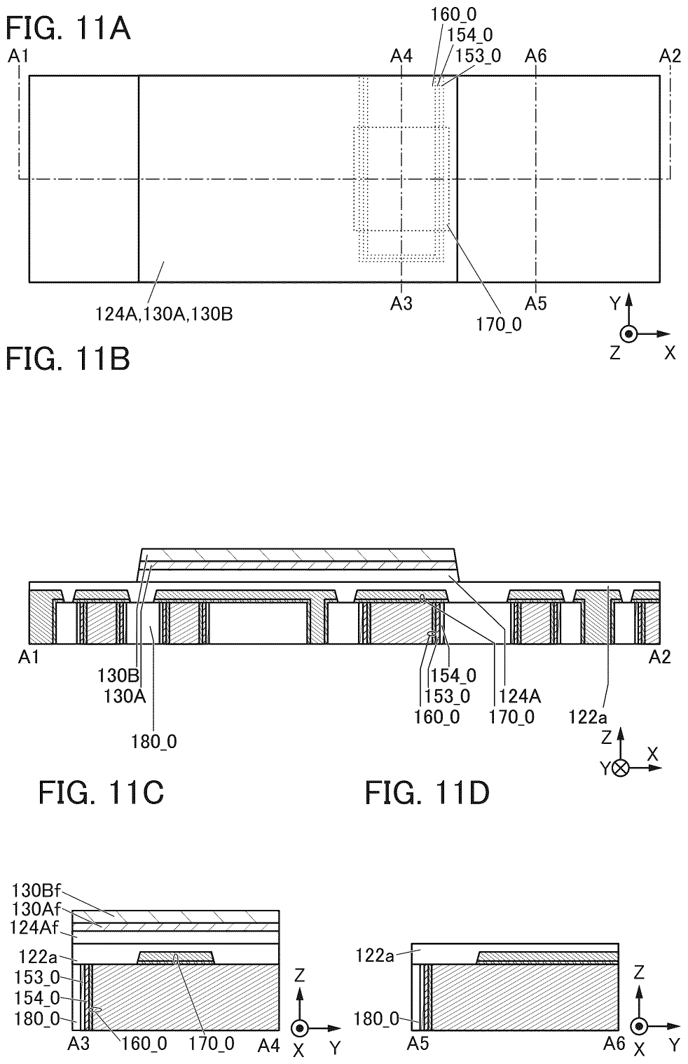

Next, the insulating film 124Af, the oxide film 130Af, and the oxide film 130Bf are processed into a band-like shape by a lithography method to form an insulating layer 124A, an oxide layer 130A, and an oxide layer 130B (see FIG. 11A to FIG. 11D). Here, the insulating layer 124A, the oxide layer 130A, and the oxide layer 130B are formed to extend in a direction parallel to the dashed-dotted line A3-A4 (the channel width direction of the transistor M1 or the Y direction illustrated in FIG. 11A). The insulating layer 124A, the oxide layer 130A, and the oxide layer 130B are formed to at least partly overlap with the conductor 160_0. A dry etching method or a wet etching method can be used for the processing. Processing by a dry etching method is suitable for microfabrication. The insulating film 124Af, the oxide film 130Af, and the oxide film 130Bf may be processed under different conditions. The insulating film 124Af, the oxide film 130Af, and the oxide film 130Bf may be processed into a shape different from a band-like shape.

Note that in a lithography method, first, a resist is exposed to light through a mask. Next, a region exposed to light is removed or left using a developing solution, so that a resist mask is formed. Then, etching treatment through the resist mask is conducted, whereby a conductor, a semiconductor, an insulator, or the like can be processed into a desired shape. The resist mask may be formed through, for example, exposure of the resist to KrF excimer laser light, ArF excimer laser light, EUV (Extreme Ultraviolet) light, or the like. A liquid immersion technique may be employed in which a gap between a substrate and a projection lens is filled with a liquid (e.g., water) in light exposure. An electron beam or an ion beam may be used instead of the light. Note that a mask is unnecessary in the case of using an electron beam or an ion beam. Note that the resist mask can be removed by dry etching treatment such as ashing, wet etching treatment, wet etching treatment after dry etching treatment, or dry etching treatment after wet etching treatment.

In addition, a hard mask formed of an insulator or a conductor may be used under the resist mask. In the case where a hard mask is used, a hard mask with a desired shape can be formed in the following manner: an insulating film or a conductive film that is the hard mask material is formed over the oxide film 130Bf, a resist mask is formed thereover, and then the hard mask material is etched. The etching of the oxide film 130Bf and the like may be performed after removing the resist mask or with the resist mask remaining. In the latter case, the resist mask sometimes disappears during the etching. The hard mask may be removed by etching after the etching of the oxide film 130Bf and the like. Meanwhile, the hard mask is not necessarily removed when the hard mask material does not affect later steps or can be utilized in later steps.

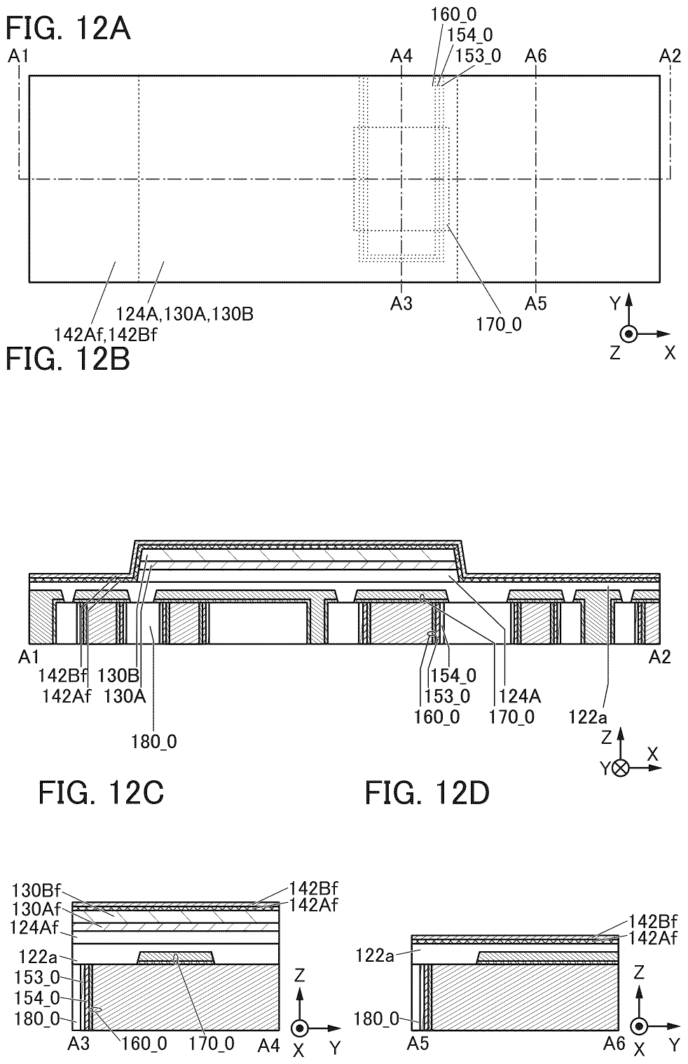

Next, a conductive film 142Af and a conductive film 142Bf are formed in this order over the insulator 122a and the oxide layer 130B (see FIG. 12A to FIG. 12D). The conductive film 142Af and the conductive film 142Bf can be formed by a film-formation method such as a sputtering method, a CVD method, an MBE method, a PLD method, or an ALD method. For example, tantalum nitride is deposited as the conductive film 142Af by a sputtering method and tungsten is deposited as the conductive film 142Bf. Note that heat treatment may be performed before the formation of the conductive film 142Af. This heat treatment may be performed under reduced pressure, and the conductive film 142Af may be successively formed without exposure to the air. Such treatment can remove moisture and hydrogen adsorbed onto the surface of the oxide layer 130B, and further can reduce the moisture concentration and the hydrogen concentration in the oxide layer 130A and the oxide layer 130B. The heat treatment temperature is preferably higher than or equal to 100° C. and lower than or equal to 400° C. In this embodiment, the heat treatment temperature is 200° C.

Note that for the conductive film 142Af, a conductive material such as a nitride containing tantalum, a nitride containing titanium, a nitride containing molybdenum, a nitride containing tungsten, a nitride containing tantalum and aluminum, or a nitride containing titanium and aluminum may be used other than tantalum nitride, for example. For another example, a conductive material such as ruthenium, ruthenium oxide, ruthenium nitride, an oxide containing strontium and ruthenium, or an oxide containing lanthanum and nickel may be used. These materials are preferable because they are each a conductive material that is less likely to be oxidized or a material that maintains the conductivity even after absorbing oxygen.

For the conductive film 142Bf, other than tungsten, a conductive material, e.g., a metal element selected from aluminum, chromium, copper, silver, gold, platinum, tantalum, nickel, titanium, molybdenum, hafnium, vanadium, niobium, manganese, magnesium, zirconium, beryllium, indium, ruthenium, iridium, strontium, and lanthanum; an alloy containing any of the above metal elements; an alloy containing a combination of the above metal elements; or the like, may be used. For example, a conductive material such as titanium nitride, a nitride containing titanium and aluminum, a nitride containing tantalum and aluminum, ruthenium oxide, ruthenium nitride, an oxide containing strontium and ruthenium, or an oxide containing lanthanum and nickel may be used. Tantalum nitride, titanium nitride, a nitride containing titanium and aluminum, a nitride containing tantalum and aluminum, ruthenium oxide, ruthenium nitride, an oxide containing strontium and ruthenium, and an oxide containing lanthanum and nickel are preferable because they are oxidation-resistant conductive materials or materials that maintain their conductivity even after absorbing oxygen.

Materials that are usable for the conductive film 142Af and the conductive film 142Bf may be used interchangeably. Alternatively, the same material may be used for the conductive film 142Af and the conductive film 142Bf. That is, the conductor 142al and the conductor 142a2 may be one conductor in the memory cell MCa. Similarly, the conductor 142b1 and the conductor 142b2 may be one conductor. Similarly, the conductor 142c1 and the conductor 142c2 may be one conductor. Similarly, the conductor 142d1 and the conductor 142d2 may be one conductor.

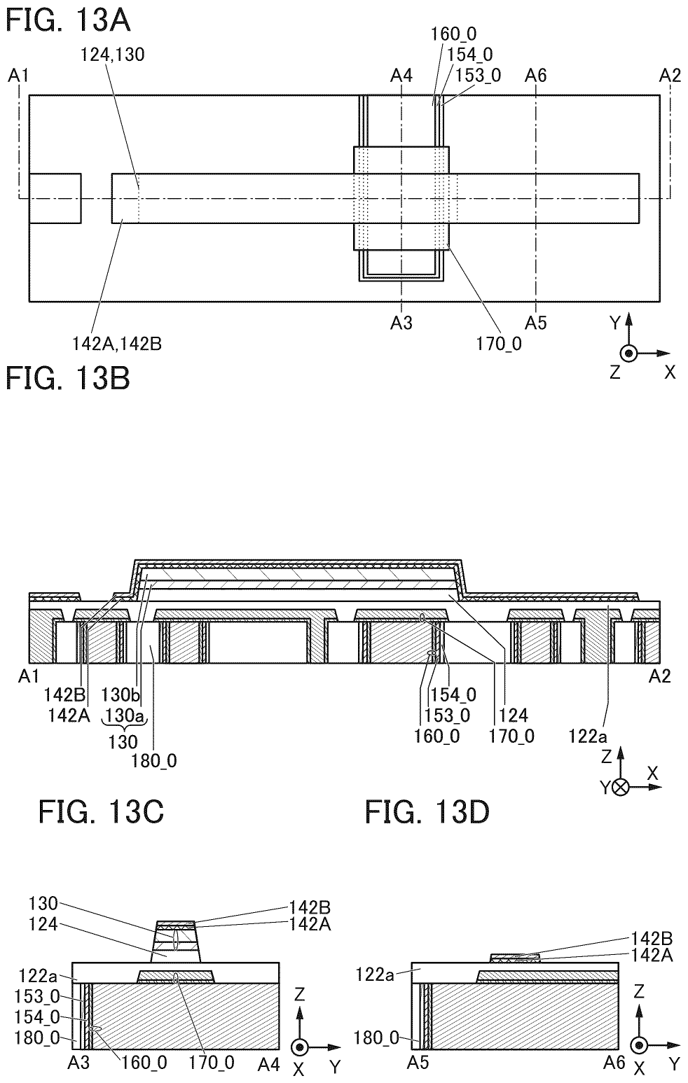

Next, the insulating layer 124A, the oxide layer 130A, the oxide layer 130B, the conductive film 142Af, and the conductive film 142Bf are processed by a lithography method to form a stacked structure including the insulator 124, the oxide 130a, and the oxide 130b that have an island shape and a conductive layer 142A and a conductive layer 142B over the stacked-structure and the insulator 122a (see FIG. 13A to FIG. 13D). For example, the insulating layer 124A, the oxide layer 130A, the oxide layer 130B, the conductive film 142Af, and the conductive film 142Bf are processed to form the insulator 124, the oxide 130a, and the oxide 130b that have an island shape and the conductive layer 142A and the conductive layer 142B that extend in a direction parallel to the dashed-dotted line A1-A2 (the channel length direction of the transistor M1 or the X direction illustrated in FIG. 13A); and then, the conductive layer 142A and the conductive layer 142B are processed to form the conductive layer 142A and the conductive layer 142B that have an island shape.

Here, the insulator 124, the oxide 130a, the oxide 130b, the conductive layer 142A, and the conductive layer 142B are formed to at least partly overlap with the conductor 160_0. The opening provided in the conductive layer 142A and the conductive layer 142B is formed in a position not overlapping with the oxide 130b. A dry etching method or a wet etching method can be used for the processing. Processing by a dry etching method is suitable for microfabrication. Note that the insulating layer 124A, the oxide layer 130A, the oxide layer 130B, the conductive film 142Af, and the conductive film 142Bf may be processed under different conditions.

Furthermore, as illustrated in FIG. 13B to FIG. 13D, the side surfaces of the insulator 124, the oxide 130a, the oxide 130b, the conductive layer 142A, and the conductive layer 142B may have tapered shapes. Each of the insulator 124, the oxide 130a, the oxide 130b, the conductive layer 142A, and the conductive layer 142B may have a taper angle greater than or equal to 60° and less than 90°. With such tapered shapes of the side surfaces, the coverage with the insulator 175 and the like to be performed in a later step can be improved, so that defects such as a void can be reduced.

Note that in this specification and the like, a tapered shape refers to a shape such that at least part of a side surface of a component is inclined to a substrate surface. An angle formed by an inclined side surface and a substrate surface is referred to as a taper angle. Specifically, in this specification and the like, a tapered shape having a taper angle greater than 0° and less than or equal to 90° is referred to as a forward tapered shape, and a tapered shape having a taper angle greater than 90° and less than 180° is referred to as an inverse tapered shape.

Not being limited to the above, the side surfaces of the insulator 124, the oxide 130a, the oxide 130b, the conductive layer 142A, and the conductive layer 142B may substantially perpendicular to the top surface of the insulator 122a. With such a structure, a plurality of transistors M1, a plurality of transistors M2, and a plurality of transistors M3 can be provided with high density in a small area.

A by-product generated in the above etching process is sometimes formed in a layered manner on the side surfaces of the insulator 124, the oxide 130a, the oxide 130b, the conductive layer 142A, and the conductive layer 142B. In that case, the layered by-product is formed between the insulator 175 and the insulator 124, the oxide 130a, the oxide 130b, the conductive layer 142A, and the conductive layer 142B. Hence, the layered by-product formed in contact with the top surface of the insulator 122a is preferably removed.

Note that the insulator 124, the oxide 130a, the oxide 130b, the conductive layer 142A, and the conductive layer 142B are not limited to have the shapes illustrated in FIG. 13A to FIG. 13D and may be processed into other shapes.

Next, the insulator 175 is deposited to cover the insulator 124, the oxide 130a, the oxide 130b, the conductive layer 142A, and the conductive layer 142B (see FIG. 14A to FIG. 14D). Here, it is preferable that the insulator 175 be in contact with the top surface of the insulator 122a and the side surface of the insulator 124. The insulator 175 can be formed by a film-formation method such as a sputtering method, a CVD method, an MBE method, a PLD method, or an ALD method. The insulator 175 is preferably formed using an insulating film having a function of inhibiting passage of oxygen. For example, silicon nitride may be formed as the insulator 175 by an ALD method. Alternatively, as the insulator 175, aluminum oxide may be formed by a sputtering method, and silicon nitride may be formed thereover by a PEALD method. When the insulator 175 has such a stacked-layer structure, the function of inhibiting diffusion of impurities such as water or hydrogen and oxygen is improved in some cases.

In that manner, the oxide 130a, the oxide 130b, the conductive layer 142A, and the conductive layer 142B can be covered with the insulator 175, which has a function of inhibiting diffusion of oxygen. This can reduce direct diffusion of oxygen from the insulator 180 or the like formed later into the insulator 124, the oxide 130a, the oxide 130b, the conductive layer 142A, and the conductive layer 142B in a later step.

Next, an insulating film to be the insulator 180 is formed over the insulator 175 (see FIG. 14A to FIG. 14D). The insulating film can be formed by a film-formation method such as a sputtering method, a CVD method, an MBE method, a PLD method, or an ALD method. A silicon oxide film may be formed by a sputtering method as the insulating film, for example. When the insulating film is formed by a sputtering method in an oxygen-containing atmosphere, the insulator 180 containing excess oxygen can be formed. Note that excess oxygen here refers to, for example, oxygen that is released from the insulator 180 by heat treatment on the insulator 180. By using a sputtering method that does not need to use a molecule containing hydrogen as a deposition gas, the hydrogen concentration in the insulator 180 can be reduced. Note that heat treatment may be performed before the formation of the insulating film. The heat treatment may be performed under reduced pressure, and the insulating film may be successively deposited without exposure to the air. Such treatment can remove moisture and hydrogen adsorbed onto the surface of the insulator 175 and the like, and further can reduce the moisture concentration and the hydrogen concentration in the oxide 130a, the oxide 130b, and the insulator 124. For the heat treatment, the above heat treatment conditions can be used.

For the insulating film to be the insulator 180, a material with a low permittivity is preferably used. Specific examples of the material with a low permittivity include silicon oxynitride, silicon nitride oxide, and silicon nitride, in addition to silicon oxide. Other examples of the material with a low permittivity include silicon oxide to which fluorine is added, silicon oxide to which carbon is added, silicon oxide to which carbon and nitrogen are added, and porous silicon oxide.

Next, the insulating film to be the insulator 180 is subjected to planarization treatment such as a CMP method, so that the insulator 180 with a flat top surface is formed (see FIG. 14A to FIG. 14D). Note that, for example, silicon nitride may be deposited over the insulator 180 by a sputtering method and CMP treatment may be performed on the silicon nitride until the insulator 180 is reached.

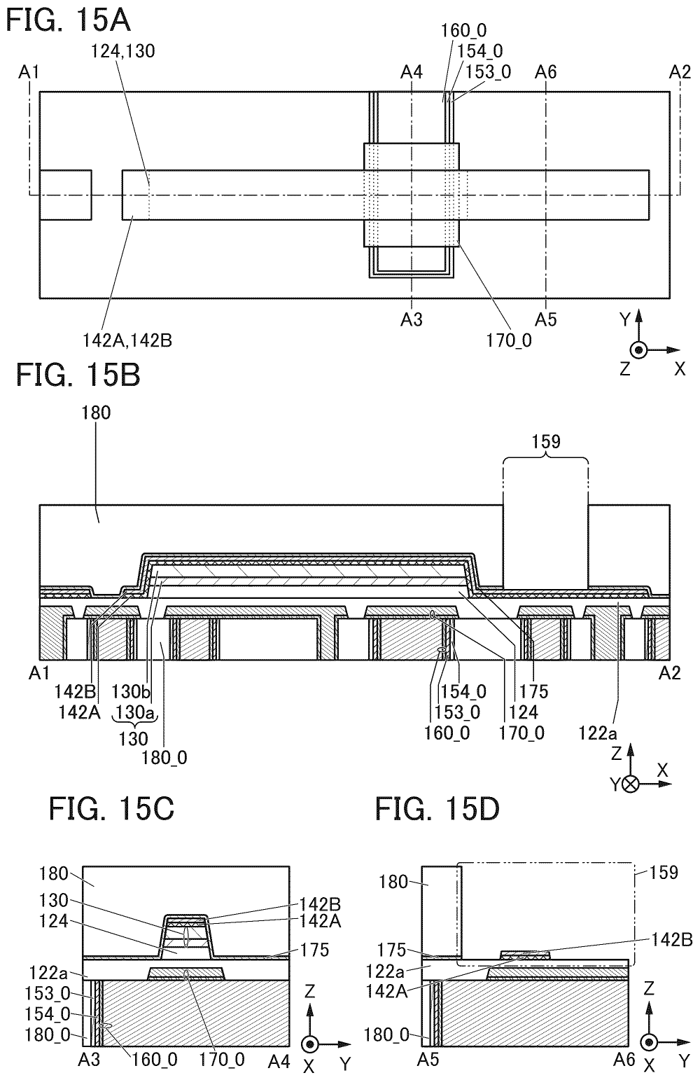

Next, part of the insulator 180 and part of the insulator 175 are processed to form the opening 159 reaching the conductive layer 142B in a region that overlaps with part of the conductive layer 142A and part of the conductive layer 142B and that overlaps with neither the insulator 124 nor the oxide 130 (see FIG. 15A to FIG. 15D).

The part of the insulator 180 and the part of the insulator 175 can be processed by a dry etching method or a wet etching method. The processing may be performed under different conditions. For example, the part of the insulator 180 may be processed by a dry etching method, and the part of the insulator 175 may be processed by a wet etching method.

The opening 159 is preferably formed to extend in a direction parallel to the dashed-dotted line A5-A6 in FIG. 15A (the channel width direction of the transistor or the Y direction illustrated in FIG. 15D). By forming the opening 159 in that manner, the conductor 160_1 to be formed later can be provided to extend in the above-described direction, so that the conductor 160_1 can function as a wiring.

Next, in a region where the conductor 160_0 and the oxide 130 overlap with each other, part of the insulator 180, part of the insulator 175, part of the conductive layer 142A, and part of the conductive layer 142B are processed to form the opening 158_2 reaching the oxide 130b. In regions including the oxide 130, part of the insulator 180, part of the insulator 175, part of the conductive layer 142A, and part of the conductive layer 142B are processed to form the opening 158_3 and the opening 158_4 that reach the oxide 130b, which are different from the opening 158_2.

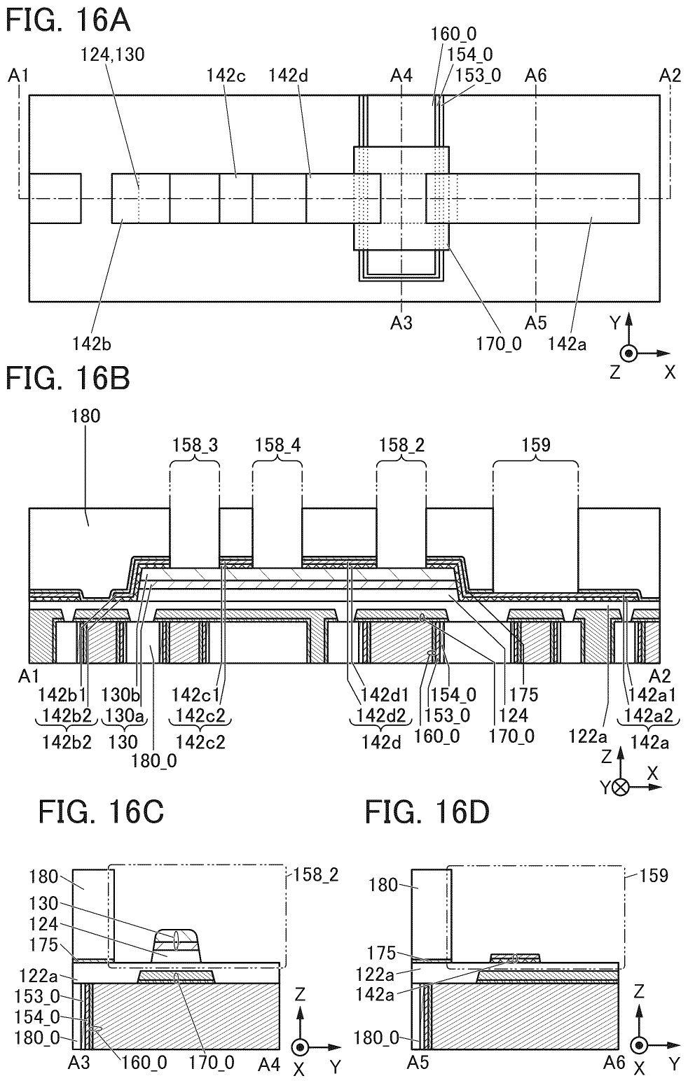

By the formation of the opening 158_2 to the opening 158_4, the conductor 142al, the conductor 142b1, the conductor 142c1, and the conductor 142d1 can be formed from the conductive layer 142A, and the conductor 142a2, the conductor 142b2, the conductor 142c2, and the conductor 142d2 can be formed from the conductive layer 142B (see FIG. 16A to FIG. 16D).

Note that the conductive layer 142A and the conductive layer 142B are hardly processed at the time of forming the opening 159, and the conductive layer 142A and the conductive layer 142B are processed at the time of forming the opening 158_2 to the opening 158_4. In other words, the conditions for forming the opening 159 and the conditions for forming the opening 158_2 to the opening 158_4 are preferably different from each other. Specifically, for example, in the formation of the opening 159, an etching method with high selectivity to the conductor 142 (the conductor 142A and the conductor 142B are collectively referred to as the conductor 142) is preferably used (the etching method uses the conductor 142 as a stop film), and in the formation of the opening 158_2 to the opening 158_4, an etching method with high selectivity to the oxide 130b is preferably used (the etching method uses the oxide 130b as a stop film).

Processing by a dry etching method is suitable for microfabrication. The processing may be performed under different conditions. For example, the part of the insulator 180 may be processed by a dry etching method, the part of the insulator 175 may be processed by a wet etching method, and the part of the conductive layer 142 may be processed by a dry etching method.

The opening 158_2 to the opening 158_4 are preferably formed to extend in a direction parallel to the dashed-dotted line A3-A4 in FIG. 16A (the channel width direction of the transistor or the Y direction illustrated in FIG. 16A). By forming the opening 158_2 to the opening 158_4 in that manner, the conductor 160_2 to the conductor 160_4 to be formed later can be provided to extend in the above-described direction, so that the conductor 160_2 to the conductor 160_4 can function as wirings. In particular, the opening 158_2 is preferably formed to overlap with the conductor 160_0.

The widths of the opening 158_2 to the opening 158_4 are preferably minute because they are reflected in the channel lengths of the transistor M1 to the transistor M3. For example, the width of each of the opening 158_2 to the opening 158_4 is preferably less than or equal to 60 nm, less than or equal to 50 nm, less than or equal to 40 nm, less than or equal to 30 nm, less than or equal to 20 nm, or less than or equal to 10 nm and greater than or equal to 1 nm or greater than or equal to 5 nm. Note that depending on the situation, the widths of the opening 158_2 to the opening 158_4 may each be less than or equal to 1 μm, less than or equal to 0.6 μm, less than or equal to 0.5 μm, less than or equal to 0.4 μm, less than or equal to 0.3 μm, less than or equal to 0.2 μm, or less than or equal to 0.1 μm and greater than or equal to 10 nm or greater than or equal to 50 nm. In order to process the opening 158_2 to the opening 158_4 minutely, a lithography method using an electron beam or short-wavelength light such as EUV light is preferably used.

In the case where the opening 158_2 to the opening 158_4 are processed minutely, the part of the insulator 180, the part of the insulator 175, the part of the conductive layer 142B, and the part of the conductive layer 142A are preferably processed by anisotropic etching. In particular, processing by a dry etching method is suitable for microfabrication and preferable. The processing may be performed under different conditions.

When the insulator 180, the insulator 175, the conductive layer 142B, and the conductive layer 142A are processed by anisotropic etching, side surfaces of the conductor 142a and the conductor 142d that face each other can be formed to be substantially perpendicular to the top surface of the oxide 130b in the transistor M1, for example. Such a structure enables formation of what is called an Loff region in a region of the oxide 130 in the vicinity of an end portion of the conductor 142a and a region of the oxide 130 in the vicinity of an end portion of the conductor 142d. Accordingly, the frequency characteristics of the transistor M1 can be improved, and the operation speed of the semiconductor device of one embodiment of the present invention can be improved. The above description is given for the transistor M1, and applies to the transistor M2 and the transistor M3.

However, without limitation to the above, the side surfaces of the insulator 180, the insulator 175, and the conductor 142 (e.g., the conductor 142a and the conductor 142d) have tapered shapes in some cases. The taper angle of the insulator 180 is larger than that of the conductor 142 in some cases. An upper portion of the oxide 130b is sometimes removed when the opening 158_2 to the opening 158_4 are formed.

By the etching process, impurities may be attached onto the side surface of the oxide 130a, the top surface and the side surface of the oxide 130b, the side surfaces of the conductor 142a to the conductor 142d, the side surface of the insulator 180, and the like or the impurities may be diffused thereinto. A step of removing the impurities may be performed. In addition, a damaged region might be formed on the surface of the oxide 130b by the above dry etching. Such a damaged region may be removed. The impurities result from components contained in the insulator 180, the insulator 175, the conductive layer 142B, and the conductive layer 142A; components contained in a member of an apparatus used to form the opening; and components contained in a gas or a liquid used for etching, for instance. Examples of the impurities include hafnium, aluminum, silicon, tantalum, fluorine, and chlorine.

In particular, impurities such as aluminum and silicon might reduce the crystallinity of the oxide 130b. Thus, it is preferable that impurities such as aluminum and silicon be removed from the surface of the oxide 130b and the vicinity thereof. The concentration of the impurities is preferably reduced. For example, the concentration of aluminum atoms at the surface of the oxide 130b and the vicinity thereof is lower than or equal to 5.0 atomic %, preferably lower than or equal to 2.0 atomic %, further preferably lower than or equal to 1.5 atomic %, still further preferably lower than or equal to 1.0 atomic %, and yet further preferably lower than 0.3 atomic %.

Note that the density of the crystal structure is reduced in the low-crystallinity region of the oxide 130b owing to impurities such as aluminum or silicon; thus, a large amount of V_{O}H (V_{O} refers to oxygen vacancies and V_{O}H refers to defects generated by entry of hydrogen into V_{O}) is formed, and the transistor tends to have normally-on characteristics (a state where a channel is present and a current flows through the transistor even when a voltage is not applied between the gate electrode and the source electrode). Hence, V_{O}H in the low-crystallinity region of the oxide 130b is preferably reduced or removed.

In contrast, the oxide 130b preferably has a layered CAAC structure. In particular, the CAAC structure preferably reaches a lower end portion of a drain in the oxide 130b. Here, in the transistor M1, the conductor 142a or the conductor 142d, and its vicinity function as a drain. In other words, the oxide 130b in the vicinity of the lower end portion of the conductor 142a (conductor 142d) preferably has a CAAC structure. In that manner, the low-crystallinity region of the oxide 130b is removed and the CAAC structure is formed also in the end portion of the drain, which significantly affects the drain withstand voltage, so that a variation in electrical characteristics of the transistors M1 can be further suppressed. In addition, the reliability of the transistor M1 can be improved.

In order to remove impurities and the like attached to the surface of the oxide 130b in the above etching process, cleaning treatment is performed. Examples of the cleaning method include wet cleaning using a cleaning solution or the like (which can also be referred to as wet etching treatment), plasma treatment using plasma, and cleaning by heat treatment, and any of these cleanings may be performed in appropriate combination. Note that the cleaning treatment sometimes makes the groove portion deeper.

In the wet cleaning, an aqueous solution in which one or more selected from ammonia water, oxalic acid, phosphoric acid, and hydrofluoric acid are diluted with carbonated water or pure water can be used. Alternatively, the wet cleaning may be performed using pure water or carbonated water. Alternatively, ultrasonic cleaning using such an aqueous solution, pure water, or carbonated water may be performed. Alternatively, such cleaning methods may be performed in combination as appropriate.

Note that in this specification and the like, in some cases, an aqueous solution in which hydrofluoric acid is diluted with pure water is referred to as diluted hydrofluoric acid, and an aqueous solution in which ammonia water is diluted with pure water is referred to as diluted ammonia water. The concentration, temperature, and the like of the aqueous solution are adjusted as appropriate in accordance with an impurity to be removed, the structure of a semiconductor device to be cleaned, or the like. The concentration of ammonia in the diluted ammonia water is higher than or equal to 0.01% and lower than or equal to 5%, preferably higher than or equal to 0.1% and lower than or equal to 0.5%. The concentration of hydrogen fluoride in the diluted hydrofluoric acid is higher than or equal to 0.01 ppm and lower than or equal to 100 ppm, preferably higher than or equal to 0.1 ppm and lower than or equal to 10 ppm.

For the ultrasonic cleaning, a frequency higher than or equal to 200 kHz is preferable, and a frequency higher than or equal to 900 kHz is further preferable. Damage to the oxide 130b and the like can be reduced with this frequency.

The cleaning treatment may be performed a plurality of times, and the cleaning solution may be changed in every cleaning treatment. For example, first cleaning treatment may use diluted hydrofluoric acid or diluted ammonia water, and second cleaning treatment may use pure water or carbonated water.

As the cleaning treatment in this embodiment, wet cleaning using diluted ammonia water is performed. The cleaning treatment can remove impurities that are attached onto the surfaces of the oxide 130a, the oxide 130b, and the like or diffused into the oxide 130a, the oxide 130b, and the like. Furthermore, the crystallinity of the oxide 130b can be increased.

After the etching or the cleaning, heat treatment may be performed. The heat treatment is performed at higher than or equal to 100° C. and lower than or equal to 450° C., preferably higher than or equal to 350° C. and lower than or equal to 400° C. Note that the heat treatment is performed in a nitrogen gas or inert gas atmosphere, or an atmosphere containing an oxidizing gas at 10 ppm or more, 1% or more, or 10% or more. For example, the heat treatment is preferably performed in an oxygen atmosphere. Accordingly, oxygen can be supplied to the oxide 130a and the oxide 130b to reduce oxygen vacancies. In addition, the crystallinity of the oxide 130b can be improved by such heat treatment. The heat treatment may be performed under reduced pressure. Alternatively, heat treatment may be performed in an oxygen atmosphere, and then heat treatment may be successively performed in a nitrogen atmosphere without exposure to the air.

As the formation order of the opening 158_2 to the opening 158_4 and the opening 159, the opening 159 may be formed after the opening 158_2 to the opening 158_4 are formed. Alternatively, one or more selected from the opening 158_2 to the opening 158_4 and the opening 159 may be formed first and then the others may be formed. Note that the opening 158_2 to the opening 158_4 are preferably formed such that the oxide 130b is exposed at the bottom portion of each of the opening 158_2 to the opening 158_4, and the opening 159 is preferably formed such that the conductor 142a is exposed at the bottom portion of the opening 159. Therefore, the opening 158_2 to the opening 158_4 and the opening 159 are preferably formed by processing methods under different conditions.

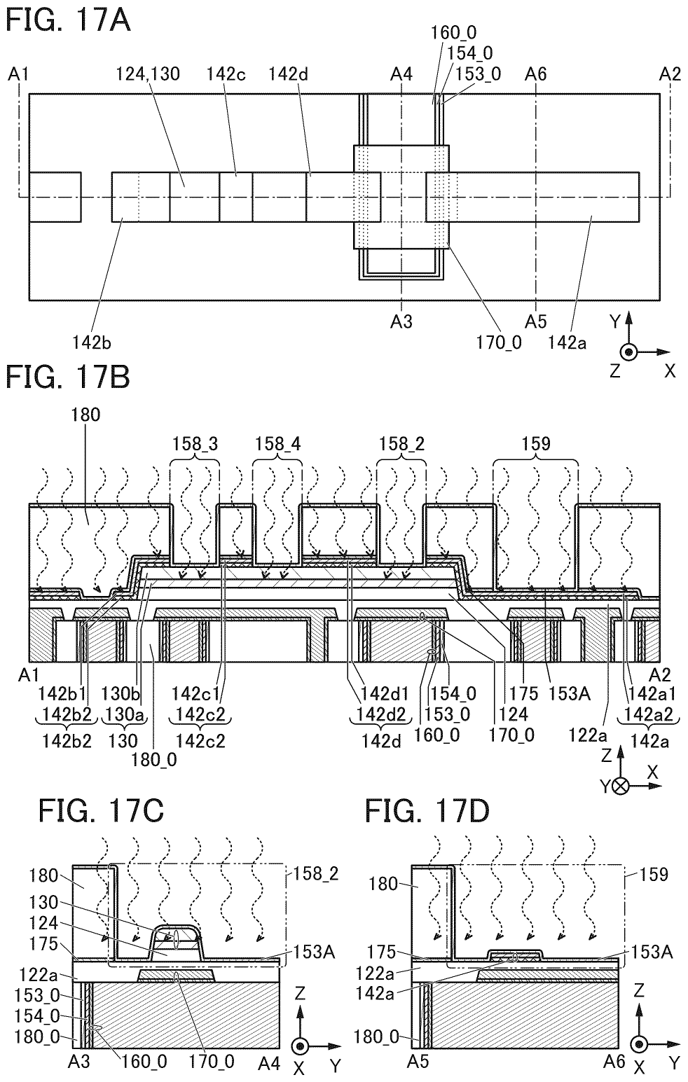

Next, an insulating film 153A is formed (see FIG. 17A to FIG. 17D). The insulating film 153A is an insulating film to be the insulator 153_1 to the insulator 153_4 in a later process. The insulating film 153A can be formed by a film-formation method such as a sputtering method, a CVD method, an MBE method, a PLD method, or an ALD method. The insulating film 153A is preferably formed by an ALD method. In particular, it is preferable to form the insulating film 153A to have a small thickness, and an unevenness of the thickness needs to be reduced. Since an ALD method is a film-formation method in which a precursor and a reactant (e.g., oxidizer) are alternately introduced and the film thickness can be adjusted with the number of repetition times of the cycle, accurate control of the film thickness is possible. Furthermore, as illustrated in FIG. 17B and FIG. 17C, the insulating film 153A with good coverage needs to be formed on the bottom surface and the side surfaces of each of the opening 158_2 to the opening 158_4 and the opening 159. In the opening 158_2 to the opening 158_4, it is preferable that the insulating film 153A with good coverage be formed on the top surface and the side surface of the oxide 130. In addition, in the opening 159, it is preferable that the insulating film 153A with good coverage be formed on the side surface and the top surface of the conductor 142a and the top surface of the insulator 122a. By an ALD method, atomic layers can be formed one by one on the bottom surface and the side surface of each of the opening 158_2 to the opening 158_4, whereby the insulating film 153A with good coverage can be formed in each of the openings.

When the insulating film 153A is formed by an ALD method, ozone (O₃), oxygen (O₂), water (H₂O), or the like can be used as the oxidizer. When an oxidizer not containing hydrogen, such as ozone (O₃) or oxygen (O₂), is used, the amount of hydrogen diffusing into the oxide 130b can be reduced.

In this embodiment, hafnium oxide is deposited as the insulating film 153A by a thermal ALD method.

Alternatively, a high-k material with a high dielectric constant may be used as an insulating material used for the insulating film 153A. Examples of the high-k material with a high dielectric constant include a metal oxide containing one kind or two or more kinds selected from aluminum, gallium, yttrium, zirconium, tungsten, titanium, tantalum, nickel, germanium, and magnesium in addition to the above-described hafnium oxide. Alternatively, any of aluminum oxide, hafnium oxide, and an oxide containing aluminum and hafnium (hafnium aluminate), which are insulators each contain an oxide of one or both of aluminum and hafnium, may be used for the insulating film 153A.

An insulating material such as silicon oxide, silicon oxynitride, or silicon nitride oxide can be used for the insulating film 153A. Alternatively, an insulating material can be used for the insulating film 153A. Examples of the insulating material include silicon oxide to which fluorine is added and silicon oxide to which carbon is added. Alternatively, silicon oxide to which carbon and nitrogen are added can be used for the insulating film 153A. Alternatively, porous silicon oxide can be used for the insulating film 153A. In particular, silicon oxide and silicon oxynitride, which are thermally stable, are preferable. Alternatively, the insulating film 153A may have a stacked-layer structure including two or more selected from the above-described materials.

Next, it is preferable to perform microwave treatment in an atmosphere containing oxygen (see FIG. 17A to FIG. 17D). Here, the microwave treatment refers to, for example, treatment using an apparatus including a power source that generates high-density plasma with the use of a microwave. In this specification and the like, a microwave refers to an electromagnetic wave having a frequency greater than or equal to 300 MHz and less than or equal to 300 GHz. Note that in the case where the insulating film 153A has a stacked-layer structure, the microwave treatment may be performed at the time when the insulating film 153A is partially formed. For example, in the case where the insulating film 153A includes a silicon oxide film or a silicon oxynitride film, the microwave treatment may be performed at the time when the silicon oxide film or the silicon oxynitride film is formed.

Here, dotted-line arrows in FIG. 17B to FIG. 17D indicate high-frequency waves such as microwaves or RF, oxygen plasma, oxygen radicals, or the like. The microwave treatment is preferably performed with a microwave treatment apparatus including a power source for generating high-density plasma using microwaves, for example. Here, the frequency of the microwave treatment apparatus is set to higher than or equal to 300 MHz and lower than or equal to 300 GHz, preferably higher than or equal to 2.4 GHz and lower than or equal to 2.5 GHz, for example, 2.45 GHz. Oxygen radicals at a high density can be generated with high-density plasma. The electric power of the power source that applies microwaves of the microwave treatment apparatus is set to higher than or equal to 1000 W and lower than or equal to 10000 W, preferably higher than or equal to 2000 W and lower than or equal to 5000 W. The microwave treatment apparatus may be provided with a power source that applies RF to the substrate side. Furthermore, application of RF to the substrate side allows oxygen ions generated by the high-density plasma to be introduced into the oxide 130b efficiently. By the effect of the plasma, the microwave, or the like, V_{O}H included in the region of the oxide 130 that does not overlap with the conductor 142a to the conductor 142d can be divided and hydrogen can be removed from the region. That is, V_{O}H contained in the region can be reduced. As a result, oxygen vacancies and V_{O}H in the region can be reduced to lower the carrier concentration. In addition, oxygen radicals generated by the oxygen plasma can be supplied to oxygen vacancies formed in the region, thereby further reducing oxygen vacancies in the region and lowering the carrier concentration.

As illustrated in FIG. 17B to FIG. 17D, the conductor 142a and the conductor 142d block the effect of high-frequency waves such as microwaves or RF, oxygen plasma, or the like, and thus such an effect does not take on the region of the oxide 130b overlapping with the conductor 142a to the conductor 142d. Hence, a reduction in V_{O}H and supply of an excess amount of oxygen due to the microwave treatment do not occur in the region, preventing a decrease in carrier concentration.

The insulating film 153A is provided in contact with the side surfaces of the conductor 142a to the conductor 142d. The insulating film 153A preferably has a barrier property against oxygen, for example. Thus, formation of oxide films on the side surfaces of the conductor 142a to the conductor 142d due to the microwave treatment can be inhibited.

Furthermore, the film quality of the insulator 153A can be improved in the above manner, leading to higher reliability of the transistor M1 to the transistor M3.

In the above manner, oxygen vacancies and V_{O}H can be selectively removed from the region of the oxide 130 not overlapping with the conductor 142a to the conductor 142d, whereby the region can be an i-type or substantially i-type region. Furthermore, supply of excess oxygen to regions of the oxide 130 overlapping with the conductor 142a to the conductor 142d functioning as the source region and the drain region can be inhibited and the conductivity can be maintained. As a result, a change in the electrical characteristics of the transistor M1 to the transistor M3 can be inhibited, and thus a variation in the electrical characteristics of the transistors M1 o the transistor M3 in the substrate plane can be inhibited.

In the microwave treatment, thermal energy is directly transmitted to the oxide 130b in some cases owing to an electromagnetic interaction between the microwaves and molecules in the oxide 130b. The oxide 130b may be heated by this thermal energy. Such heat treatment is sometimes referred to as microwave annealing. When microwave treatment is performed in an oxygen-containing atmosphere, an effect equivalent to that of oxygen annealing is sometimes obtained. In the case where hydrogen is contained in the oxide 130b, the thermal energy may be transmitted to the hydrogen in the oxide 130b and the hydrogen activated by the energy may be released from the oxide 130b.

Note that microwave treatment may be performed before the formation of the insulating film 153A without the microwave treatment performed after the formation of the insulating film 153A.

After the microwave treatment after the formation of the insulating film 153A, heat treatment may be performed under a maintained reduced pressure. Such treatment enables hydrogen in the insulating film 153A, the oxide 130b, and the oxide 130a to be removed efficiently. Part of hydrogen is gettered by the conductor 142 (the conductor 142a to the conductor 142d) in some cases. Alternatively, the step of performing microwave treatment and then performing heat treatment with the reduced pressure being maintained may be repeated a plurality of cycles. The repetition of the heat treatment enables hydrogen in the insulating film 153A, the oxide 130b, and the oxide 130a to be removed more efficiently. Note that the temperature of the heat treatment is preferably higher than or equal to 300° C. and lower than or equal to 500° C. The microwave treatment, i.e., the microwave annealing may also serve as the heat treatment. The heat treatment is not necessarily performed in the case where the oxide 130b and the like are adequately heated by the microwave annealing.

Furthermore, the microwave treatment improves the film quality of the insulating film 153A, thereby inhibiting diffusion of impurities such as hydrogen or water. Accordingly, impurities such as hydrogen and water can be inhibited from diffusing into the oxide 130b, the oxide 130a, and the like through the insulator 153 in a later process such as formation of a conductive film to be the conductor 160_1 to the conductor 160_4 or later treatment such as heat treatment.

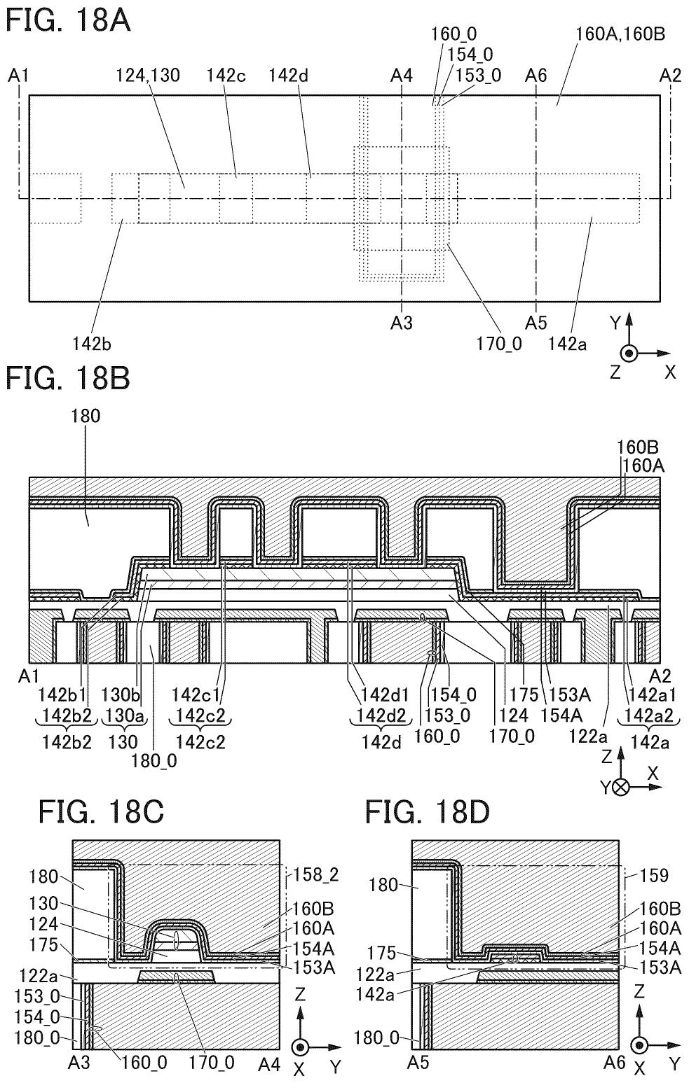

Next, an insulating film 154A to be the insulator 154_1 to the insulator 154_4 is formed (see FIG. 18A to FIG. 18D). The insulating film 154A can be formed by a film-formation method such as a sputtering method, a CVD method, an MBE method, a PLD method, or an ALD method. Like the insulating film 153A, the insulating film 154A is preferably formed by an ALD method. By an ALD method, the insulating film 154A can be formed to have a small thickness and good coverage. In this embodiment, as the insulating film 154A, silicon nitride is deposited by a PEALD method.

Note that an insulating material that is usable for the insulating film 153A may be used for the insulating film 154A.

The same material as the insulating film 153A may be used for the insulating film 154A. That is, in the memory cell MCa, each of the insulator 153_1 to the insulator 153_4 and the insulator 154_1 to the insulator 154_4 may be one insulator.

Next, a conductive film 160A to be the conductor 160a_1 to the conductor 160a_4 and a conductive film 160B to be the conductor 160b_1 and the conductor 160b_4 are formed sequentially (see FIG. 18A to FIG. 18D). The conductive film 160A and the conductive film 160B can be formed by a film-formation method such as a sputtering method, a CVD method, an MBE method, a PLD method, or an ALD method. In this embodiment, titanium nitride is deposited as the conductive film 160A by a CVD method or an ALD method, and tungsten is deposited as the conductive film 160B by a CVD method.

Note that for the conductive film 160A, a conductive material such as tantalum, tantalum nitride, titanium, ruthenium, or ruthenium oxide may be used other than titanium nitride. Alternatively, a stacked-layer structure including two or more selected from the above-described materials may be used for the conductive film 160A. For the conductive film 160B, a conductive material such as copper or aluminum may be used other than tungsten. Alternatively, a stacked-layer structure including two or more selected from the above-described materials may be used for the conductive film 160B.

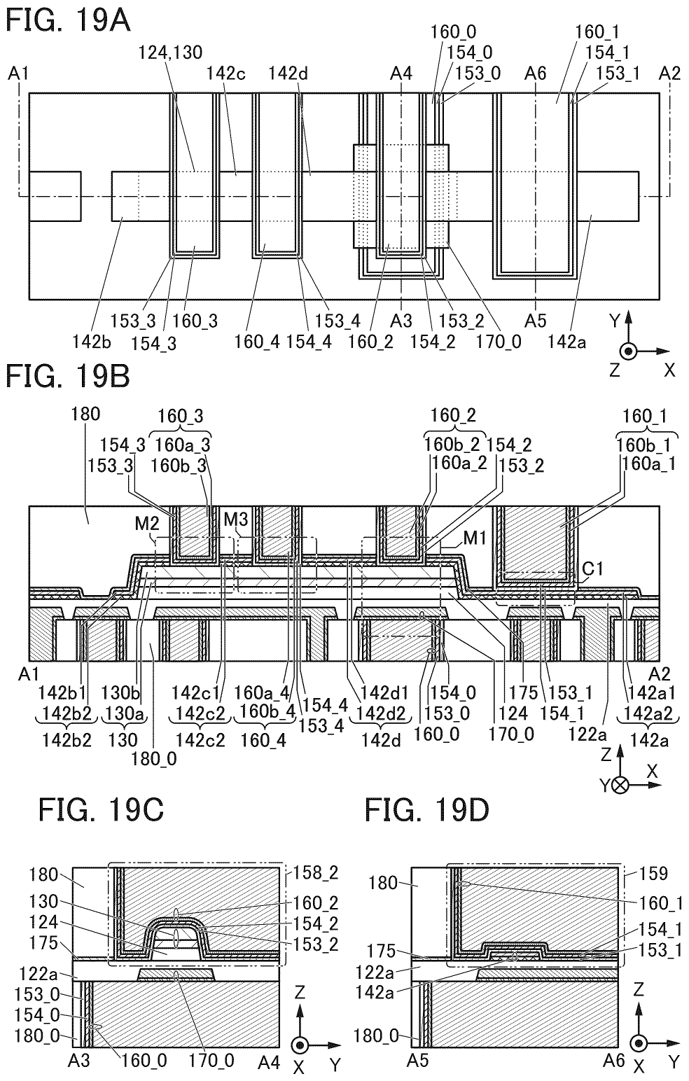

Next, the insulating film 153A, the insulating film 154A, the conductive film 160A, and the conductive film 160B are polished by planarization treatment such as a CMP method until the insulator 180 is exposed. That is, portions of the insulating film 153A, the insulating film 154A, the conductive film 160A, and the conductive film 160B that are exposed from the opening 158_2 to the opening 158_4 and the opening 159 are removed. Accordingly, the insulator 153_2, the insulator 154_2, and the conductor 160_2 (the conductor 160a_2 and the conductor 160b_2) are formed in the opening 158_2; the insulator 153_3, the insulator 154_3, and the conductor 160_3 (the conductor 160a_3 and the conductor 160b_3) are formed in the opening 158_3; and the insulator 153_4, the insulator 154_4, and the conductor 160_4 (the conductor 160a_4 and the conductor 160b_4) are formed in the opening 158_4. The insulator 153_1, the insulator 154_1, and the conductor 160_1 (the conductor 160a_1 and the conductor 160b_1) are formed in the opening 159 (see FIG. 19A to FIG. 19D).

In this manner, the insulator 153_2 is provided in contact with the inner wall and the side surface of the opening 158_2 overlapping with the oxide 130b, and the conductor 160_2 is provided to fill the opening 158_2 with the insulator 153_2 and the insulator 154_2 therebetween. Thus, the transistor M1 is formed. Similarly, the insulator 153_3 is provided in contact with the inner wall and the side surface of the opening 158_3 overlapping with the oxide 130b, and the conductor 160_3 is provided to fill the opening 158_3 with the insulator 153_3 and the insulator 154_3 therebetween. Thus, the transistor M2 is formed. Similarly, the insulator 153_4 is provided in contact with the inner wall and the side surface of the opening 158_4 overlapping with the oxide 130b, and the conductor 160_4 is provided to fill the opening 158_4 with the insulator 153_4 and the insulator 154_4 therebetween. Thus, the transistor M3 is formed.

The insulator 153_1 is provided in contact with the inner wall and the side surface of the opening 159 overlapping with the conductor 142a, and the conductor 160_1 is provided to fill the opening 159 with the insulator 153_1 and the insulator 154_1 therebetween. In that manner, the capacitor C1 is formed.

Then, heat treatment may be performed under conditions similar to those for the above heat treatment. In this embodiment, treatment is performed at 400° C. for one hour in a nitrogen atmosphere. The heat treatment can reduce the moisture concentration and the hydrogen concentration in the insulator 180. After the heat treatment, the conductor 170_1 to the conductor 170_5 described later may be successively deposited without exposure to the air.

Next, in a region that overlaps with the conductor 142a and does not overlap with the insulator 124 or the oxide 130, part of the insulator 180 and part of the insulator 175 are processed, so that an opening 157_3 reaching the conductor 142a is formed. Similarly, part of the insulator 180 and part of the insulator 175 are processed in a region overlapping with the conductor 142d, so that the opening 157_5 reaching the conductor 142d is formed (see FIG. 20A to FIG. 20D).

The part of the insulator 180 and the part of the insulator 175 can be processed by a dry etching method or a wet etching method. Processing by a dry etching method is suitable for microfabrication. The processing may be performed under different conditions. For example, the part of the insulator 180 may be processed by a dry etching method, and the part of the insulator 175 may be processed by a wet etching method.

Alternatively, as a method for forming one or both of the opening 157_3 and the opening 1575, a processing method that enables formation of the opening 158_2 to the opening 158_4 or the opening 159 may be used.

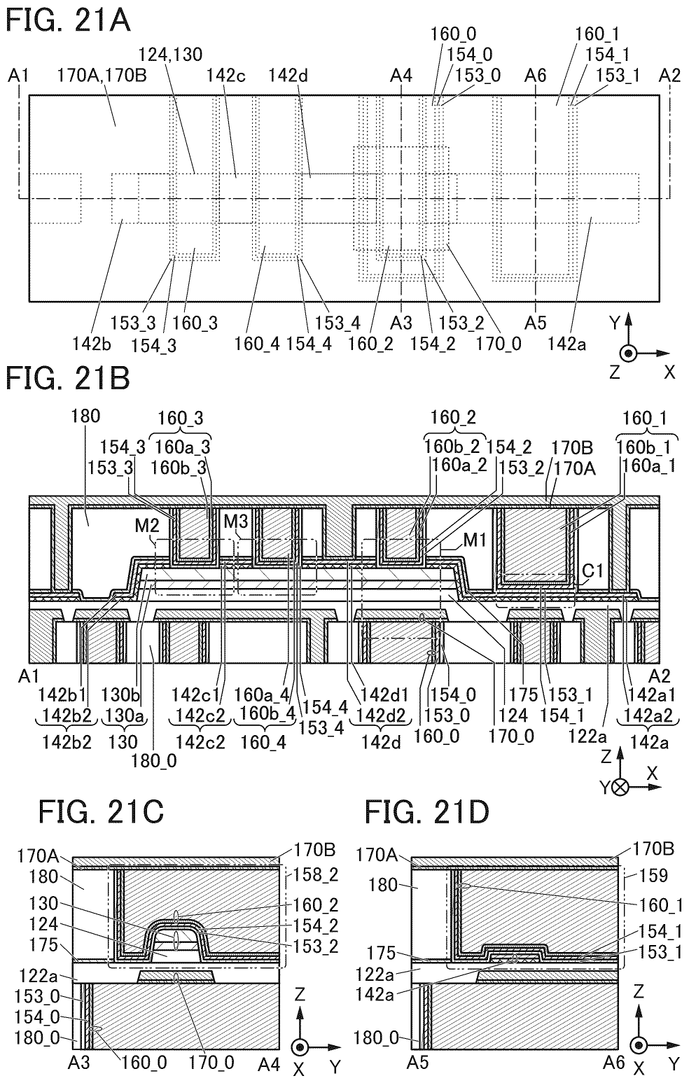

Next, a conductive film 170A to be the conductor 170a_1 to the conductor 170a_5 and a conductive film 170B to be the conductor 170b_1 to the conductor 170b_5 are formed in order over the insulator 153_1 to the insulator 153_4, the insulator 154_1 to the insulator 1544, and the conductor 160_1 to the conductor 160_4 (see FIG. 21A to FIG. 21D). The conductive film 170A and the conductive film 170B can be formed by a sputtering method, a CVD method, an MBE method, a PLD method, an ALD method, or the like. In particular, the conductive film 170A with good coverage is preferably formed on the bottom surfaces and the side surfaces of the opening 157_3 and the opening 157_5. Thus, the conductive film 170A is preferably formed by a CVD method or an ALD method, for example. The conductive film 170B is preferably formed by a CVD method, for example.

Note that a material that is usable for the conductive film 160A can be used for the conductive film 170A. A material that is usable for the conductive film 160B can be used for the conductive film 170B. Note that since the conductive film 170A and the conductive film 170B are processed in a later step, materials used for the conductive film 170A and the conductive film 170B are preferably different from the materials for the conductive film 160A and the conductive film 160B. Specifically, in the case where etching treatment is employed as processing treatment, for example, a material having a higher etching rate than that for the conductor 160_2 is preferably used for the conductive film 170A and the conductive film 170B.

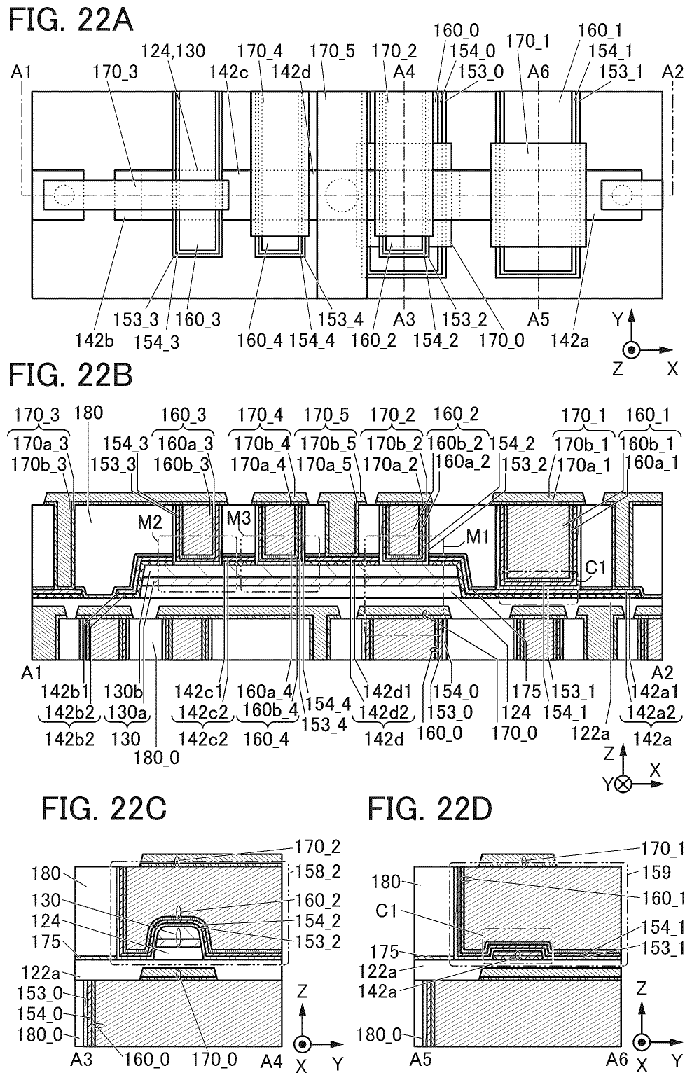

Next, the conductive film 170A and the conductive film 170B are processed by a lithography method to form the island-shaped conductor 170_1 (the conductor 170a_1 and the conductor 170b_1), the island-shaped conductor 1702 (the conductor 170a_2 and the conductor 170b_2), the island-shaped conductor 170_3 (the conductor 170a_3 and the conductor 170b_3), the island-shaped conductor 170_4 (the conductor 170a_4 and the conductor 170b_4), and the island-shaped conductor 170_5 (the conductor 170a_5 and the conductor 170b_5) (see FIG. 22A to FIG. 22D). In particular, this processing makes the conductor 170_3 a wiring that establishes electrical conduction between the conductor 142a of the transistor M1 and the conductor 160_3 of the transistor M3.

Next, the insulator 122b is formed over the insulator 180, over the insulator 153_1 to the insulator 153_4, over the insulator 1541 to the insulator 154_4, over the conductor 160_1 to the conductor 160_4, and over the conductor 170_1 to the conductor 170_5 (see FIG. 8A to FIG. 8D). The insulator 122b can be formed by a film-formation method such as a sputtering method, a CVD method, an MBE method, a PLD method, or an ALD method. For example, hafnium oxide with a reduced hydrogen concentration is preferably deposited as the insulator 122b by an ALD method, like in the case of the insulator 122a.

Note that for another material and another formation method of the insulator 122b, the description of the insulator 122a is referred to.

In addition, the transistor M1, the transistor M2, the transistor M3, and the capacitor C1 included in the memory layer ALYb are sometimes formed over the insulator 122b in a later step. Therefore, planarization treatment such as a CMP method is preferably performed on the insulator 122b.

Through the above process, the semiconductor device including the memory cell MCa illustrated in FIG. 2 or FIG. 3 can be manufactured. As illustrated in FIG. 9A to FIG. 22D, with the use of the method for manufacturing a semiconductor device described in this embodiment, the capacitor C1 and the transistor M1 to the transistor M3 can be manufactured in the same process. This can decrease the number of manufacturing steps of the semiconductor device including the capacitor C1 and the transistor M1 to the transistor M3.

In the semiconductor device including the memory cell MCa illustrated in FIG. 2 or FIG. 3, the area occupied by the memory cell can be small. In other words, the recording density of the semiconductor device can be increased.

Note that the method for manufacturing a semiconductor device of one embodiment of the present invention is not limited to that illustrated in FIG. 8A to FIG. 22D. The materials and steps in the method for manufacturing a semiconductor device may be changed depending on the situation.

Note that this embodiment can be combined with any of the other embodiments in this specification as appropriate. For example, the configurations, structures, methods, and the like described in this embodiment can be used in an appropriate combination with any of the configurations, structures, methods, and the like described in the other embodiments and the like.

### Embodiment 2

In this embodiment, a semiconductor device having a structure different from the structure of the semiconductor device described in the above embodiment will be described.

### <Circuit Structure Example of Semiconductor Device>

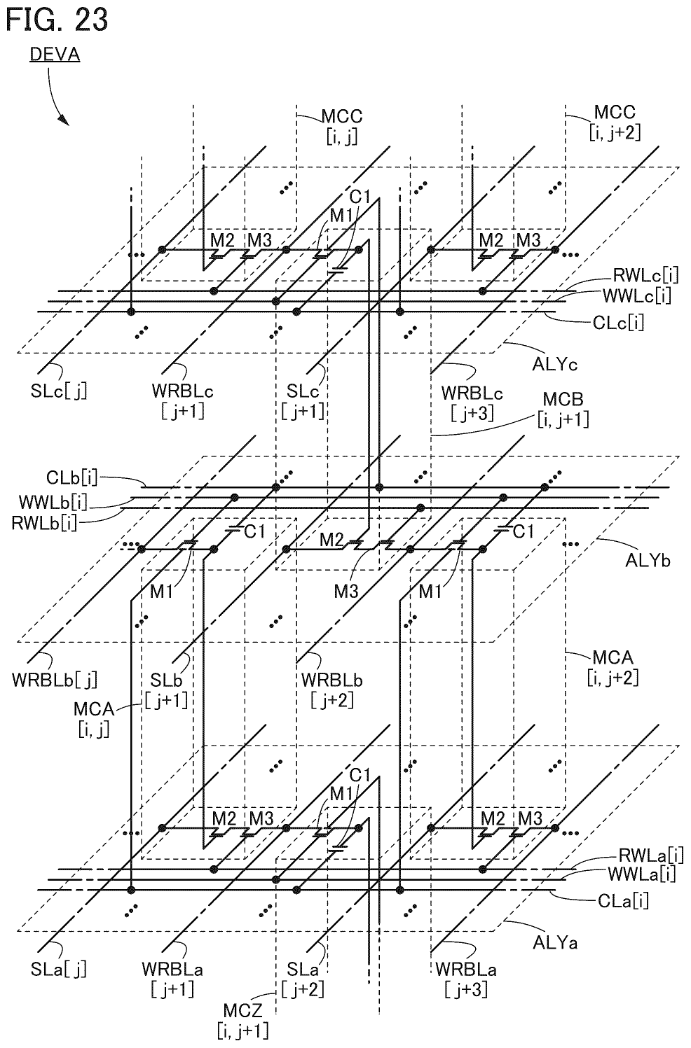

FIG. 23 is a circuit diagram illustrating a structure example of a semiconductor device DEVA of one embodiment of the present invention. The semiconductor device DEVA includes a plurality of memory layers in an example. FIG. 23 illustrates the memory layer ALYa, the memory layer ALYb, and the memory layer ALYc as an example of the plurality of memory layers. In addition, the memory layer ALYb is located above the memory layer ALYa and the memory layer ALYc is located above the memory layer ALYb. A memory layer different from the memory layer ALYb and the memory layer ALYc may be located below the memory layer ALYa, and a memory layer different from the memory layer ALYa and the memory layer ALYb may be located above the memory layer ALYc.

The semiconductor device DEVA includes a plurality of memory cells. In particular, the memory layer ALYa and the memory layer ALYb share a plurality of memory cells MCA, and the memory layer ALYb and the memory layer ALYc share a plurality of memory cells MCB. The memory layer ALYa and a memory layer located below the memory layer ALYa share a plurality of memory cells MCZ, and the memory layer ALYc and a memory layer located above the memory layer ALYc share a plurality of memory cells MCC. In FIG. 23, for example, the memory cell MCA[i,j] and the memory cell MCA[i,j+2] are illustrated as the memory cells MCA, the memory cell MCB[i,j+1] is illustrated as the memory cell MCB, a memory cell MCZ[i,j+1] is illustrated as the memory cell MCZ, and a memory cell MCC[i,j] and a memory cell MCC[i,j+2] are illustrated as the memory cells MCC. Note that i and j will be described later.

The plurality of memory cells MCA are arranged in an array in the memory layer ALYa and the memory layer ALYb in an example. For example, in FIG. 23, the memory cells MCA are arranged in a matrix of N memory cells (here, N is an integer greater than or equal to 1) in the row direction and M memory cells (here, M is an integer greater than or equal to 1) in the column direction, that is, M×N memory cells MCA are arranged in matrix. Similarly, the plurality of memory cells MCB are arranged in a M×N matrix in the memory layer ALYb and the memory layer ALYc, the plurality of memory cells MCC are arranged in a M×N matrix in the memory layer ALYc and the memory layer located above the memory layer ALYc, and the plurality of memory cells MCZ are arranged in a M×N matrix in the memory layer ALYa and the memory layer located below the memory layer ALYa, for example.

Here, the memory cell MCA is a memory cell located at the i-th row and the 2k−1-th column (k is an integer greater than or equal to 1 and less than or equal to N) in the memory layer ALYa and the memory layer ALYb. The memory cell MCB is a memory cell located at the i-th row and the 2k-th column in the memory layer ALYb and the memory layer ALYc. The memory cell MCC is a memory cell located at the i-th row and the 2k−1-th column in the memory layer ALYc and the memory layer above the memory layer ALYc. The memory cell MCZ is a memory cell located at the i-th row and the 2k-th column in the memory layer ALYa and the memory layer below the memory layer ALYa.

Note that in FIG. 23, i is an integer greater than or equal to 1 and less than or equal to M. Furthermore, j is a number satisfying 2k−1=j or 2k−1=j+2. In this case, j illustrated in FIG. 23 is an odd number greater than or equal to 1 and less than or equal to 2N−3. At this time, j+1 shown in FIG. 23, satisfying 2k=j+1, is an even number greater than or equal to 2 and less than or equal to 2N−2.

The transistor M2 and the transistor M3 are placed at the i-th row and the 2k−1-th column in the memory layer ALYa. That is, in FIG. 23, the transistor M2 and the transistor M3 are placed at each of the i-th row and the j-th column and the i-th row and the j+2-th column in the memory layer ALYa. The transistor M1 and the capacitor C1 are placed at the i-th row and the 2k−1-th column in the memory layer ALYb. In other words, in FIG. 23, the transistor M1 and the capacitor C1 are placed at each of the i-th row and the j-th column and the i-th row and the j+2-th column in the memory layer ALYb.

Basically, in the memory layer ALYa and the memory layer ALYb, the memory cell MCA[i, j] includes the transistor M2 and the transistor M3 at the i-th row and the j-th column in the memory layer ALYa, and the transistor M1 and the capacitor C1 at the i-th row and the j-th column in the memory layer ALYb. The memory cell MCA[i,j+2] includes the transistor M2 and the transistor M3 at the i-th row and the j+2-th column in the memory layer ALYa and the transistor M1 and the capacitor C1 at the i-th row and the j+2-th column in the memory layer ALYb.

The transistor M2 and the transistor M3 are placed at the i-th row and the 2k-th column in the memory layer ALYb. That is, in FIG. 23, the transistor M2 and the transistor M3 are placed at the i-th row and the j+1-th column in the memory layer ALYb. The transistor M1 and the capacitor C1 are placed at the i-th row and the 2k-th column in the memory layer ALYc. That is, in FIG. 23, the transistor M1 and the capacitor C1 are placed at the i-th row and the j+1-th column in the memory layer ALYc.

Basically, in the memory layer ALYb and the memory layer ALYc, the memory cell MCB[i,j+1] includes the transistor M2 and the transistor M3 in the i-th row and the j+1-th column in the memory layer ALYb and the transistor M1 and the capacitor C1 in the i-th row and the j+1-th column in the memory layer ALYc.

Similarly, in the memory layer ALYc and the memory layer above the memory layer ALYc, the memory cell MCC includes the transistor M2 and the transistor M3 placed at the memory layer ALYc and the transistor M1 and the capacitor C1 placed in the memory layer located above the memory layer ALYc. Similarly, in the memory layer ALYa and the memory layer located below the memory layer ALYa, the memory cell MCC includes the transistor M1 and the capacitor C1 placed in the memory layer ALYa and the transistor M2 and the transistor M3 placed in the memory layer located below the memory layer ALYa.

Note that the transistor M1 to the transistor M3 and the capacitor C1 described in Embodiment 1 can be referred to for the transistor M1 to the transistor M3 and the capacitor C1 included in the semiconductor device DEVA in FIG. 23.

In each of the memory cell MCA, the memory cell MCB, the memory cell MCC, and the memory cell MCZ included in the semiconductor device DEVA in FIG. 23, the first terminal of the transistor M1 is electrically connected to the gate of the transistor M2 and the first terminal of the capacitor C1. The first terminal of the transistor M2 is electrically connected to the first terminal of the transistor M3.

That is, the memory cell MCA, the memory cell MCB, the memory cell MCC, and the memory cell MCZ included in the semiconductor device DEVA in FIG. 23 each have a gain cell structure, which is referred to as a NOSRAM (registered trademark) described in Embodiment 1.

In FIG. 23, the wiring SLa is extended in the 2k−1-th column in the memory layer ALYa. Specifically, the wiring SLa[j] is extended in the j-th column and a wiring SLa[j+2] is extended in the j+2-th column in the memory layer ALYa. The wiring SLb is extended in the 2k-th column in the memory layer ALYb. Specifically, the wiring SLb[j+1] is extended in the j+1-th column in the memory layer ALYb. A wiring SLc is extended in the 2k−1-th column in the memory layer ALYc. Specifically, a wiring SLc[U] is extended in the j-th column and a wiring SLc[j+2] is extended in the j+2-th column in the memory layer ALYc.

In FIG. 23, the wiring WRBLa is extended in the 2k-th column in the memory layer ALYa. Specifically, the wiring WRBLa[j+1] is extended in the j+1-th column in the memory layer ALYa. The wiring WRBLb is extended in the 2k−1-th column in the memory layer ALYb. Specifically, the wiring WRBLb[j] is extended in the j-th column and the wiring WRBLb[j+2] is extended in the j+2-th column in the memory layer ALYb. A wiring WRBLc is extended in the 2k-th column in the memory layer ALYc. Specifically, a wiring WRBLc[j+1] is extended in the j+1-th column in the memory layer ALYc. In FIG. 23, for convenience, a wiring WRBLa[j+3] is extended in the memory layer ALYa, and a wiring WRBLc[j+3] is extended in the memory layer ALYc.

In FIG. 23, the wiring WWLa[i], the wiring RWLa[i], and the wiring CLa[i] are extended in the i-th row in the memory layer ALYa. In the i-th row in the memory layer ALYb, the wiring WWLb[i], the wiring RWLb[i], and the wiring CLb[i] are extended. In the i-th row in the memory layer ALYc, the wiring WWLc[i], the wiring RWLc[i], and the wiring CLc[i] are extended.

Note that in FIG. 23, the wiring WWLa functions as a write word line for the memory cell MCZ, the wiring WWLb functions as a write word line for the memory cell MCA, and the wiring WWLc functions as a write word line for the memory cell MCB. The wiring RWLa functions as a read word line for the memory cell MCA, the wiring WWLb functions as a read word line for the memory cell MCB, and the wiring WWLc functions as a read word line for the memory cell MCC. The wiring WRBLa functions as a write bit line for the memory cell MCZ and functions as a read bit line for the memory cell MCA. The wiring WRBLb functions as a write bit line for the memory cell MCA and functions as a read bit line for the memory cell MCB. The wiring WRBLc functions as a write bit line for the memory cell MCB and functions as a read bit line for the memory cell MCC.

For the description of signals (e.g., potentials or currents) transmitted to the wiring WWLa to the wiring WWLc, the wiring RWLa to the wiring RWLc, and the wiring WRBLa to the wiring WRBLc, the description of signals transmitted to the wiring WWLa, the wiring WWLb, the wiring RWLa, the wiring RWLb, the wiring WRBLa, and the wiring WRBLb described in Embodiment 1 can be referred to.

In FIG. 23, the wiring SLa functions as a wiring for supplying a fixed potential to the memory cell MCA and the memory cell MCZ, the wiring SLb functions as a wiring for supplying a fixed potential to the memory cell MCA and the memory cell MCB, and the wiring SLc functions as a wiring for supplying a fixed potential to the memory cell MCB and the memory cell MCC.

Note that the wiring CLa to the wiring CLc may each function as a wiring for supplying a variable potential depending on the situation.

In the memory cell MCA[i,j], the second terminal of the transistor M1 is electrically connected to the wiring WRBLb[U], the gate of the transistor M1 is electrically connected to the wiring WWLb[i], and the back gate of the transistor M1 is electrically connected to the wiring CLa[i]. The second terminal of the capacitor C1 is electrically connected to the wiring CLb[i]. A second terminal of the transistor M2 is electrically connected to the wiring SLa[j]. The second terminal of the transistor M3 is electrically connected to the wiring WRBLa[j+1], and the gate of the transistor M3 is electrically connected to the wiring RWLa[i].

Similarly, in the memory cell MCB[i,j+1], the second terminal of the transistor M1 is electrically connected to the wiring WRBLc[j+1], the gate of the transistor M1 is electrically connected to the wiring WWLc[i], and the back gate of the transistor M1 is electrically connected to the wiring CLb[i]. The second terminal of the capacitor C1 is electrically connected to the wiring CLc[i]. The second terminal of the transistor M2 is electrically connected to the wiring SLb[j+1]. The second terminal of the transistor M3 is electrically connected to the wiring WRBLb[j+2], and the gate of the transistor M3 is electrically connected to the wiring RWLb[i].

Next, data writing to the memory cell MCA to the memory cell MCC and the memory cell MCZ and data reading from the memory cell MCA to the memory cell MCC and the memory cell MCZ in the semiconductor device DEVA illustrated in FIG. 23 are described. Here, as an example, data writing to the memory cell MCA[i,j] and data reading from the memory cell MCA[i,j] in the memory layer ALYa and the memory layer ALYb in the semiconductor device DEVA are described.

To write data to the memory cell MCA[i,j] in the semiconductor device DEVA illustrated in FIG. 23, first, a first potential (e.g., a ground potential) is supplied to the wiring CLb[i], for example. Next, a high-level potential is supplied to the wiring WWLb[i] to turn on the transistor M1 included in the memory cell MCA[i,j], and a low-level potential is supplied to the wiring WWLb[1] to the wiring WWLb[m] excluding the wiring WWLb[i] to turn off the transistors M1 included in the memory cells MCA at the first row to the m-th row excluding the i-th row. A low-level potential is supplied to the wiring RWLa[1] to the wiring RWLa[m] to turn off the transistors M3 included in all the memory cells MCA.

Then, data for writing is transmitted to the wiring WRBLb[j], and a potential corresponding to the data is written to the first terminal of the capacitor C1 of the memory cell MCA[i,j]. After the data writing to the first terminal of the capacitor C1 of the memory cell MCA[i,j], a low-level potential is supplied to the wiring WWLb[i] to turn off the transistor M1 included in the memory cell MCA[i,j]. Accordingly, the operation of writing data to the memory cell MCA[i,j] ends.

To read data from the memory cell MCA[i,j] in the semiconductor device DEV illustrated in FIG. 23, a second potential (e.g., a high-level potential higher than the first potential) is supplied to the wiring WRBLa[j+1] first. After that, a high-level potential is supplied to the wiring RWLa[i] to turn on the transistor M3 included in the memory cell MCA[i,j]. At this time, in the case where the transistor M2 in the memory cell MCA[i,j] operates in a saturation region, a current corresponding to the gate-source voltage of the transistor M2 (a potential difference between the potential of the gate of the transistor M2 and the potential of the wiring SLa[j]) flows. Thus, the current flows from the wiring WRBLa[j+1] to the wiring SLa[j] through the transistor M2. By inputting the current flowing through the wiring WRBLa[j+1] to the reading circuit, data written to the memory cell MCA[i,j] can be read. Note that although data written to the memory cell MCA[i,j] is read from the amount of current here, data written to the memory cell MCA[i,j] may be read from a change in the voltage of the wiring WRBLa[j+1].

Note that data wiring to and data reading from other memory cells MCA, other memory cells MCB, other memory cells MCC, and other memory cells MCZ can also be performed in a similar manner to the above operation.

Note that the circuit structure of the semiconductor device of one embodiment of the present invention is not limited to the structure in FIG. 23. The circuit structure of the semiconductor device may be changed depending on the situation.

For example, the number of each of the memory cells MCA, the memory cells MCB, the memory cells MCC, and the memory cells MCZ is M×N in FIG. 23; alternatively, the number of each of the memory cells MCA and the memory cells MCC may be M×N and the number of each of the memory cells MCB and the memory cells MCC may be M×N−1. Specifically, the number of columns of the memory cells MCA may be Nin the memory layer ALYa and the memory layer ALYb; the number of columns of the memory cells MCC may be Nin the memory layer ALYc and the memory layer located above the memory layer ALYc; and the number of columns of the memory cells MCB may be N−1 in the memory layer ALYb and the memory layer ALYc; and the number of columns of the memory cells MCZ may be N−1 in the memory layer ALYa and the memory layer located below the memory layer ALYa.

### <Cross-Sectional Structure Example of Semiconductor Device>

Next, a structure example of the semiconductor device DEVA is described.

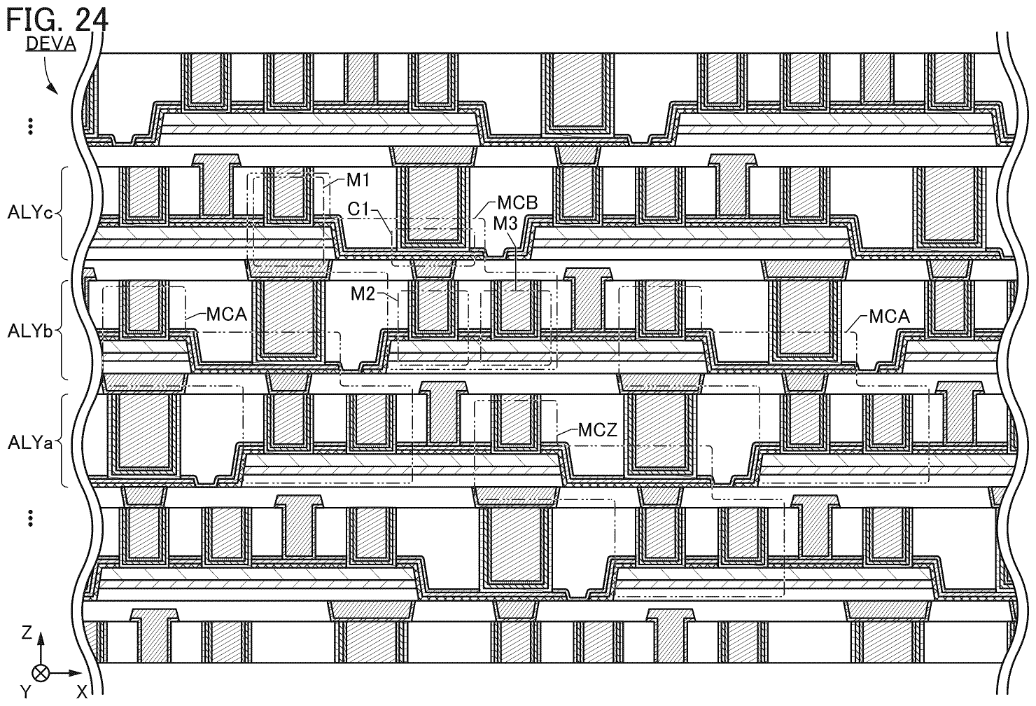

FIG. 24 is a schematic cross-sectional view illustrating a structure example of the semiconductor device DEVA of one embodiment of the present invention. In FIG. 24, the semiconductor device DEVA includes not only the memory layer ALYa, the memory layer ALYb, and the memory layer ALYc but also the memory layer located above the memory layer ALYc and the memory layer located below the memory layer ALYa.

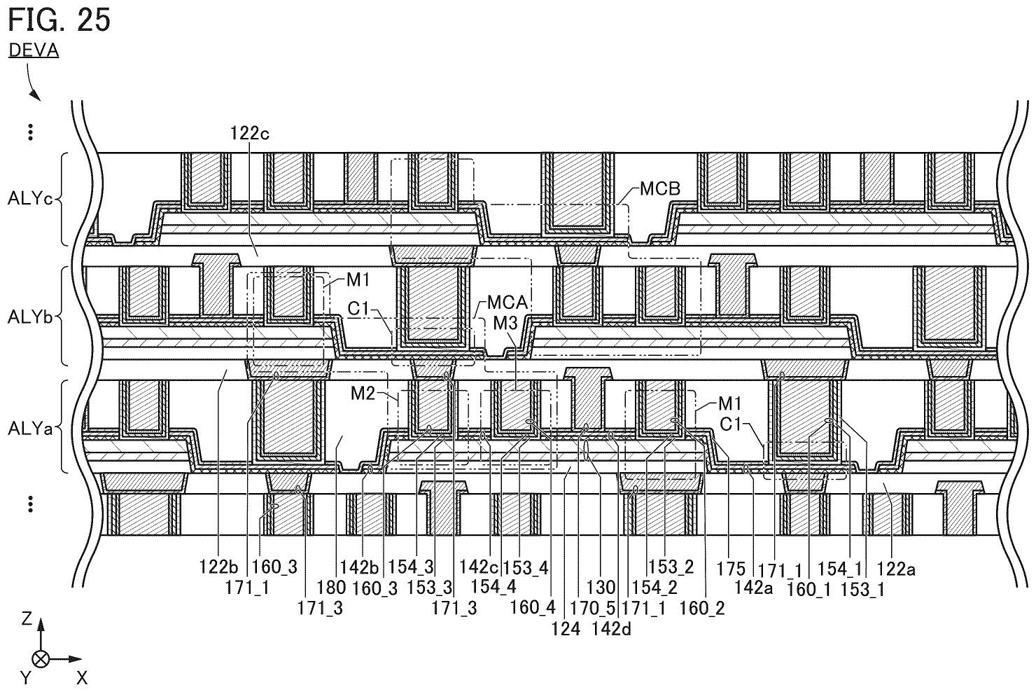

FIG. 25 is a schematic cross-sectional view mainly illustrating the memory layer ALYa and the memory layer ALYb in the structure example of the DEVA of the semiconductor device in FIG. 24, and in the schematic cross-sectional view illustrated in FIG. 25, reference numerals showing components in the memory layer ALYa, the memory layer ALYb, and the memory layer ALYc are shown as an example.

Note that FIG. 25 illustrates a structure example in which the memory layer ALYa is provided over the insulator 122a, the insulator 122b is provided over the memory layer ALYa, the memory layer ALYb is provided over the insulator 122b, an insulator 122c is provided over the memory layer ALYb, and the memory layer ALYc is provided over the insulator 122c. For the insulator 122a to the insulator 122c, the insulator 122a and the insulator 122b described in Embodiment 1 can be referred to.

The X direction shown in FIG. 24 to FIG. 31 is parallel to the channel length directions of the transistor M1, the transistor M2, and the transistor M3, the Y direction is perpendicular to the X direction, and the Z direction is perpendicular to the X direction and the Y direction. The X direction, the Y direction, and the Z direction shown in FIG. 24 to FIG. 31 form a right-handed system.

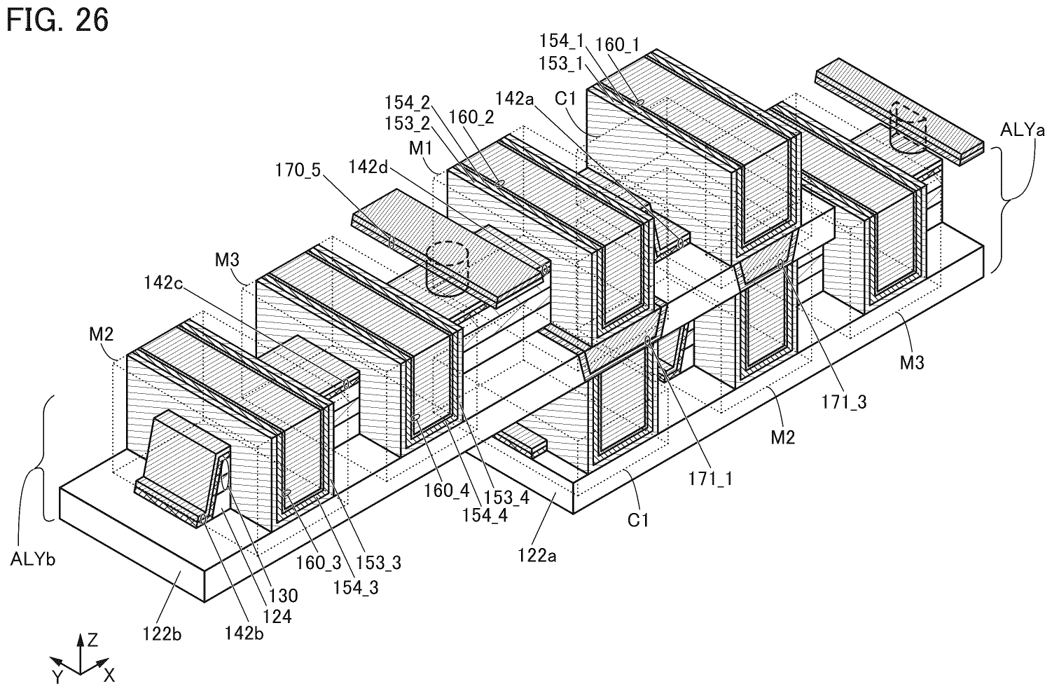

FIG. 26 is a schematic perspective view illustrating an example of structures of part of the memory layer ALYa and part of the memory layer ALYb of the semiconductor device DEV in FIG. 24. Note that in FIG. 26, the insulator 180 and the insulator 175 are not illustrated so that the structures in the memory layer ALYa and the memory layer ALYb can be seen easily. For the details of the insulator 180 and the insulator 175, the insulator 180 and the insulator 175 described in Embodiment 1 can be referred to.

In the memory layer ALYa in FIG. 26, the conductor 1601, the conductor 160_2, the conductor 160_3, the conductor 160_4, and the conductor 170_5, which are described later, are extended in the Y direction, for example.

In the memory layer ALYa and the memory layer ALYb illustrated in FIG. 24 and FIG. 25, the memory cell MCA is provided above the insulator 122a.

As described in the circuit structure example, the memory cell MCA includes the transistor M1, the transistor M2, the transistor M3, and the capacitor CL. In particular, the transistor M2 and the transistor M3 are provided above the insulator 122a, and the transistor M1 and the capacitor C1 are provided above the insulator 122b. Note that in FIG. 24 and FIG. 25, the transistor M1 to the transistor M3 are OS transistors, for example. That is, the semiconductor layer of each of the transistor M1 to the transistor M3 includes a metal oxide.

Next, components of the semiconductor device DEVA are described. For simple description, the memory layer ALYa in FIG. 25 is focused on here. The description of contents overlapping with the semiconductor device DEV illustrated in FIG. 2 and FIG. 3 described in Embodiment 1 is omitted in some cases.

In the memory layer ALYa illustrated in FIG. 24 and FIG. 25, each of the transistor M1 to the transistor M3 includes the insulator 124 and the oxide 130. The transistor M1 includes the conductor 142a, the conductor 142d, the conductor 160_2, the insulator 153_2, and the insulator 154_2. The transistor M2 includes the conductor 142b, the conductor 142c, the conductor 160_3, the insulator 153_3, and the insulator 154_3. The transistor M3 includes the conductor 142c, the conductor 142d, the conductor 160_4, the insulator 153_4, and the insulator 154_4. The capacitor C1 includes the conductor 142a, the conductor 160_1, the insulator 153_1, and the insulator 154_1.

The transistor M1 also includes a conductor 171_1 embedded in the insulator 122a.

Each of the conductor 160_2 to the conductor 160_4 is provided to overlap with a region including the oxide 130, for example. The conductor 160_2 functions as the gate of the transistor M1, the conductor 160_3 functions as the gate of the transistor M2, and the conductor 160_4 functions as the gate of the transistor M3. Note that the gates are each referred to as a first gate in some cases. In this specification and the like, the conductor 160_2 to the conductor 160_4 are each referred to as a gate electrode or a first gate electrode in some cases. The conductor 160_2 functions as the wiring WWLa[i] in FIG. 23, for example. The conductor 160_4 functions as the wiring RWLa[i] in FIG. 23, for example.

The insulator 153 and the insulator 154_2 function as the first gate insulating film of the transistor M1. The insulator 153_3 and the insulator 154_3 function as the first gate insulating film of the transistor M2. The insulator 153_4 and the insulator 154_4 function as the first gate insulating film of the transistor M3.

The insulator 124 is provided over the insulator 122a. The insulator 122a and the insulator 124 function as a second gate insulating film of the transistor M1.

The oxide 130 is provided over the insulator 124, for example. Each of the conductor 160_2 to the conductor 160_4 is provided to overlap with a region including the oxide 130. The oxide 130 functions as a semiconductor included in the channel formation region of each of the transistor M1 to the transistor M3.

The conductor 171_1 embedded in the insulator 122a functions as the back gate (sometimes referred to as a second gate) of the transistor M1. Therefore, in this specification and the like, the conductor 171_1 is referred to as a back gate electrode or a second gate electrode in some cases. The conductor 171_1 also functions as one of a pair of electrodes of a capacitor included in a memory cell of the memory layer located below the memory layer ALYa.

Note that in FIG. 25, as in the memory layer ALYa, the conductor 160_2 to the conductor 160_4, the insulator 153 (the insulator 153_2 to the insulator 153_4), the insulator 154 (the insulator 154_2 to the insulator 154_4), and the insulator 180 are provided in the memory layer located below the memory layer ALYa. In the memory layer located below the memory layer ALYa, the conductor 160_2 to the conductor 160_4, the insulator 153, and the insulator 154 are embedded in the insulator 180. In particular, the conductor 160_1, the insulator 153_1, and the insulator 154_1 are located below the conductor 171_1 embedded in the insulator 122a.

For the conductor 142a, the conductor 142b, the conductor 142c, the conductor 142d, and the insulator 175, the description of the conductor 142a, the conductor 142b, the conductor 142c, the conductor 142d, and the insulator 175 described in Embodiment 1 can be referred to.

In particular, the conductor 170_5 is provided over the conductor 142d. The conductor 170_5 functions as the wiring WRBLa[j+1] or the wiring WRBLa[j+3] in FIG. 23, for example.

The conductor 142b functions as, for example, a conductor electrically connected to the wiring SLa[j] or the wiring SLa[j+2] in FIG. 23 or the wiring SLa.

A conductor 171_3 embedded in the insulator 122a is located below a region overlapping with the conductor 142a and not overlapping with the oxide 130. The conductor 171_3 embedded in the insulator 122a functions as a wiring for electrically connecting the insulator 122a included in the memory layer ALYa and the conductor 160_3 included in the memory layer located below the memory layer ALYa.

In the region overlapping with the conductor 142a and not overlapping with the oxide 130, the insulator 153_1, the insulator 154_1, and the conductor 160_1 are provided in order. In particular, the capacitor C1 is formed in a region where the conductor 142a and the conductor 160_1 overlap with each other. That is, part of the conductor 142a functions as one of a pair of electrodes of the capacitor C1, and part of the conductor 160_1 functions as the other of the pair of electrodes of the capacitor CL.

The conductor 171_1 is located above the conductor 160_1. In particular, the conductor 171_1 is embedded in the insulator 122b. The conductor 171_1 embedded in the insulator 122b also functions as the back gate electrode of the transistor M1 included in the memory layer ALYb.

Although the conductor 171_1 embedded in the insulator 122b is located above the insulator 153_1 and the insulator 154_1 in FIG. 25, the conductor 171_1 embedded in the insulator 122b is located above the conductor 1601, but it need not be located above the insulator 153_1 or the insulator 154_1.

The conductor 171_3 is located above the conductor 160_3. In particular, the conductor 171_3 is embedded in the insulator 122b. The conductor 171_3 embedded in the insulator 122b functions as a wiring for electrically connecting the conductor 160_3 included in the memory layer ALYa and the conductor 142a included in the memory layer ALYb.

Note that in FIG. 25, the conductor 171_1 embedded in the insulator 122b may also be located above the insulator 153_1 and the insulator 154_1.

The conductor 171_1 and the conductor 171_3 can be formed using the same conductive material. Note that a specific conductive material that can be used for the conductor 171_1 and the conductor 171_3 will be described later.

The conductor 171_1 and the conductor 1713 may be formed in different steps or concurrently in the same step.

As illustrated in FIG. 24 and FIG. 25, when the semiconductor device DEVA is formed, a conductor corresponding to the back gate electrode of the transistor M1 in the memory layer ALYb and a conductor corresponding to the other of the pair of electrodes of the capacitor C1 in the memory layer ALYa can be formed concurrently. That is, the structure illustrated in FIG. 24 and FIG. 25 offers the following advantages: the number of photomasks for manufacturing the semiconductor device DEVA is reduced as compared with that in the case of a conventional structure, and the manufacturing process of the semiconductor device DEVA is shortened.

The structure of the semiconductor device DEVA in FIG. 24 may be changed depending on the situation.

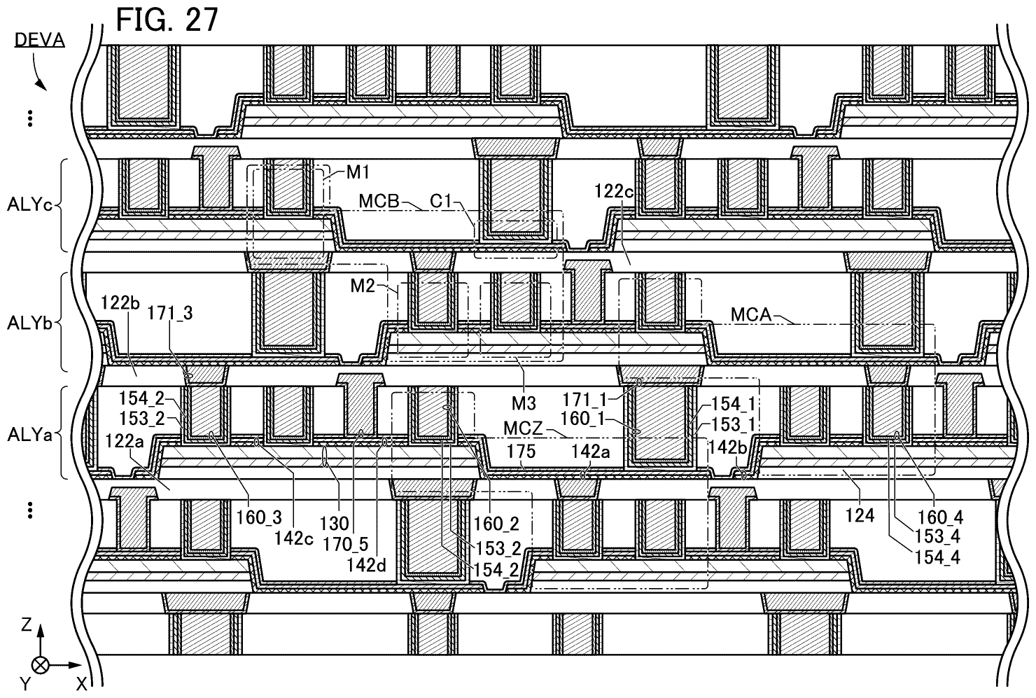

The structure of the semiconductor device DEVA in FIG. 24 (FIG. 25) may be changed to that of the semiconductor device DEVA illustrated in FIG. 27, for example. The semiconductor device DEVA in FIG. 27 is different from the semiconductor device DEVA in FIG. 24 (FIG. 25) in that the conductor 160_3 included in the memory layer ALYb and 171_3 embedded in the insulator 122c do not overlap with the conductor 160_1 in the memory layer ALYc, for example. That is, in the semiconductor device DEVA in FIG. 27, the transistor M2 in the lower memory layer and the capacitor C1 in the upper memory layer do not overlap with each other. The structure of the semiconductor device DEVA in FIG. 27 can give greater circuit design flexibility for leading wirings and the like than that of the semiconductor device DEVA in FIG. 24 (FIG. 25) in some cases.

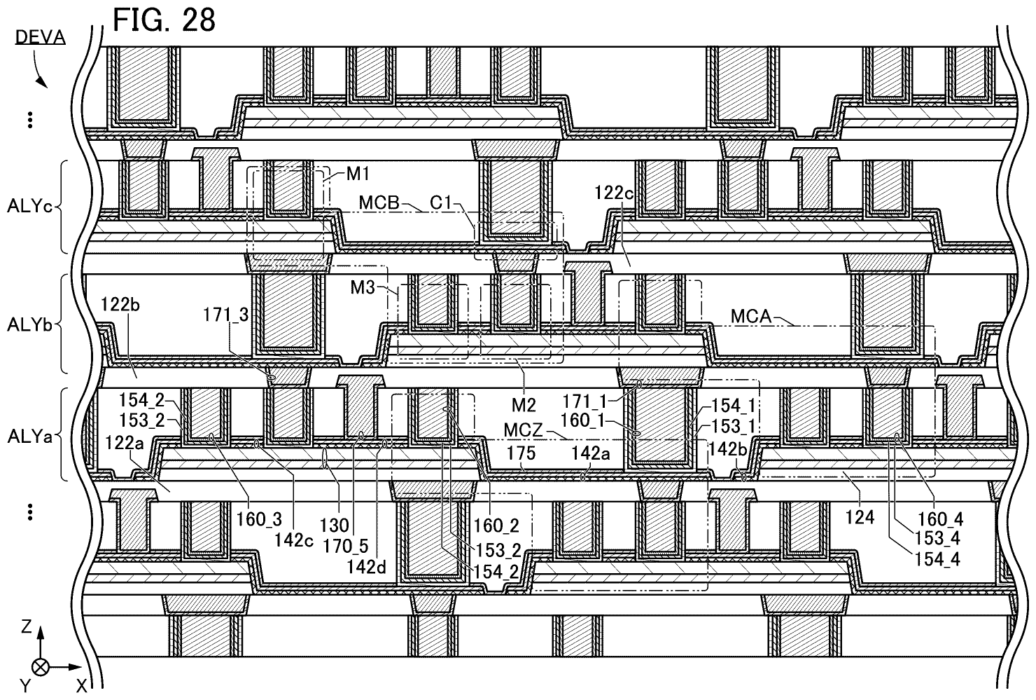

The structure of the semiconductor device DEVA in FIG. 24 (FIG. 25) may be changed to that of the semiconductor device DEVA illustrated in FIG. 28, for example. The semiconductor device DEVA in FIG. 28 is different from the semiconductor device DEVA in FIG. 24 (FIG. 25) in that the conductor 160_4 included in the memory layer ALYb and 171_3 embedded in the insulator 122c overlap with the conductor 160_1 in the memory layer ALYc, for example. In other words, in the semiconductor device DEVA in FIG. 28, the positions of the transistor M2 and the transistor M3 formed with the oxide 130 in the semiconductor device DEVA in FIG. 24 (FIG. 25) are interchanged with each other. The semiconductor device DEVA in FIG. 28 has a structure in which the transistor M2 and the transistor M3 in the circuit diagram in FIG. 23 are interchanged with each other. Also in the structure of the semiconductor device DEVA in FIG. 28, data writing and data reading can be performed as in the structure of the semiconductor device DEVA in FIG. 24 (FIG. 25).

As illustrated in FIG. 24 and FIG. 25, for example, the other of the pair of electrodes of the capacitor C1 in the memory layer ALYa is used in common with the back gate electrode of the transistor M1 in the memory layer ALYb, whereby the area occupied by the memory cell MCA (the memory cell MCB, the memory cell MCC, and the memory cell MCZ) can be reduced. Accordingly, the semiconductor device can be scaled down or highly integrated, resulting in an increase in memory density.

When three transistors are formed in one oxide 130 as illustrated in FIG. 24 and FIG. 25, the area occupied by the transistors can be reduced. That is, the area occupied by the memory cells can be reduced, so that the semiconductor device can be miniaturized or highly integrated, resulting in an increase in memory density.

### <Example of Manufacturing Method of Semiconductor Device>>

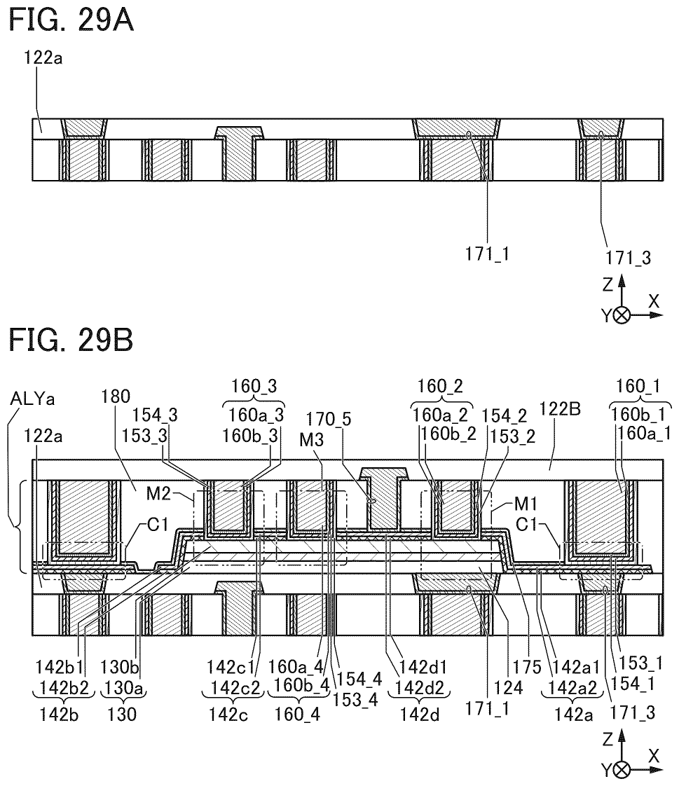

Next, an example of a method for manufacturing the memory layer ALYa of the semiconductor device DEVA illustrated in FIG. 24 and FIG. 25 is described. Referring to FIG. 29A to FIG. 31, the example of the manufacturing method is described.

FIG. 29A to FIG. 31 are schematic cross-sectional views. In particular, FIG. 29A to FIG. 31 are each a schematic cross-sectional view of the transistor M1 to the transistor M3 in the channel length direction.

Note that in description for the manufacturing method of the semiconductor device DEVA illustrated in FIG. 24 and FIG. 25, description of contents overlapping with the description of the manufacturing method of the semiconductor device DEV illustrated in FIG. 2 and FIG. 3 described in Embodiment 1 is omitted in some cases.

First, a substrate (not illustrated) is prepared, and the memory layer below the memory layer ALYa is formed over the substrate. For example, an insulator and a conductor that are included in the memory layer below the memory layer ALYa are formed over the substrate. The insulator and the conductor can be formed using the same materials as those of the insulator 180, the insulator 153_1 to the insulator 153_4, the insulator 154_1 to the insulator 154_4, the conductor 160_1 to the conductor 160_4, the conductor 170_5, the insulator 122a, the conductor 1711, and the conductor 171_3 included in the memory layer ALYa. By the formation of the insulator and the conductor, the transistor M1 to the transistor M3 and the capacitor C1 are formed in the memory layer below the memory layer ALYa.

Next, an insulating film to be the insulator 122a is formed to cover the insulator and the conductor. After that, in the insulating film, an opening reaching the gate electrode is provided in a region overlapping with the gate electrode of the transistor M2, and an opening reaching an upper electrode is provided in a region overlapping with the upper electrode of a pair of electrodes of the capacitor C1, whereby the insulator 122a is formed (see FIG. 29A). For the insulator 122a, the description of the insulator 122a in Embodiment 1 can be referred to.

The conductor 171_3 is embedded in an opening of the insulator 122a that overlaps with the gate electrode of the transistor M2. The conductor 171_1 is embedded in an opening of the insulator 122a that overlaps with the upper electrode of the pair of electrodes of the capacitor C1 (see FIG. 29A). Note that the conductor 171_1 and the conductor 171_3 will be described later.

Next, the transistor M1 to the transistor M3 and the capacitor C1 are formed over the insulator 122a and over the conductor 1711, and the conductor 171_3 according to the formation method illustrated in FIG. 10A to FIG. 19D (see FIG. 29B).

According to the manufacturing method illustrated in FIG. 20A to FIG. 20D, an opening reaching the conductor 142d is provided in a region of the insulator 180 overlapping with the conductor 142d (corresponding to the opening 1575 in FIG. 20B).

Furthermore, according to the formation method illustrated in FIG. 21A to FIG. 22D, the conductor 170_5 is formed in the above-described opening (see FIG. 29B). Note that as illustrated in FIG. 29B, the conductor 170_5 may also be formed over part of the insulator 180.

After that, an insulating film 122B to be the insulator 122b is formed to cover the insulator 153_1 to the insulator 153_4, the insulator 154_1 to the insulator 154_4, the conductor 160_1 to the conductor 160_4, the insulator 180, and the conductor 170_5 (see FIG. 29B). For the formation method of the insulating film 122B, the description of the insulator 122b in Embodiment 1 can be referred to.

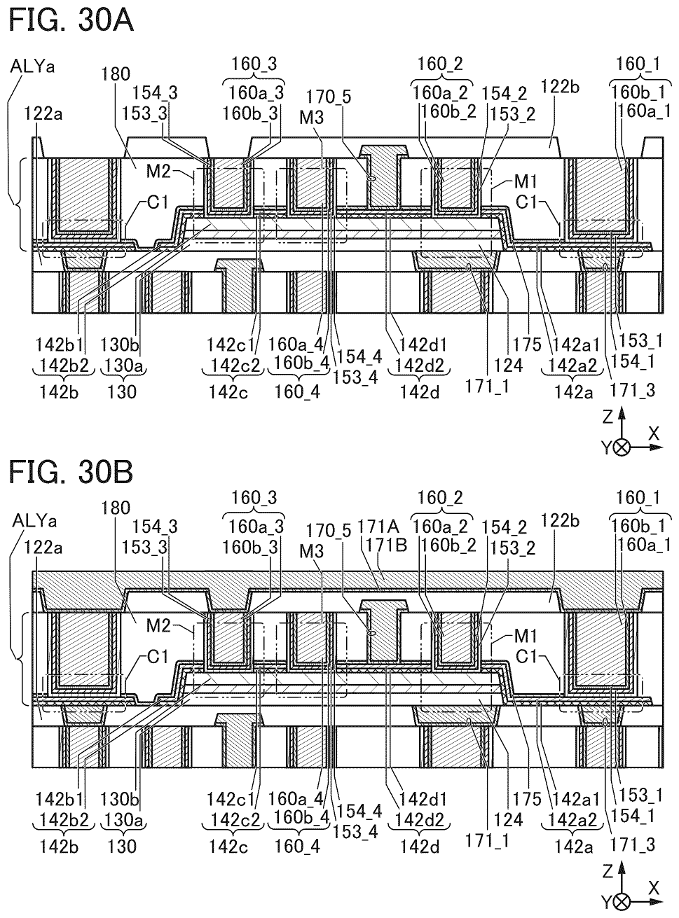

Next, the insulating film 122B is processed to form the insulator 122b having openings in a region overlapping with the conductor 160_1 included in the memory layer ALYa and a region overlapping with the conductor 160_3 included in the memory layer ALYa (see FIG. 30A). A dry etching method or a wet etching method can be used for the processing.

The conductive film 171A and the conductive film 171B are formed in order over the insulator 122b and in the opening over the insulator 122b (see FIG. 30B). Note that the conductive film 171A and the conductive film 171B are preferably formed successively without being exposed to an atmospheric environment. By formation without exposure to the atmospheric environment, impurities or moisture from the atmospheric environment can be prevented from being attached onto the conductive film 171A and the conductive film 171B, so that the vicinity of the interface between the conductive film 171A and the conductive film 171B can be kept clean.

The conductive film 171A and the conductive film 171B can be formed by a film-formation method such as a sputtering method, a CVD method, an MBE method, a PLD method, or an ALD method. In this embodiment, the conductive film 171A and the conductive film 171B are formed by a CVD method.

For the conductive film 171A, any of the materials usable for the conductor 160a_1 to the conductor 160a_4 can be used, for example. For the conductive film 171B, any of the materials usable for the conductor 160b_1 to the conductor 160b_4 can be used, for example.

Materials that are usable for the conductive film 171A and the conductive film 171B may be used interchangeably. Alternatively, the same material may be used for the conductive film 171A and the conductive film 171B. That is, the conductive film 171A and the conductive film 171B may be one conductor.

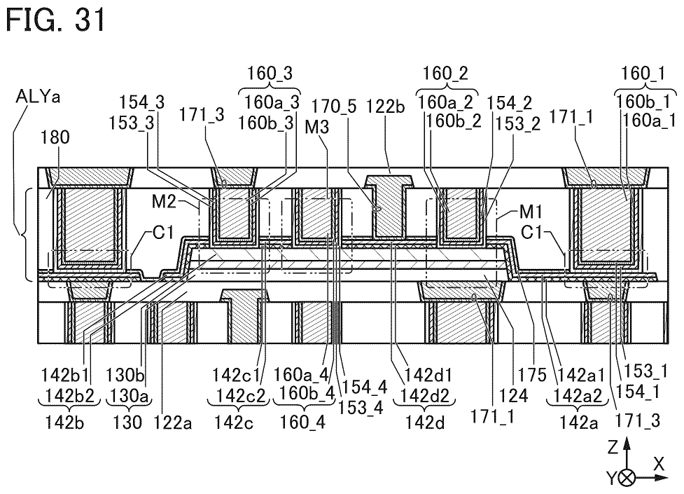

Next, the conductive film 171A and the conductive film 171B are polished by planarization treatment such as a CMP method until the insulator 122b is exposed. That is, the conductive film 171A and the conductive film 171B in portions exposed from the openings of the insulator 122b are removed. In this manner, the conductor 171_3 is formed in the opening of the insulator 122b overlapping with the conductor 160_3 included in the memory layer ALYa, and the conductor 171_1 is formed in the opening of the insulator 122b overlapping with the conductor 160_1 included in the memory layer ALYa (see FIG. 31).

After the formation of the conductor 171_1 and the conductor 1713, the heat treatment described in Embodiment 1 may be performed.

As described above, the manufacturing method illustrated in FIG. 29A to FIG. 31 is employed, whereby the memory layer ALYa of the semiconductor device DEVA can be formed. In the case where the memory layer ALYb is formed over the insulator 122b, the transistor M1 to the transistor M3 and the capacitor C1 can be formed according to the manufacturing method illustrated in FIG. 29A to FIG. 31.

Note that the method for manufacturing a semiconductor device of one embodiment of the present invention is not limited to that illustrated in FIG. 29A to FIG. 31. The materials and steps in the method for manufacturing a semiconductor device may be changed depending on the situation.

Note that this embodiment can be combined with any of the other embodiments in this specification as appropriate. For example, the configurations, structures, methods, and the like described in this embodiment can be used in an appropriate combination with any of the configurations, structures, methods, and the like described in the other embodiments and the like.

### Embodiment 3

In this embodiment, a structure example of a memory device including the semiconductor device described in the above embodiment is described.

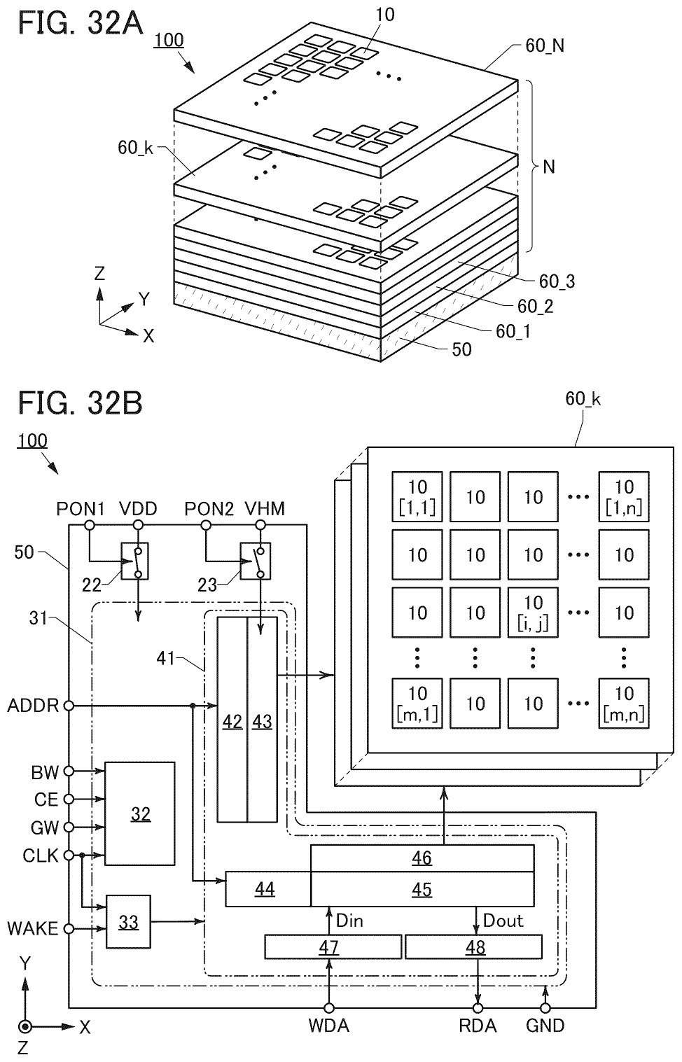

FIG. 32A is a schematic perspective view illustrating a structure example of a memory device 100. FIG. 32B is a block diagram illustrating the structure example of the memory device 100. The memory device 100 includes a driver circuit layer 50 and N(Nis a integer of 1 or more) memory layers 60. One memory layer 60 includes a plurality of memory cells 10 arranged in a matrix of m rows and n columns. Note that FIG. 32B illustrates an example where a memory cell 10[1,1], a memory cell 10[m,1] (here, m is an integer of 1 or more), a memory cell 10[1,n] (here, n is an integer of 1 or more), a memory cell 10[m,n], and a memory cell 10[i,j] (here, i is an integer greater than or equal to 1 and less than or equal to m, and j is an integer greater than or equal to 1 and less than or equal to n) are provided in a memory layer 60_k.

Note that the memory layer 60 corresponds to the memory layer ALYa, the memory layer ALYb, or the memory layer ALYc described in Embodiment 1. The memory cell 10 corresponds to the memory cell MCa or the memory cell MCb described in Embodiment 1. The plurality of memory layers 60 may include the memory layer ALYa to the memory layer ALYc described in Embodiment 2.

The N memory layers 60 are provided over the driver circuit layer 50. Provision of the N memory layers 60 over the driver circuit layer 50 can reduce the area occupied by the memory device 100. Furthermore, memory capacity per unit area can be increased.

In this embodiment and the like, the first memory layer 60 is denoted by a memory layer 601, the second memory layer 60 is denoted by a memory layer 602, and the third memory layer 60 is denoted by a memory layer 603. Furthermore, the k-th memory layer 60 (k is an integer greater than or equal to 1 and less than or equal to N) is denoted by a memory layer 60_k, and the N-th memory layer 60 is denoted by a memory layer 60_N. Note that in this embodiment and the like, the simple term “memory layer 60” is sometimes used in the case of describing a matter related to all the N memory layers 60 or showing a matter common to the N memory layers 60.

### <Structure Example of Driver Circuit Layer 50>

The driver circuit layer 50 includes a PSW 22 (power switch), a PSW 23, and a peripheral circuit 31. The peripheral circuit 31 includes a peripheral circuit 41, a control circuit 32, and a voltage generation circuit 33.

In the memory device 100, each circuit, each signal, and each voltage can be appropriately selected as needed. Alternatively, another circuit or another signal may be added. A signal BW, a signal CE, a signal GW, a signal CLK, a signal WAKE, a signal ADDR, a signal WDA, a signal PON1, and a signal PON2 are signals input from the outside, and a signal RDA is a signal output to the outside. The signal CLK is a clock signal.

The signal BW, the signal CE, and the signal GW are control signals. The signal CE is a chip enable signal, the signal GW is a global write enable signal, and the signal BW is a byte write enable signal. The signal ADDR is an address signal. The signal WDA is write data, and the signal RDA is read data. The signal PON1 and the signal PON2 are power gating control signals. Note that the signal PON1 and the signal PON2 may be generated in the control circuit 32.

The control circuit 32 is a logic circuit having a function of controlling the entire operation of the memory device 100. For example, the control circuit performs a logical operation on the signal CE, the signal GW, and the signal BW to determine an operation mode (e.g., a writing operation or a reading operation) of the memory device 100. The control circuit 32 generates a control signal for the peripheral circuit 41 so that the operation mode is executed.

The voltage generation circuit 33 has a function of generating a negative voltage. The signal WAKE has a function of controlling the input of the signal CLK to the voltage generation circuit 33. For example, when an H-level signal is supplied as the signal WAKE, the signal CLK is input to the voltage generation circuit 33, and the voltage generation circuit 33 generates a negative voltage.

The peripheral circuit 41 is a circuit for writing and reading data to/from the memory cells 10. The peripheral circuit 41 includes a row decoder 42, a column decoder 44, a row driver 43, a column driver 45, an input circuit 47, an output circuit 48, and a sense amplifier 46.

The row decoder 42 and the column decoder 44 have a function of decoding the signal ADDR. The row decoder 42 is a circuit for specifying a row to be accessed, and the column decoder 44 is a circuit for specifying a column to be accessed.

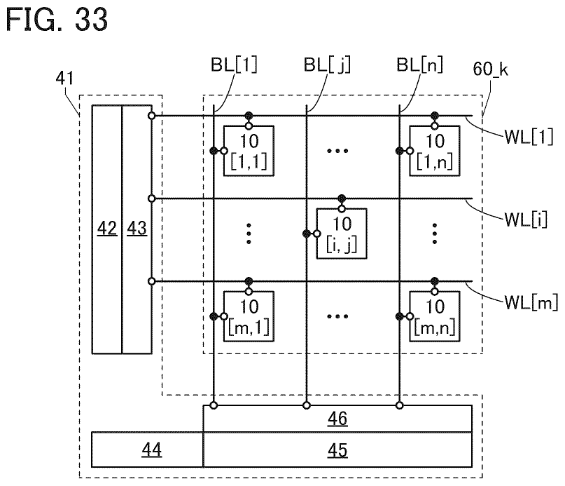

The row driver 43 has a function of selecting any one of word lines for writing and reading (e.g., any one of a wiring WL[1] to a wiring WL[m] illustrated in FIG. 33 described later) specified by the row decoder 42.

The column driver 45 has a function of writing data to the memory cells 10, a function of reading data from the memory cells 10, and a function of retaining the read data. The column driver 45 has a function of selecting write and read bit lines (e.g., a wiring BL[1] to a wiring BL[n] illustrated in FIG. 33 described later) specified by the column decoder 44.

The input circuit 47 has a function of retaining the signal WDA. Data retained by the input circuit 47 (the first data in the above embodiment) is output to the column driver 45. Data output from the input circuit 47 is data (Din) to be written to the memory cells 10. Data (Dout) read from the memory cells 10 by the column driver 45 is output to the output circuit 48. Note that in the above embodiment, the read data (Dout) is treated as arithmetic operation result data. The output circuit 48 has a function of retaining Dout. In addition, the output circuit 48 has a function of outputting Dout to the outside of the memory device 100. Data output from the output circuit 48 is the signal RDA.

The PSW 22 has a function of controlling supply of VDD to the peripheral circuit 31. The PSW 23 has a function of controlling supply of VHM to the row driver 43. Here, in the memory device 100, a high power supply voltage is VDD and a low power supply voltage is GND (a ground potential). In addition, VHM is a high power supply voltage used to set a word line at a high level and is higher than VDD. The on state and the off state of the PSW 22 are switched by the signal PON1, and the on state and the off state of the PSW 23 is switched by the signal PON2. The number of power domains to which VDD is supplied is one in the peripheral circuit 31 in FIG. 32B but can be more than one. In that case, a power switch is provided for each power domain.

Next, electrical connection between the peripheral circuit 41 and the memory layer 60 is described.

FIG. 33 is a block diagram illustrating a structure example of the peripheral circuit 41 and the memory layer 60_k. In FIG. 33, the row decoder 42 and the row driver 43 are electrically connected to each of the wiring WL[1] to the wiring WL[m], and the column decoder 44, the column driver 45, and the sense amplifier 46 are electrically connected to each of the wiring BL[1] to the wiring BL[n].

Note that the wiring WL[1] to the wiring WL[m] are wirings corresponding to the wiring WWLa[i], the wiring RWLa[i], the wiring WWLb[i], and the wiring RWLb[i] described in Embodiment 1. That is, the wiring WL[1] to the wiring WL[m] function as word lines.

The wiring BL[1] to the wiring BL[n] are wirings corresponding to the wiring WRBLa[U], the wiring WRBLa[j+1], the wiring WRBLa[j+2], the wiring WRBLb[U], the wiring WRBLb[j+1], and the wiring WRBLb[j+2] described in Embodiment 1. That is, the wiring BL[1] to the wiring BL[n] function as bit lines.

The memory cell 10[i,j] located at the i-th row and the j-th column is electrically connected to the wiring WL[i] and the wiring BL[j].

As illustrated in FIG. 33, the memory layer 60_k is electrically connected to the peripheral circuit 41, whereby data writing to the memory layer 60_k and data reading from the memory layer 60_k can be performed.

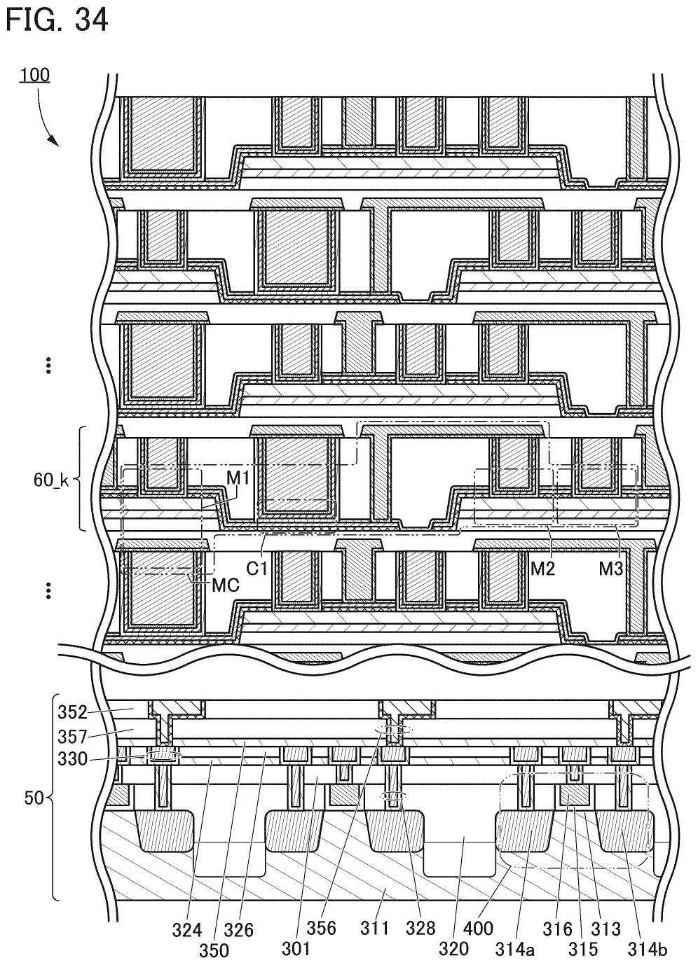

Next, FIG. 34 illustrates a cross-sectional structure example of the memory device 100 of one embodiment of the present invention. The memory device 100 illustrated in FIG. 34 includes a plurality of memory layers 60 (the memory layers ALYa, the memory layers ALYb, or the memory layers ALYc in FIG. 2 described in Embodiment 1) above the driver circuit layer 50. The description of the memory layers 60 in this embodiment is omitted in order to reduce repeated description.

FIG. 34 also illustrates a transistor 400 included in the driver circuit layer 50 as an example. The transistor 400 is provided on a substrate 311 and includes a conductor 316 functioning as a gate, an insulator 315 functioning as a gate insulator, a semiconductor region 313 including part of the substrate 311, and a low-resistance region 314a functioning as one of a source region and a drain region, and a low-resistance region 314b functioning as the other of the source region and the drain region. The transistor 400 may be a p-channel transistor or an n-channel transistor. As the substrate 311, a single crystal silicon substrate can be used, for example.

Here, in the transistor 400 illustrated in FIG. 34, the semiconductor region 313 (part of the substrate 311) where a channel is formed has a protruding shape. The conductor 316 is provided to cover a side surface and a top surface of the semiconductor region 313 with the insulator 315 therebetween. Note that a material for adjusting the work function may be used as the conductor 316. Such a transistor 400 is also referred to as a FIN-type transistor because it utilizes a protruding portion of a semiconductor substrate. Note that an insulator functioning as a mask for forming the protruding portion may be included in contact with an upper portion of the protruding portion. Furthermore, although the case where the protruding portion is formed by processing part of the semiconductor substrate is described here, a semiconductor film having a protruding shape may be formed by processing an SOI (Silicon On Insulator) substrate.

Note that the transistor 400 illustrated in FIG. 34 is an example and the structure is not limited thereto; an appropriate transistor can be used in accordance with a circuit structure or a driving method.

A wiring layer provided with an interlayer film, a wiring and a plug may be provided between the components. A plurality of wiring layers can be provided in accordance with design. Furthermore, in this specification and the like, a wiring and a plug electrically connected to the wiring may be a single component. That is, part of a conductor may function as a wiring and part of the conductor may function as a plug.

For example, an insulator 320, an insulator 301, an insulator 324, and an insulator 326 are stacked in this order over the transistor 400 as interlayer films. A conductor 328 or the like is embedded in the insulator 320 and the insulator 301. A conductor 330 or the like is embedded in the insulator 324 and the insulator 326. Note that the conductor 328 and the conductor 330 function as a contact plug or a wiring.

The insulators functioning as the interlayer films may also function as planarization films that cover an uneven shape thereunder. For example, the top surface of the insulator 301 may be planarized by planarization treatment using a chemical mechanical polishing (CMP) method or the like to improve planarity.

A wiring layer may be provided over the insulator 326 and the conductor 330. For example, in FIG. 34, an insulator 350, an insulator 357, and an insulator 352 are stacked sequentially over the insulator 326 and the conductor 330. A conductor 356 is formed in the insulator 350, the insulator 357, and the insulator 352. The conductor 356 functions as a contact plug or a wiring. For example, the transistor 400 is electrically connected to the wiring WL or the wiring BL through the conductor 356, the conductor 330, or the like.

This embodiment can be combined as appropriate with any of the other embodiments and the like described in this specification.

### Embodiment 4

In this embodiment, a transistor whose channel formation region includes an oxide semiconductor (OS transistor) is described. In the description of the OS transistor, comparison with a transistor whose channel formation region includes silicon (also referred to as Si transistor) is also described briefly.

### [OS Transistor]

An oxide semiconductor having a low carrier concentration is preferably used for the OS transistor. For example, the carrier concentration in a channel formation region of an oxide semiconductor is lower than or equal to 1×10¹⁸ cm⁻³, preferably lower than 1×10¹⁷ cm⁻³, further preferably lower than 1×10¹⁶ cm⁻³, still further preferably lower than 1×10¹³ cm⁻³, yet still further preferably lower than 1×10¹⁰ cm⁻³, and higher than or equal to 1×10⁻⁹ cm⁻³. In order to reduce the carrier concentration of an oxide semiconductor film, the impurity concentration in the oxide semiconductor film is reduced so that the density of defect states can be reduced. In this specification and the like, a state with a low impurity concentration and a low density of defect states is referred to as a highly purified intrinsic or substantially highly purified intrinsic state. Note that an oxide semiconductor having a low carrier concentration may be referred to as a highly purified intrinsic or substantially highly purified intrinsic oxide semiconductor.

A highly purified intrinsic or substantially highly purified intrinsic oxide semiconductor has a low density of defect states and accordingly has a low density of trap states in some cases. Charge trapped by the trap states in the oxide semiconductor takes a long time to disappear and might behave like fixed charge. A transistor whose channel formation region is formed in an oxide semiconductor having a high density of trap states has unstable electrical characteristics in some cases.

Accordingly, in order to obtain stable electrical characteristics of the transistor, reducing the concentration of impurities in the oxide semiconductor is effective. In order to reduce the impurity concentration in the oxide semiconductor, the impurity concentration in a film that is adjacent to the oxide semiconductor is preferably reduced. As examples of the impurity, hydrogen, nitrogen, and the like are given. Note that impurities in an oxide semiconductor refer to, for example, elements other than the main components of the oxide semiconductor. For example, an element with a concentration lower than 0.1 atomic % is regarded as an impurity.

When impurities and oxygen vacancies are in a channel formation region of an oxide semiconductor in an OS transistor, electrical characteristics of the OS transistor easily vary and the reliability thereof might worsen. In the OS transistor, a defect that is an oxygen vacancy in the oxide semiconductor into which hydrogen enters (hereinafter sometimes referred to as V_{O}H) may be formed and may generate an electron serving as a carrier. When V_{O}H is formed in the channel formation region, the donor concentration in the channel formation region increases in some cases. As the donor concentration in the channel formation region increases, the threshold voltage might vary. Accordingly, when the channel formation region in the oxide semiconductor includes oxygen vacancies, the transistor tends to have normally-on characteristics (a state where a channel is present and a current flows through the transistor even when no voltage is applied to the gate electrode). Therefore, the impurities, oxygen vacancies, and V_{O}H are preferably reduced as much as possible in the channel formation region in the oxide semiconductor.

The band gap of the oxide semiconductor is preferably larger than the band gap of silicon (typically 1.1 eV), further preferably larger than or equal to 2 eV, still further preferably larger than or equal to 2.5 eV, yet still further preferably larger than or equal to 3.0 eV. With use of an oxide semiconductor having a larger band gap than silicon, the off-state current (also referred to as off leakage current or Ioff) of the transistor can be reduced.

In a Si transistor, a short-channel effect (also referred to as SCE) appears as miniaturization of the transistor proceeds. Thus, it is difficult to miniaturize the Si transistor. One factor that causes the short-channel effect is a small band gap of silicon. By contrast, the OS transistor includes an oxide semiconductor that is a semiconductor material having a wide band gap, and thus can suppress the short-channel effect. In other words, a short-channel effect does not appear or hardly appears in an OS transistor.

The short-channel effect refers to degradation of electrical characteristics which becomes obvious along with miniaturization of a transistor (a decrease in channel length). Specific examples of the short-channel effect include a decrease in threshold voltage, an increase in subthreshold swing value (sometimes also referred to as S value), an increase in leakage current, and the like. Here, the S value means the amount of change in gate voltage in the subthreshold region when the drain voltage keeps constant and the drain current changes by one order of magnitude.

The characteristic length is widely used as an indicator of resistance to a short-channel effect. The characteristic length is an indicator of curving of potential in a channel formation region. When the characteristic length is shorter, the potential rises more sharply, which means that the resistance to a short-channel effect is high.

The OS transistor is an accumulation-type transistor and the Si transistor is an inversion-type transistor. Accordingly, an OS transistor has a shorter characteristic length between a source region and a channel formation region and a shorter characteristic length between a drain region and the channel formation region than a Si transistor. Therefore, an OS transistor has higher resistance to a short-channel effect than a Si transistor. That is, in the case where a transistor with a short channel length is to be manufactured, an OS transistor is more suitable than a Si transistor.

Even in the case where the carrier concentration in the oxide semiconductor is reduced until the channel formation region becomes an i-type or substantially i-type region, the conduction band minimum of the channel formation region in a short-channel transistor decreases because of the Conduction-Band-Lowering (CBL) effect; thus, the energy difference between the conduction band minimum of the source region or the drain region and that of the channel formation region might decrease to greater than or equal to 0.1 eV and less than or equal to 0.2 eV. Accordingly, the OS transistor can be regarded as having an n⁺/n⁻/n⁺ accumulation-type junction-less transistor structure or an n⁺/n⁻/n⁺ accumulation-type non-junction transistor structure in which the channel formation region becomes an n⁻-type region and the source and drain regions become n⁺-type regions in the OS transistor.

An OS transistor having the above structure enables a semiconductor device to have favorable electrical characteristics even when the semiconductor device is miniaturized or highly integrated. For example, the semiconductor device can have favorable electrical characteristics even when the OS transistor has a gate length less than or equal to 20 nm, less than or equal to 15 nm, less than or equal to 10 nm, less than or equal to 7 nm, or less than or equal to 6 nm and greater than or equal to 1 nm, greater than or equal to 3 nm, or greater than or equal to 5 nm. In contrast, it is sometimes difficult for a Si transistor to have a gate length less than or equal to 20 nm or less than or equal to 15 nm because of appearance of a short-channel effect. Therefore, an OS transistor can be suitably used as a transistor having a short channel length as compared with a Si transistor. Note that the gate length refers to the length of a gate electrode in a direction in which carriers move inside a channel formation region during an operation of the transistor and to the width of a bottom surface of the gate electrode in a plan view of the transistor.

Miniaturization of an OS transistor can improve the high frequency characteristics of the transistor. Specifically, the cutoff frequency of the transistor can be improved. When the gate length of the OS transistor is within the above range, the cutoff frequency of the transistor can be greater than or equal to 50 GHz, preferably greater than or equal to 100 GHz, further preferably greater than or equal to 150 GHz at room temperature, for example.

As described above, an OS transistor has an effect superior to that of a Si transistor, such as a low off-state current and capability of having a short channel length.

Note that this embodiment can be combined with any of the other embodiments in this specification as appropriate. For example, the configurations, structures, methods, and the like described in this embodiment can be used in an appropriate combination with any of the configurations, structures, methods, and the like described in the other embodiments and the like.

### Embodiment 5

In this embodiment, electronic components, electronic devices, a large computer, space equipment, and a data center (also referred to as DC) in which the semiconductor device described in the above embodiment can be used will be described. Electronic components, electronic devices, a large computer, space equipment, and a data center in which the semiconductor device of one embodiment of the present invention is used are effective in improving performance, e.g., reducing power consumption.

### [Electronic Component]

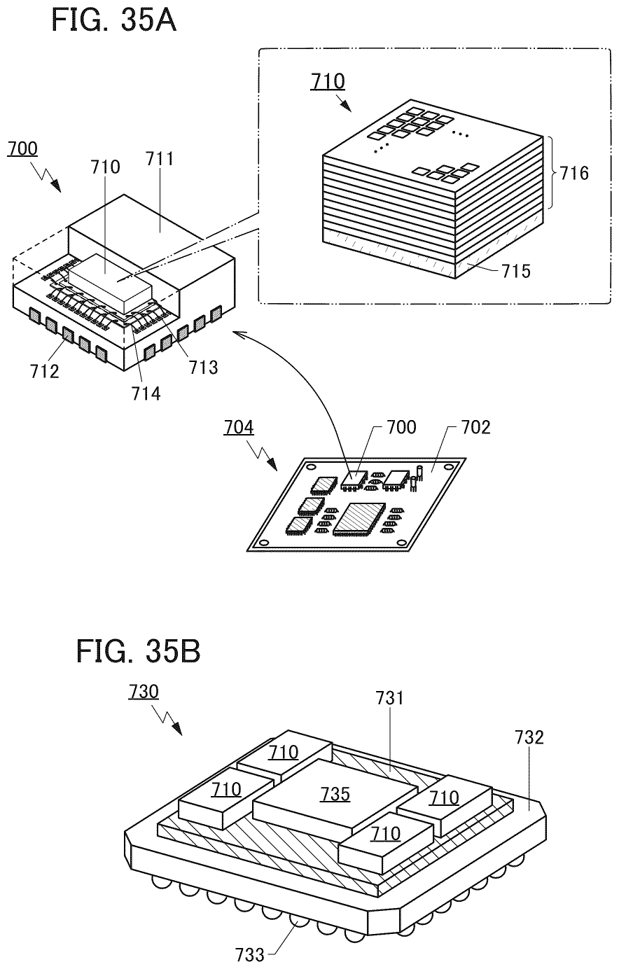

FIG. 35A is a perspective view of a substrate (a circuit board 704) on which an electronic component 700 is mounted. The electronic component 700 illustrated in FIG. 35A includes a semiconductor device 710 in a mold 711. Some components are omitted in FIG. 35A to show the inside of the electronic component 700. The electronic component 700 includes a land 712 outside the mold 711. The land 712 is electrically connected to an electrode pad 713, and the electrode pad 713 is electrically connected to the semiconductor device 710 through a wire 714. The electronic component 700 is mounted on a printed circuit board 702, for example. A plurality of such electronic components are combined and electrically connected to each other on the printed circuit board 702, which forms the circuit board 704.

The semiconductor device 710 includes a driver circuit layer 715 and a memory layer 716. The memory layer 716 has a structure in which a plurality of memory cell arrays are stacked. A stacked-layer structure of the driver circuit layer 715 and the memory layer 716 can be a monolithic stacked-layer structure. In the monolithic stacked-layer structure, layers can be connected to each other without using a through electrode technique such as TSV (Through Silicon Via) or a bonding technique such as Cu-to-Cu direct bonding. The monolithic stacked-layer structure of the driver circuit layer 715 and the memory layer 716 enables, for example, what is called an on-chip memory structure in which a memory is directly formed on a processor. The on-chip memory structure allows an interface portion between the processor and the memory to operate at high speed.

With the on-chip memory structure, the sizes of a connection wiring and the like can be smaller than those in the case where the through electrode technique such as TSV is employed; thus, the number of connection pins can be increased. An increase in the number of connection pins enables parallel operations, which can increase the bandwidth of the memory (also referred to as a memory bandwidth).

It is preferable that the plurality of memory cell arrays included in the memory layer 716 be formed using OS transistors and be monolithically stacked. Monolithically stacking the plurality of memory cell arrays can improve one or both of a memory bandwidth and a memory access latency. Note that a bandwidth refers to a data transfer volume per unit time, and an access latency refers to time from access to start of data transmission. In the case where the memory layer 716 is formed using Si transistors, it is difficult to obtain the monolithic stacked-layer structure as compared with the case where the memory layer 716 is formed using OS transistors. Thus, an OS transistor is superior to a Si transistor in the monolithic stacked-layer structure.

The semiconductor device 710 may be referred to as a die. In this specification and the like, a die refers to each of chip pieces obtained by dividing a circuit pattern formed on a circular substrate (also referred to as a wafer) or the like into dice in the manufacturing process of a semiconductor chip, for example. Examples of a semiconductor material that can be used for a die include silicon (Si), silicon carbide (SiC), and gallium nitride (GaN). A die obtained from a silicon substrate (also referred to as a silicon wafer) may be referred to as a silicon die, for example.

FIG. 35B is a perspective view of an electronic component 730. The electronic component 730 is an example of a SiP (System in Package) or an MCM (Multi Chip Module).

In the electronic component 730, an interposer 731 is provided over a package substrate 732 (printed circuit board), and a semiconductor device 735 and a plurality of the semiconductor devices 710 are provided over the interposer 731.

The electronic component 730 that includes the semiconductor device 710 as a high bandwidth memory (HBM) is illustrated as an example. The semiconductor device 735 can be used for an integrated circuit such as a CPU (Central Processing Unit), a GPU (Graphics Processing Unit), or an FPGA (Field Programmable Gate Array).

As the package substrate 732, a ceramic substrate, a plastic substrate, or a glass epoxy substrate can be used, for example. As the interposer 731, a silicon interposer or a resin interposer can be used, for example.

The interposer 731 includes a plurality of wirings and has a function of electrically connecting a plurality of integrated circuits with different terminal pitches. The plurality of wirings are provided in a single layer or multiple layers. In addition, the interposer 731 has a function of electrically connecting an integrated circuit provided on the interposer 731 to an electrode provided on the package substrate 732. Accordingly, the interposer is referred to as a “redistribution substrate” or an “intermediate substrate” in some cases. Furthermore, a through electrode is provided in the interposer 731 and the through electrode is used to electrically connect an integrated circuit and the package substrate 732 in some cases. Moreover, in the case of using a silicon interposer, a TSV can also be used as the through electrode.

An HBM needs to be connected to many wirings to achieve a wide memory bandwidth. Therefore, an interposer on which an HBM is mounted requires minute and densely formed wirings. For this reason, a silicon interposer is preferably used as the interposer on which an HBM is mounted.

In a SiP or an MCM that includes a silicon interposer, a decrease in reliability due to a difference in the coefficient of expansion between an integrated circuit and the interposer is less likely to occur. Furthermore, a surface of a silicon interposer has high planarity; thus, poor connection between the silicon interposer and an integrated circuit provided on the silicon interposer is less likely to occur. It is particularly preferable to use a silicon interposer for a 2.5D package (2.5-dimensional mounting) in which a plurality of integrated circuits are arranged side by side on the interposer.

Meanwhile, in the case where a plurality of integrated circuits with different terminal pitches are electrically connected to each other using a silicon interposer and TSV, a space for the width of the terminal pitches and the like is needed. Thus, in the case where the size of the electronic component 730 is to be reduced, the width of the terminal pitches causes a problem, which sometimes makes it difficult to provide a large number of wirings for achieving a wide memory bandwidth. For this reason, the above-described monolithic stacked-layer structure using OS transistors is suitable. A composite structure combining memory cell arrays stacked using TSV and monolithically stacked memory cell arrays may be employed.

In addition, a heat sink (a radiator plate) may be provided to overlap with the electronic component 730. In the case of providing a heat sink, the heights of integrated circuits provided on the interposer 731 are preferably equal to each other. For example, in the electronic component 730 described in this embodiment, the heights of the semiconductor devices 710 and the semiconductor device 735 are preferably equal to each other.

To mount the electronic component 730 on another substrate, an electrode 733 may be provided on a bottom portion of the package substrate 732. FIG. 35B illustrates an example in which the electrode 733 is formed of a solder ball. Solder balls are provided in a matrix on the bottom portion of the package substrate 732, so that BGA (Ball Grid Array) mounting can be achieved. Alternatively, the electrode 733 may be formed of a conductive pin. When conductive pins are provided in a matrix on the bottom portion of the package substrate 732, PGA (Pin Grid Array) mounting can be achieved.

The electronic component 730 can be mounted on another substrate by any of various mounting methods not limited to BGA and PGA. Examples of a mounting method include an SPGA (Staggered Pin Grid Array), an LGA (Land Grid Array), a QFP (Quad Flat Package), a QFJ (Quad Flat J-leaded package), and a QFN (Quad Flat Non-leaded package).

### [Electronic Device]

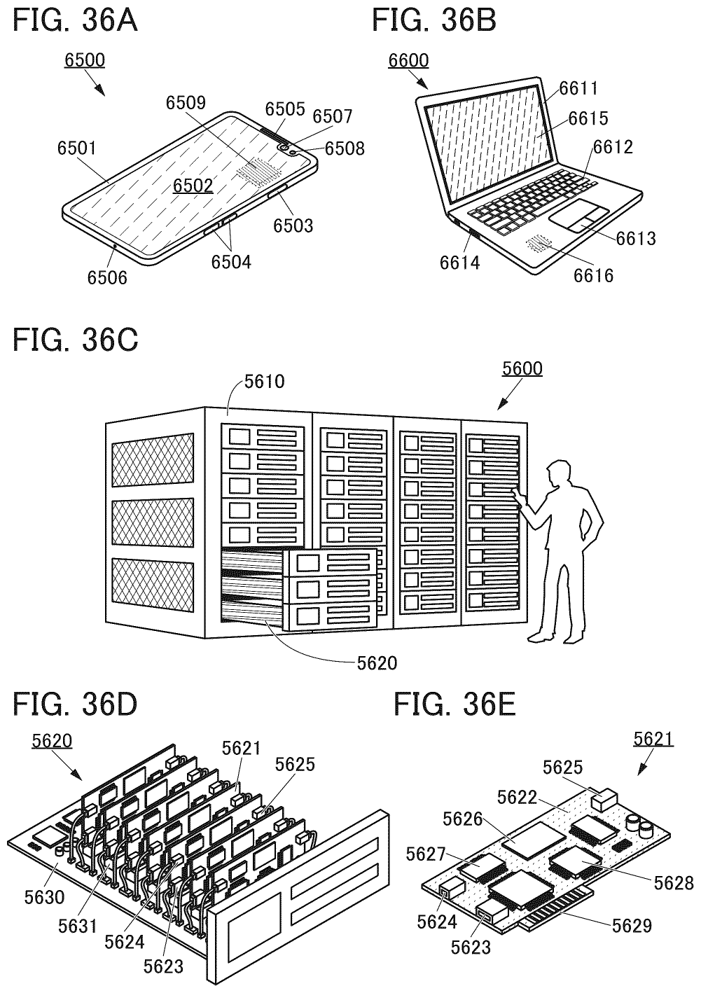

FIG. 36A is a perspective view of an electronic device 6500. The electronic device 6500 illustrated in FIG. 36A is a portable information terminal that can be used as a smartphone. The electronic device 6500 includes a housing 6501, a display portion 6502, a power button 6503, buttons 6504, a speaker 6505, a microphone 6506, a camera 6507, a light source 6508, and a control device 6509. One or more selected from a CPU, a GPU, and a memory device are provided as the control device 6509, for example. The semiconductor device of one embodiment of the present invention can be used for the display portion 6502, the control device 6509, and the like.

An electronic device 6600 illustrated in FIG. 36B is an information terminal that can be used as a notebook personal computer. The electronic device 6600 includes a housing 6611, a keyboard 6612, a pointing device 6613, an external connection port 6614, a display portion 6615, and a control device 6616. One or more selected from a CPU, a GPU, and a memory device are provided as the control device 6616, for example. The semiconductor device of one embodiment of the present invention can be used for the display portion 6615, the control device 6616, and the like. Note that the semiconductor device of one embodiment of the present invention is preferably used for the control device 6509 and the control device 6616 described above, in which case power consumption can be reduced.

### [Large Computer]

FIG. 36C is a perspective view of a large computer 5600. In the large computer 5600 illustrated in FIG. 36C, a plurality of rack mount computers 5620 are stored in a rack 5610. Note that the large computer 5600 may be referred to as a supercomputer.

The computer 5620 can have a structure in a perspective view of FIG. 36D, for example. In FIG. 36D, the computer 5620 includes a motherboard 5630, and the motherboard 5630 includes a plurality of slots 5631 and a plurality of connection terminals. A PC card 5621 is inserted in the slot 5631. In addition, the PC card 5621 includes a connection terminal 5623, a connection terminal 5624, and a connection terminal 5625, a terminal of each of which is connected to the motherboard 5630.

The PC card 5621 illustrated in FIG. 36E is an example of a processing board provided with a CPU, a GPU, a memory device, and the like. The PC card 5621 includes a board 5622. The board 5622 includes the connection terminal 5623, the connection terminal 5624, and the connection terminal 5625, a semiconductor device 5626, a semiconductor device 5627, a semiconductor device 5628, and a connection terminal 5629. Although FIG. 36E illustrates semiconductor devices other than the semiconductor device 5626, the semiconductor device 5627, and the semiconductor device 5628, the following description of the semiconductor device 5626, the semiconductor device 5627, and the semiconductor device 5628 is referred to for these semiconductor devices.

The connection terminal 5629 has a shape with which the connection terminal 5629 can be inserted in the slot 5631 of the motherboard 5630, and the connection terminal 5629 functions as an interface for connecting the PC card 5621 and the motherboard 5630. An example of the standard for the connection terminal 5629 is PCIe.

The connection terminal 5623, the connection terminal 5624, and the connection terminal 5625 can serve as, for example, an interface for performing power supply, signal input, or the like to the PC card 5621. For another example, they can serve as an interface for outputting a signal calculated by the PC card 5621. Examples of the standard for each of the connection terminal 5623, the connection terminal 5624, and the connection terminal 5625 include USB (Universal Serial Bus), SATA (Serial ATA), and SCSI (Small Computer System Interface). In the case where video signals are output from the connection terminal 5623, the connection terminal 5624, and the connection terminal 5625, an example of the standard therefor is HDMI (registered trademark).

The semiconductor device 5626 includes a terminal (not shown) for inputting and outputting signals, and when the terminal is inserted in a socket (not shown) of the board 5622, the semiconductor device 5626 and the board 5622 can be electrically connected to each other.

The semiconductor device 5627 includes a plurality of terminals, and when the terminals are reflow-soldered, for example, to wirings of the board 5622, the semiconductor device 5627 and the board 5622 can be electrically connected to each other. Examples of the semiconductor device 5627 include an FPGA, a GPU, and a CPU. As the semiconductor device 5627, the electronic component 730 can be used, for example.

The semiconductor device 5628 includes a plurality of terminals, and when the terminals are reflow-soldered, for example, to wirings of the board 5622, the semiconductor device 5628 and the board 5622 can be electrically connected to each other. An example of the semiconductor device 5628 is a memory device. As the semiconductor device 5628, the electronic component 700 can be used, for example.

The large computer 5600 can also function as a parallel computer. When the large computer 5600 is used as a parallel computer, large-scale computation necessary for artificial intelligence learning and inference can be performed, for example.

### [Space Equipment]

The semiconductor device of one embodiment of the present invention can be suitably used for space equipment, as equipment for information processing and information storing.

The semiconductor device of one embodiment of the present invention can include an OS transistor. A change in electrical characteristics of the OS transistor due to radiation irradiation is small. That is, the OS transistor is highly resistant to radiation and thus can be suitably used in an environment where radiation can enter. For example, the OS transistor can be suitably used in outer space.

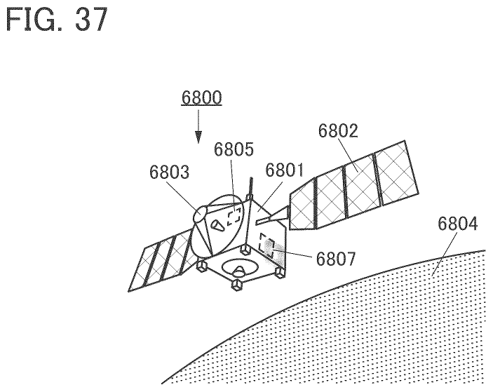

FIG. 37 illustrates an artificial satellite 6800 as an example of space equipment. The artificial satellite 6800 includes a body 6801, a solar panel 6802, an antenna 6803, a secondary battery 6805, and a control device 6807. FIG. 37 illustrates a planet 6804 in outer space, for example. Note that outer space refers to, for example, space at an altitude greater than or equal to 100 km, and outer space in this specification may also include thermosphere, mesosphere, and stratosphere.

Although not illustrated in FIG. 37, a battery management system (also referred to as BMS) or a battery control circuit may be provided in the secondary battery 6805. The battery management system or the battery control circuit preferably includes an OS transistor, in which case power consumption is low and high reliability is achieved even in outer space.

The amount of radiation in outer space is 100 or more times that on the ground. Examples of radiation include electromagnetic waves (electromagnetic radiation) typified by X-rays and gamma rays and particle radiation typified by alpha rays, beta rays, neutron beams, proton beams, heavy-ion beams, and meson beams.

When the solar panel 6802 is illuminated with sunlight, electric power required for an operation of the artificial satellite 6800 is generated. However, for example, in the situation where the solar panel is not illuminated with sunlight or the amount of sunlight with which the solar panel is illuminated is small, the amount of generated electric power is small. Accordingly, electric power required for an operation of the artificial satellite 6800 might not be generated. In order to operate the artificial satellite 6800 even with a small amount of generated electric power, the artificial satellite 6800 is preferably provided with the secondary battery 6805. Note that a solar panel is referred to as a solar cell module in some cases.

The artificial satellite 6800 can generate a signal. The signal is transmitted through the antenna 6803, and can be received by a ground-based receiver or another artificial satellite, for example. When the signal transmitted by the artificial satellite 6800 is received, the position of a receiver that receives the signal can be measured. Thus, the artificial satellite 6800 can constitute a satellite positioning system.

The control device 6807 has a function of controlling the artificial satellite 6800. The control device 6807 is configured with one or more selected from a CPU, a GPU, and a memory device, for example. Note that the semiconductor device of one embodiment of the present invention is suitably used for the control device 6807. A change in electrical characteristics due to radiation irradiation is smaller in an OS transistor than in a Si transistor. That is, the OS transistor has high reliability and thus can be suitably used even in an environment where radiation can enter.

The artificial satellite 6800 can include a sensor. For example, with a structure including a visible light sensor, the artificial satellite 6800 can have a function of sensing sunlight reflected by a ground-based object. Alternatively, with a structure including a thermal infrared sensor, the artificial satellite 6800 can have a function of sensing thermal infrared rays emitted from the surface of the earth. Thus, the artificial satellite 6800 can function as an earth observing satellite, for example.

Although the artificial satellite is described as an example of space equipment in this embodiment, one embodiment of the present invention is not limited thereto. The semiconductor device of one embodiment of the present invention can be suitably used for space equipment such as a spacecraft, a space capsule, or a space probe, for example.

As described above, an OS transistor has excellent effects of achieving a wide memory bandwidth and being highly resistant to radiation as compared with a Si transistor.

### [Data Center]

The semiconductor device of one embodiment of the present invention can be suitably used for a storage system in a data center, for example. Long-term management of data, such as guarantee of data immutability, is required for the data center. The management of long-term data needs an increase in building size owing to installation of storages and servers for storing an enormous amount of data, stable electric power for data retention, cooling equipment necessary for data retention, and the like.

With the use of the semiconductor device of one embodiment of the present invention for the storage system used in the data center, electric power required for data retention can be reduced and the size of a semiconductor device retaining data can be downsized. Thus, downsizing of the storage system, downsizing of the power supply for retaining data, downscaling of the cooling equipment, and the like can be achieved, for example. This can reduce the space of the data center.

Since the semiconductor device of one embodiment of the present invention has low power consumption, heat generation from a circuit can be reduced. Accordingly, adverse effects of the heat generation on the circuit itself, the peripheral circuit, and the module can be reduced. Furthermore, the use of the semiconductor device of one embodiment of the present invention enables a data center that operates stably even in a high-temperature environment. Thus, the reliability of the data center can be increased.

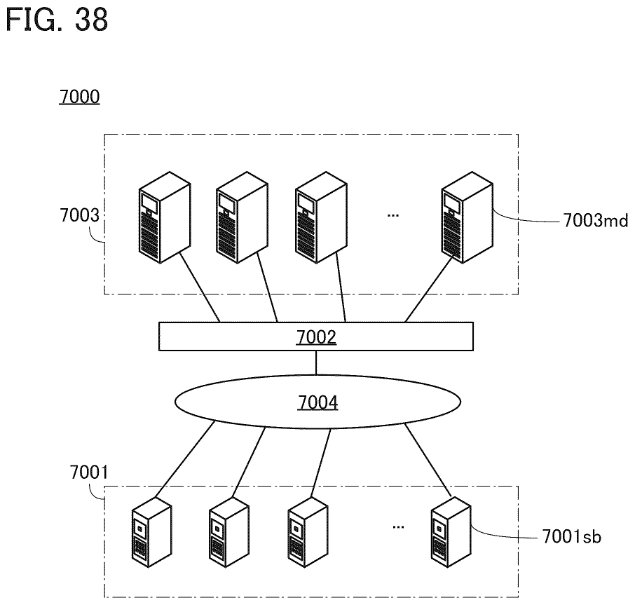

FIG. 38 illustrates a storage system that can be used in a data center. A storage system 7000 illustrated in FIG. 38 includes a plurality of servers 7001sb as a host 7001. The storage system 7000 includes a plurality of memory devices 7003md as a storage 7003). In the illustrated mode, the host 7001 and the storage 7003 are connected to each other through a storage area network 7004 and a storage control circuit 7002.

The host 7001 corresponds to a computer that accesses data stored in the storage 7003. The host 7001 may be connected to another host 7001 through a network.

The data access speed, i.e., the time taken for storing and outputting data, of the storage 7003 is shortened by using a flash memory, but is still considerably longer than the data access speed of a DRAM (Dynamic Random Access Memory) that can be used as a cache memory in a storage. In the storage system, in order to solve the problem of low access speed of the storage 7003, a cache memory is normally provided in the storage to shorten the time taken for storing and outputting data.

The above-described cache memory is used in the storage control circuit 7002 and the storage 7003. The data transmitted between the host 7001 and the storage 7003 is stored in the cache memories in the storage control circuit 7002 and the storage 7003 and then output to the host 7001 or the storage 7003.

The use of an OS transistor as a transistor for storing data in the cache memory to retain a potential based on data can reduce the frequency of refreshing, so that power consumption can be reduced. Furthermore, downsizing is possible by stacking memory cell arrays.

The use of the semiconductor device of one embodiment of the present invention for one or more selected from an electronic component, an electronic device, a large computer, space equipment, and a data center will produce an effect of reducing power consumption. Although demand for energy will increase with increasing performance and integration degree of semiconductor devices, the use of the semiconductor device of one embodiment of the present invention can thus lead to a reduction of the emission amount of greenhouse gas typified by carbon dioxide (CO₂). The semiconductor device of one embodiment of the present invention can be effectively used as one of the global warming countermeasures because of its low power consumption.

Note that this embodiment can be combined with any of the other embodiments in this specification as appropriate. For example, the configurations, structures, methods, and the like described in this embodiment can be used in an appropriate combination with any of the configurations, structures, methods, and the like described in the other embodiments and the like.

### Example 1

In this example, an OS transistor included in a semiconductor device of one embodiment of the present invention is described. In addition, a memory cell array and peripheral circuits which can be used for the semiconductor device of one embodiment of the present invention are described. Note that in this example, the memory cell array and the peripheral circuit are referred to as a memory device for convenience. Furthermore, the memory device was actually formed and a measurement result of data retention characteristics of the memory device is described.

### <OS Transistor>

As described in the above embodiment, the band gap of an oxide semiconductor included in an OS transistor is made larger than that of silicon, so that the off-state current of the OS transistor can be reduced.

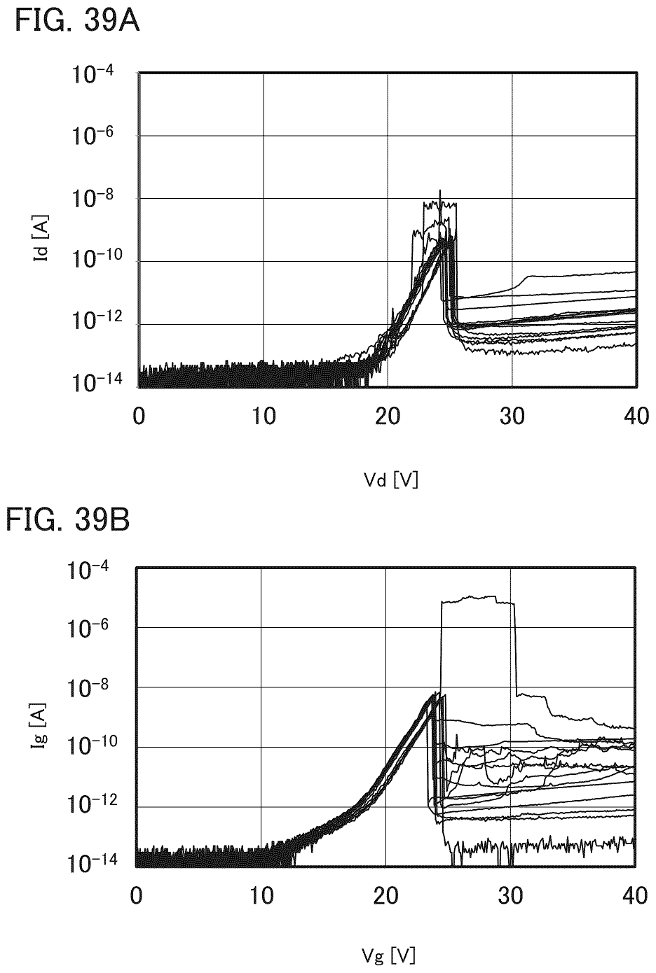

An OS transistor has higher resistance to voltage than a Si transistor. FIG. 39A is a graph showing the source-drain withstand voltage characteristics of the OS transistor, and the horizontal axis represents the source-drain voltage (Vd [V]), and the vertical axis represents an amount of a leakage current (Id [A]) flowing between the source and the drain. FIG. 39B is a graph showing the gate withstand voltage characteristics of the OS transistor, and the horizontal axis represents the gate-source (drain) voltage (Vd [V]), and the vertical axis represents the amount of leakage current flowing between the gate and the source (drain) (Ig [A]). As the sizes of the OS transistors used for the measurements in FIG. 39A and FIG. 39B, the channel length is 0.5 μm and the channel width is 0.5 μm. As shown in FIG. 39A and FIG. 39B, the source-drain withstand voltage and the gate withstand voltage of the OS transistors are each higher than or equal to 13.5 V, and the leakage current is lower than or equal to 1 pA (1×10⁻¹² A).

OS transistors can be formed with one or both of a chemical vapor deposition method and a physical vapor deposition method, which enables the OS transistors to be stacked over a CMOS circuit formed on a semiconductor substrate using silicon as its materials, for example. In other words, a semiconductor device where OS transistors are formed to be monolithically stacked over a CMOS circuit can be fabricated.

### <Circuit Structure of Memory Device>

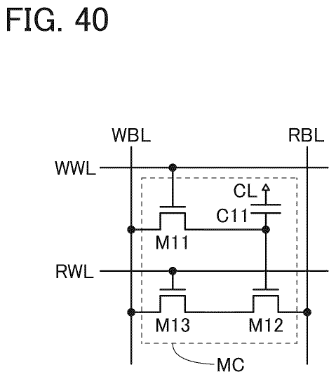

FIG. 40 illustrates the memory cell MC that can be used in the memory cell array. The memory cell MC illustrated in FIG. 40 has a 3Tr1C NOSRAM (registered trademark) with a structure similar to that of the memory cell MCa (the memory cell MCb) illustrated in FIG. 1, which includes a transistor M11 to a transistor M13 and a capacitor C11.

In the memory cell MC, a first terminal of the transistor M11 is electrically connected to a gate of the transistor M12 and a first terminal of the capacitor C11, a second terminal of the transistor M11 is electrically connected to the wiring WBL, and a gate of the transistor M11 is electrically connected to the wiring WWL. A second terminal of the capacitor C11 is electrically connected to the wiring CL. A first terminal of the transistor M12 is electrically connected to the wiring RBL, and a second terminal of the transistor M12 is electrically connected to a first terminal of the transistor M13. A second terminal of the transistor M13 is electrically connected to the wiring WBL, and a gate of the transistor M13 is electrically connected to the wiring RWL.

Accordingly, the transistor M11 corresponds to the transistor M1 of the memory cell MCa (the memory cell MCb) in FIG. 1, the transistor M12 corresponds to the transistor M2 of the memory cell MCa (the memory cell MCb) in FIG. 1, the transistor M13 corresponds to the transistor M3 of the memory cell MCa (the memory cell MCb) in FIG. 1, and the capacitor C11 corresponds to the capacitor C1 of the memory cell MCa (the memory cell MCb) in FIG. 1. Note that the memory cell MC is different from the memory cell MCa (memory cell MCb) illustrated in FIG. 1 in that the second terminal of the transistor M11 is electrically connected to the wiring WBL and the second terminal of the transistor M13 is electrically connected to the wiring WBL. In addition, the transistor M11 may have a structure with a back gate, like the transistor M1 in the memory cell MCa (the memory cell MCb) illustrated in FIG. 1.

The wiring WWL functions as a write word line and the wiring RWL functions as a read word line. The wiring WBL functions as a write bit line, and the wiring RBL functions as a read bit line. Note that the wiring WBL also functions as a wiring for supplying a predetermined potential at the time of reading. The wiring CL functions as a wiring for applying a predetermined potential to the second terminal of the capacitor C11, as in the case of the description of the memory cell MCa (the memory cell MCb) illustrated in FIG. 1. Note that in data writing and data reading, a low-level potential (referred to as reference potential in some cases) is preferably applied to the wiring CL.

In particular, as the transistor M11, an OS transistor using an In—Ga—Zn oxide that is a CAAC-OS (hereinafter, referred to as CAAC-IGZO) for an active layer is used. It is known that the transistor in which a CAAC-IGZO is used for an active layer has extremely low off-state current characteristics. For example, the off-state current of the transistor can be less than or equal to 100 zA (z: zept, 10⁻²¹), less than or equal to 1 zA, or less than or equal to 10 yA (y: yocto, 10⁻²⁴) per channel width of 1 μm. Therefore, by using the transistor as the transistor M11, a loss of data retained at the first terminal of the capacitor C11, due to current leakage, can be prevented. In other words, data written in the memory cell MC can be retained for a long time.

Furthermore, a transistor including silicon in its active layer is used for each of the transistor M12, the transistor M13, and a transistor M21 to a transistor M23 described later. A transistor including silicon in its active layer is suitable for a transistor included in a signal converter circuit, an amplifier circuit, or the like because of its high on-state current characteristics. As the silicon, amorphous silicon, microcrystalline silicon, polycrystalline silicon, or the like can be used.

The memory device of this example has the structure where the above-described transistors are formed over a semiconductor substrate of single crystal silicon and the transistor M11 to the transistor M13 and the capacitor C11 are formed thereover with an insulating film or the like therebetween.

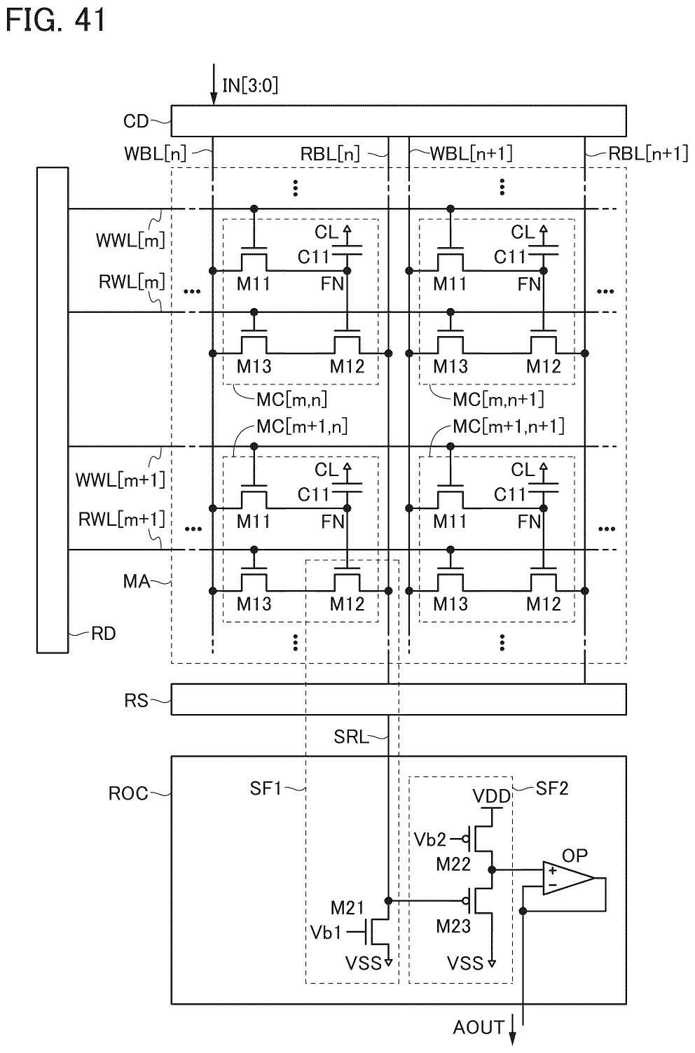

FIG. 41 illustrates a configuration of a memory cell array MA using the memory cell MC and peripheral circuits thereof.

The memory cell array MA includes memory cells MC arranged in a matrix. Note that FIG. 41 illustrates the memory cells MC arranged at addresses of m-th row and n-th column, m-th row and n+1-th column, m+1-th row and n-th column, and m+1-th row and n+1-th column (here, each of m and n is an integer greater than or equal to 1). Furthermore, a memory cell arranged at an address of m-th row and n-th column is denoted by a reference numeral MC[m, n], and in a similar manner, memory cells arranged at addresses of m-th row and n+1-th column, m+1-th row and n-th column, and m+1-th row and n+1-th column are denoted by, respectively, reference numerals MC[m, n+1], MC[m+1, n], and MC[m+1, n+1].

In this example, address notation is omitted, and one or more of a plurality of memory cells included in the memory cell array MA may be collectively denoted by a memory cell MC in some cases.

Note that in FIG. 41, a node FN is illustrated as an electrical connection point between the first terminal of the transistor M11, the first terminal of the capacitor C11, and the gate of the transistor M12 in each of the memory cells MC.

A wiring WWL[m] and a wiring WWL[m+1] are wirings electrically connected to the memory cells MC located in the m-th row and the m+1-th row, respectively, and have a function of the wiring WWL in FIG. 40. A wiring RWL[m] and a wiring RWL[m+1] are wirings electrically connected to the memory cells MC located in the m-th row and the m+1-th row, respectively, and have a function of the wiring RWL in FIG. 40. A wiring WBL[n] and a wiring WBL[n+1] are wirings electrically connected to the memory cells MC located in the n-th row and the n+1-th row, respectively, and have a function of the wiring WBL in FIG. 40. A wiring RBL[n] and a wiring RBL[n+1] are wirings electrically connected to the memory cells MC in the n-th row and the n+1-th row, respectively, and have a function of the wiring RBL in FIG. 40. In this example, the address notation for one or a plurality of wirings included in the memory cell array MA is omitted in some cases. For example, the wiring WBL[n] and the wiring WBL[n+1] are collectively referred to as the wiring WBL in some cases. In addition, the WWL[m] and the wiring WWL[m+1] are collectively referred to as the wiring WWL in some cases.

FIG. 41 illustrates a circuit CD, a circuit RD, a circuit RS, and a reading circuit ROC as peripheral circuits of the memory cell array MA.

The circuit CD includes a column decoder and a column driver circuit. The circuit CD is electrically connected to the wiring WBL and the wiring RBL. The circuit CD has a function of receiving 4-bit writing data as a signal IN[3:0] from the outside, a function of selecting the wiring WBL in a column including a memory cell MC to which data is written, to apply a write voltage corresponding to the data, and a function of selecting the wiring WBL in a column including a memory cell MC from which data is read out, to apply a predetermined potential.

The circuit RD includes a row decoder and a row driver, and the circuit RD is electrically connected to the wiring WWL and the wiring RWL. The circuit RD has a function of selecting the wiring WWL in a row including a memory cell MC to which data is written, to apply a predetermined potential to the wiring WWL and a function of selecting the wiring RWL in a row including a memory cell MC from which the data is read out, to apply a predetermined potential to the wiring RWL.

The circuit RS is electrically connected to the wiring RBL and a wiring SRL. The circuit RS has a function of selecting the wiring RBL in a column including a memory cell MC from which data is read out to be electrically connected to the wiring SRL.

The reading circuit ROC includes the transistor M21 to the transistor M23 and an operational amplifier OP.

A first terminal of the transistor M21 is electrically connected to the wiring SRL and a gate of the transistor M23, a second terminal of the transistor M21 is electrically connected to a wiring VSS, and a gate of the transistor M21 is electrically connected to a wiring Vb1.

The wiring VSS is a wiring for supplying a low-level potential, and the wiring Vb1 is a wiring for supplying a voltage higher than the threshold voltage of the transistor M21.

Here, the transistor M12 and the transistor M21 are focused on. As illustrated in FIG. 41, a source follower circuit SF1 is constructed with a connection configuration of the transistor M12 and the transistor M21. Here, when data is read out from the memory cell MC[m+1, n], a high-level potential (for example, a potential supplied from the wiring VDD, described later) is applied to the wiring WBL[n] and a predetermined potential is applied to the wiring RWL[m+1] to turn on the transistor M13, so that a potential substantially equal to a potential input to the gate of the transistor M12 (potential held by the capacitor C11) can be supplied to a gate of the transistor M23 by the source follower circuit SF1.

A first terminal of the transistor M22 is electrically connected to a first terminal of the transistor M23 and a non-inverting input terminal of the operational amplifier OP, a second terminal of the transistor M22 is electrically connected to the wiring VDD, and a gate of the transistor M22 is electrically connected to a wiring Vb2. A second terminal of the transistor M23 is electrically connected to the wiring VSS.

The wiring VDD is a wiring for supplying a high-level potential higher than a low-level potential supplied from the wiring VSS. The wiring Vb2 is a wiring for supplying a voltage lower than the threshold voltage of the transistor M22.

The above connection of the transistor M22 and the transistor M23 constructs a source follower circuit SF2. Thus, a potential substantially equal to the potential input to the gate of the transistor M23 is input to the non-inverting input terminal of the operational amplifier OP.

An inverting input terminal of the operational amplifier OP is electrically connected to an output terminal of the operational amplifier OP. That is, the operational amplifier OP has a connection structure as a voltage follower. Although the detailed specifications of the memory device in this example are described later, a signal AOUT output from the operational amplifier OP is an analog potential.

By adjusting each of the potentials supplied from the wiring Vb1 and the wiring Vb2, an error between the reading voltage and the write voltage can be reduced.

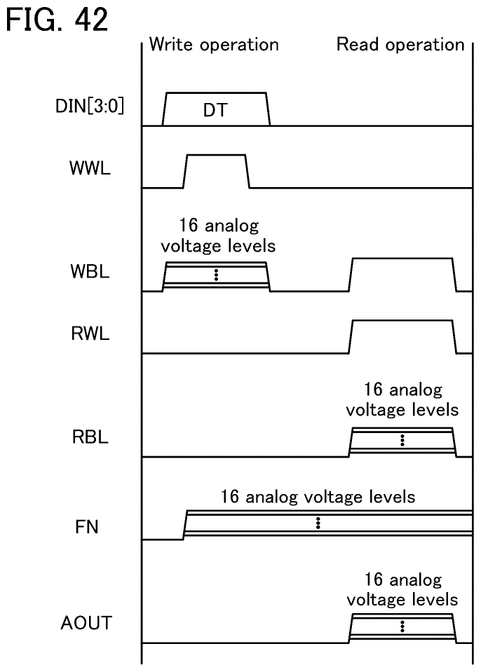

An operation example of the memory device illustrated in FIG. 41 is shown in the timing chart of FIG. 42. FIG. 42 illustrates changes in potentials of the wiring WWL, the wiring WBL, the wiring RWL, the wiring RBL, the node FN, and the signal AOUT.

As for data writing, as illustrated in FIG. 42, a 4-bit write data DT is input to the circuit CD as a signal DIN [3:0]. The circuit CD performs digital-analog conversion on the data DT to generate a potential corresponding to the data DT, and supplies the potential corresponding to the data DT to the wiring WBL. Then, the circuit RD supplies a high-level potential to the wiring WWL to turn on the transistor M11. Thus, the potential of the wiring WBL (analog potential corresponding to the data DT) can be written to the first terminal of the capacitor C11. After that, by applying a low-level potential to the wiring WWL to bring the transistor M11 into a non-conduction state, the potential of the first terminal of the capacitor C11 and the potential of the gate (the node FN) of the transistor M12 are held. Note that a low-level potential is applied to the wiring RWL and the wiring RBL. At this time, the transistor M13 is brought into an off state.

Note that the 4-bit write data DT is converted into 16 analog potential levels by the digital-analog converter circuit included in the circuit CD.

Data reading is performed in a manner in which a predetermined potential is applied to the wiring WBL and a high-level potential is applied to the wiring RWL to turn on the transistor M13, as illustrated in FIG. 42. At this time, the potential of the wiring RBL is determined in accordance with the potential of the first terminal of the capacitor C11 and the potential of the gate (the node FN) of the transistor M12. The potential of the wiring RBL is input to the circuit RS and the reading circuit ROC, and the reading circuit ROC outputs the signal AOUT corresponding to the potential of the wiring RBL, that is, data written to the node FN. Thus, data written to the memory cell can be read.

### <Formation of Memory Device>

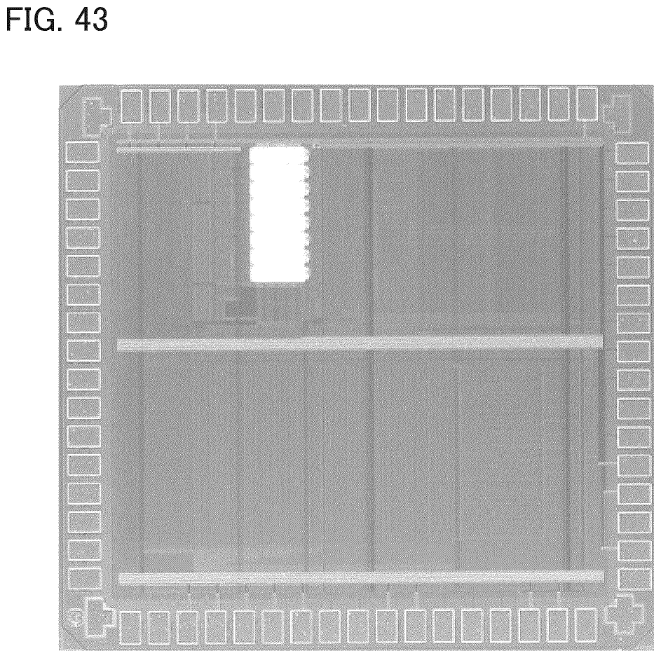

The above-described circuit structure of the memory device was actually formed on a semiconductor substrate to prototype a memory die. FIG. 43 is a captured image of a top view of the memory die.

In addition, the specifications of the memory die are shown in a table below. Note that in the item of Technology Size shown in the table below, CMOS represents the transistor M12, the transistor M13, and the transistor M21 to the transistor M23, and OSFET represents the transistor M11. Furthermore, the item of Density indicates that the memory cell array MA includes circuits arranged in a matrix of two rows and eight columns and that the one circuit includes eight memory cells that can be accessed in parallel at once.

TABLE 1

| | |
|---|---|
| Die Size | 3.02 mm × 2.87 mm |
| Resolution | 6 bit |
| Technology Size | CMOS: 0.15 μm |
| | OSFET: 0.50 μm |
| Storage Capacitance | 10 fF |
| Cell Size | 6.4 μm × 13 μm |
| Density | 128 cell |
| | (2 rows × 8 columns × 8 cells) |
| Number of I/O | 8 |
| Supply Voltage | 1.8 V/13.5 V |

### <Measurements and Results>

In the memory die including the memory device illustrated in FIG. 41, one memory cell MC was selected, 16 voltage levels obtained by converting 4-bit digital data by a digital-analog converter circuit (DAC) were written to the memory cell MC, and a read voltage corresponding to each of the write voltages was measured. Then, the same measurement was conducted on other 15 memory cells MC, and a standard deviation σ and a mean of the voltages in each level read out from the 16 memory cells MC in total were obtained.

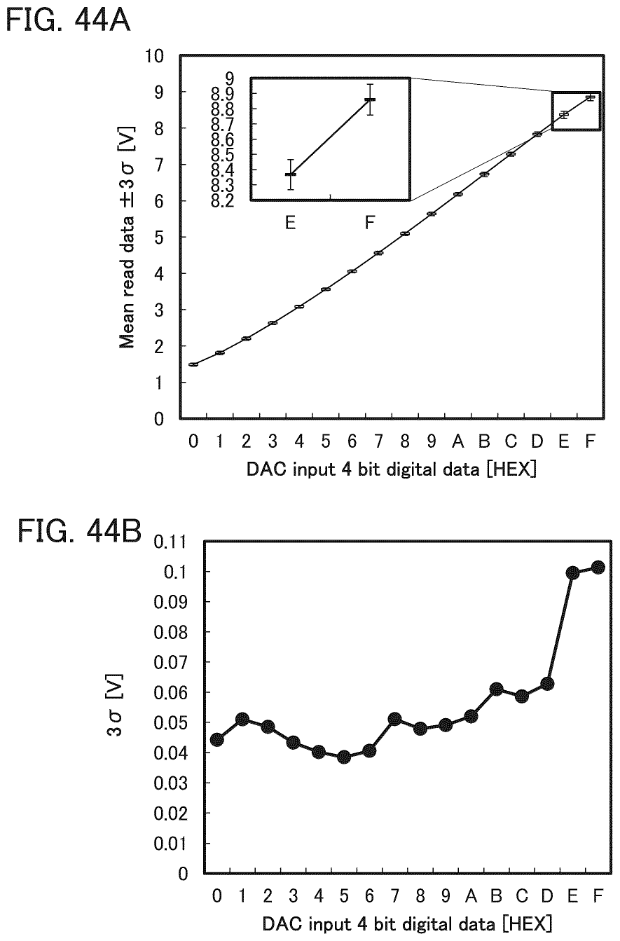

FIG. 44A shows the results. FIG. 44A shows the relation between 16 write voltage levels (DAC input 4 bit digital data [HEX′]) and an average of ±3σ (Mean read data±3σ (V)) of read voltages (Mean Read Voltage). Note that in FIG. 44A, the 16 write voltage levels are 0, 1, 2, 3, 4, 5, 6, 7, 8, 9, A, B, C, D, E, and F. As shown in FIG. 44A, favorable linearity was observed in the relation between the write voltage and the read voltage. In addition, among adjacent write voltages, the voltage between distributions of the write voltage “E” and the write voltage “F” was the smallest within the range of “mean read data±3σ of read voltages”. Note that the voltage between the distributions at this time was 0.291 V.

FIG. 44B is a graph showing 16 write voltage levels (DAC input 4 bit digital data [HEX]) on the horizontal axis and 3σ on the vertical axis. As shown in FIG. 44B, when the write voltage is “F”, 3σ is maximum and 3σ=0.101 V. In addition, the voltage range from −3σ s to 3σ s is 0.202 V.

According to the above results, 0.202 V, which is the voltage range from −3σ s to 3σ when 3σ is maximum, is lower than 0.291 V, which is the smallest voltage between distributions in the range of “the mean read data 3σ of read voltages with respect to the adjacent write voltages”, and thus there is a possibility that the number of write voltage levels can be increased to more than 16.

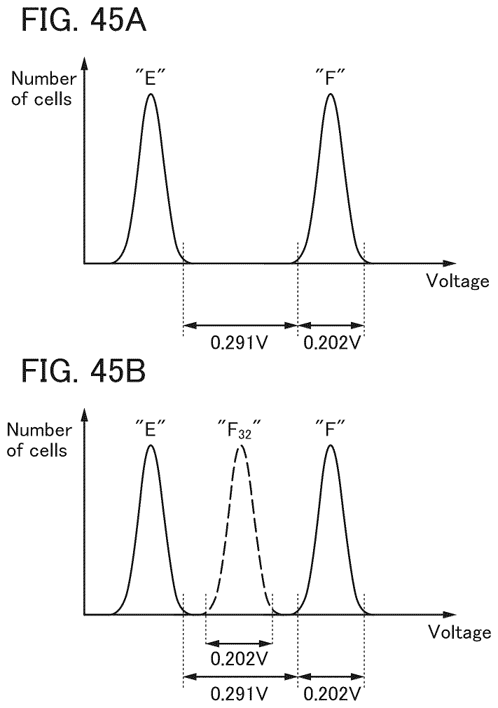

FIG. 45A is a schematic diagram of the threshold voltage distributions of the write voltage “E” and the write voltage “F”, for example. According to the above results, the voltage between the distributions of the write voltage “E” and the write voltage “F” is 0.291 V, and the voltage range from −3σ to 3σ at the write voltage “F” when 3σ is maximum is 0.202 V; thus, the threshold voltage distributions of the write voltage “E” and the write voltage “F” are as shown in FIG. 45A. Thus, as in the schematic diagram of the threshold voltage distributions illustrated in FIG. 45B, a new level of write voltage can be provided between the write voltage “E” and the write voltage “F”. Note that in FIG. 45B, the new level of write voltage is denoted by “F₃₂” and shown by a dashed line. In FIG. 45B, the voltage range from −3σ s to 3σ of the write voltage “F₃₂” is 0.202 V.

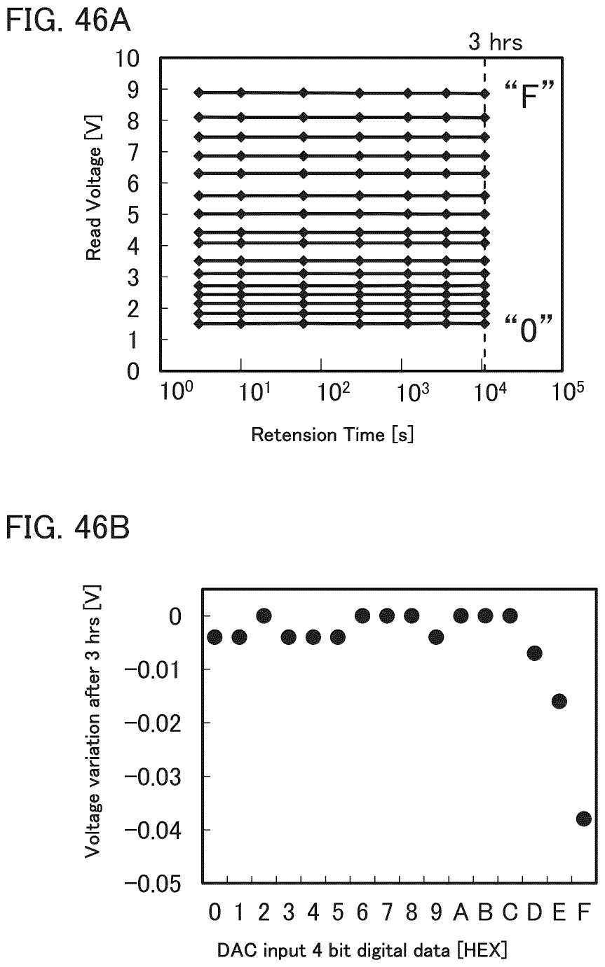

Next, the data retention characteristics of the fabricated memory device were measured. Specifically, the 16 write voltage levels used in the above measurement were written to memory cell MC included in the memory cell array MA of the memory device, and a variation in each read voltage over time at a room temperature was measured (FIG. 46A). A graph shown in FIG. 46A shows the variation amount in read voltage (Read Voltage) with respect to retention time (Retension Time), and this graph shows that the 16 voltage levels written to the memory cell MC are kept without variations over approximately 3 hours.

The graph in FIG. 46B shows the variation amount in the read voltage after three hours with respect to the write voltage (the DAC input 4 bit digital data [HEX]) to the memory cell MC. The graph in FIG. 46B confirms that the variation amount in read voltages (Voltage variation after 3 hrs [V]) ranged from 0 V to −0.05 V and the data was retained accurately even after three hours. The largest variation amount in this case was 0.038 V at the write voltage “F”.

In consideration of the above variation amount, the voltage range from −3σ s to 3σ when 3σ is maximum is 0.202+0.038=0.240 V, and the voltage between distributions in the range of “the mean value±3σ of the read voltages with respect to the adjacent write voltages” is 0.291−0.038=0.253 V. Even in consideration of the above variation amount, the voltage range from −3σ s to 3σ is lower than the voltage between the distributions within the range “the mean value±3σ of the read voltages with respect to the adjacent write voltages”; therefore, the number of write voltage levels that can be retained in the memory cell MC can be increased to more than 16. From the voltage range from −3σ s to 3σ and the voltage between the distributions within the range “the mean value±3σ of the read voltages with respect to the adjacent write voltages”, it can be estimated that the memory cell MC can retain 32 analog potential levels (i.e., equivalent to 5-bit digital data) for three hours.

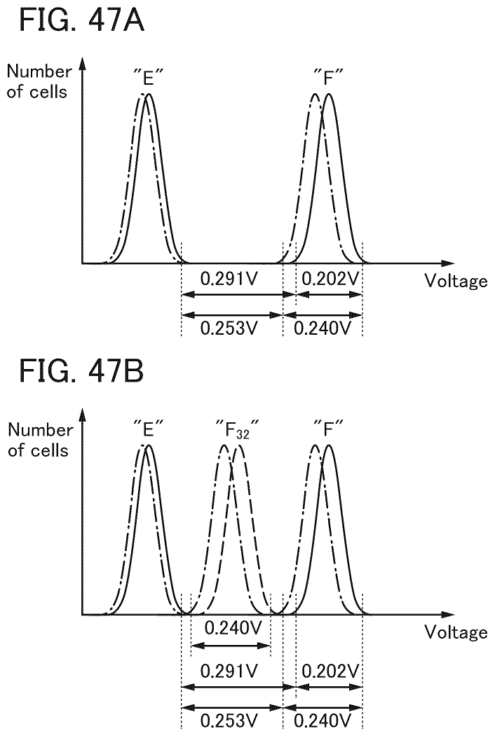

For example, FIG. 47A is a schematic diagram of the threshold voltage distributions at the write voltage “E” and the write voltage “F”. According to the above results, the voltage range from −3σ s to 3σ at the write voltage “F” after variation is 0.240 V, and the voltage between distributions in the range of “the mean value±3σ of the read voltages with respect to the adjacent write voltages” is 0.291−0.038=0.251 V; thus, the threshold voltage distribution at each of the write voltage “E” and the write voltage “F” is as shown in FIG. 47A. Note that in FIG. 47A, the voltage distribution after the variation is indicated by a dashed-dotted line.

Therefore, also in consideration of the above variation amount, as illustrated in FIG. 47B, a new level of write voltage can be provided between the write voltage “E” and the write voltage “F” as in FIG. 45B. FIG. 47B is a schematic diagram of the threshold voltage distribution in FIG. 47A, in which the new level of the write voltage “F₃₂” is provided between the write voltage “E” and the write voltage “F”. Note that in FIG. 45B, the write voltage “F₃₂” before the variation is denoted by a dashed line and the write voltage “F₃₂” after the variation is denoted by a dashed-dotted line. In FIG. 47B, the voltage range from −3σ s to 3σ at the write voltage “F₃₂” is 0.240 V.

The above-described results show that in the circuit structure illustrated in FIG. 41, when a transistor including CAAC-IGZO in its active layer is used as a writing transistor, 5-bit data can be processed per cell, and a memory device capable of retaining the data for three hours can be formed.

### REFERENCE NUMERALS

DEV: semiconductor device, DEVA: semiconductor device, ALYa: memory layer, ALYb: memory layer, ALYc: memory layer, MC: memory cell, MCa: memory cell, MCa[i,j]: memory cell, MCa[i,j−1]: memory cell, MCa[i,j+1]: memory cell, MCa[i+1,j+1]: memory cell, MCa[i+1,j]: memory cell, MCa[i+1,j−1]: memory cell, MCb: memory cell, MCb[i,j]: memory cell, MCb[i,j+1]: memory cell, MCc: memory cell, MCA[i,j]: memory cell, MCA[i,j+2]: memory cell, MCB[i,j+1]: memory cell, MCC[i,j]: memory cell, MCC[i,j+2]: memory cell, MCZ[i,j+1]: memory cell, WWLa[i]: wiring, WWLa[i+1]: wiring, WWLb[i]: wiring, WWLc[i]: wiring, RWLa[i]: wiring, RWLa[i+1]: wiring, RWLb[i]: wiring, RWLc[i]: wiring, CLa[i]: wiring, CLa[i+1]: wiring, CLb[i]: wiring, CLc[i]: wiring, WRBLa[j]: wiring, WRBLa[j+1]: wiring, WRBLa[j+2]: wiring, WRBLa[j+3]: wiring, WRBLb[j]: wiring, WRBLb[j+1]: wiring, WRBLb[j+2]: wiring, WRBLc[j+1]: wiring, WRBLc[j+3]: wiring, SLa[j]: wiring, SLa[j+1]: wiring, SLa[j+2]: wiring, SLb[j]: wiring, SLb[j+1]: wiring, SLc[j]: wiring, SLc[j+2]: wiring, WL[1]: wiring, WL[i]: wiring, WL[m]: wiring, BL[1]: wiring, BL[j]: wiring, BL[n]: wiring, WWL: wiring, WWL[m]: wiring, WWL[m+1]: wiring, WBL: wiring, WBL[n]: wiring, WBL[n+1]: wiring, RWL: wiring, RWL[m]: wiring, RWL[m+1]: wiring, RBL: wiring, RBL[n]: wiring, RBL[n+1]: wiring, CL: wiring, Vb1: wiring, Vb2: wiring, CD: circuit, RD: circuit, RS: circuit, ROC: reading circuit, OP: operational amplifier, M1: transistor, M2: transistor, M3: transistor, M11: transistor, M12: transistor, M13: transistor, M21: transistor, M22: transistor, M23: transistor, C1: capacitor, C11: capacitor, FN: node, PLa: opening, PLb: opening, PLc: opening, PLd: opening, PLe: opening, 10: memory cell, 10[1,1]: memory cell, 10[m,1]: memory cell, 10[1,n]: memory cell, 10[m,n]: memory cell, 10[i,j]: memory cell, 22: PSW, 23: PSW, 31: peripheral circuit, 32: control circuit, 33: voltage generation circuit, 41: peripheral circuit, 42: row decoder, 43: row driver, 44: column decoder, 45: column driver, 46: sense amplifier, 47: input circuit, 48: output circuit, 50: driver circuit layer, 60_k: memory layer, 60_1: memory layer, 60_2: memory layer, 60_3: memory layer, 60_N: memory layer, 100: memory device, 122a: insulator, 122b: insulator, 122c: insulator, 124: insulator, 130: oxide, 130a: oxide, 130b: oxide, 142a: conductor, 142b: conductor, 142c: conductor, 142d: conductor, 142e: conductor, 142f: conductor, 142g: conductor, 153_0: insulator, 153_1: insulator, 153_2: insulator, 153_3: insulator, 153_4: insulator, 154_0: insulator, 154_1: insulator, 154_2: insulator, 154_3: insulator, 154_4: insulator, 157_3: opening, 157_5: opening, 158_2: opening, 158_3: opening, 158_4: opening, 159: opening, 160_0: conductor, 160_1: conductor, 160_2: conductor, 160_3: conductor, 160_4: conductor, 160a_1: conductor, 160a_2: conductor, 160a_3: conductor, 160a_4: conductor, 160b_1: conductor, 160b_2: conductor, 160b_3: conductor, 160b_4: conductor, 170_0: conductor, 170_1: conductor, 170_2: conductor, 170_3: conductor, 170_4: conductor, 170_5: conductor, 170a_1: conductor, 170a_2: conductor, 170a_3: conductor, 170a_4: conductor, 170a_5: conductor, 170b_1: conductor, 170b_2: conductor, 170b_3: conductor, 170b_4: conductor, 170b_5: conductor, 171_1: conductor, 171_3: conductor, 175: insulator, 180: insulator, 180_0: insulator, 301: insulator, 311: substrate, 313: semiconductor region, 314a: low-resistance region, 314b: low-resistance region, 315: insulator, 316: conductor, 320: insulator, 324: insulator, 326: insulator, 328: conductor, 330: conductor, 350: insulator, 352: insulator, 356: conductor, 357: insulator, 400: transistor, 700: electronic component, 710: semiconductor device, 711: mold, 712: land, 713: electrode pad, 714: wire, 715: driver circuit layer, 716: memory layer, 730: electronic component, 731: interposer, 732: package substrate, 735: semiconductor device, 5600: large computer, 5610: rack, 5620: computer, 5621: PC card, 5622: board, 5623: connection terminal, 5624: connection terminal, 5625: connection terminal, 5626: semiconductor device, 5627: semiconductor device, 5628: semiconductor device, 5629: connection terminal, 5630: motherboard, 5631: slot, 6500: electronic device, 6501: housing, 6502: display portion, 6503: power button, 6504: button, 6505: speaker, 6506: microphone, 6507: camera, 6508: light source, 6509: control device, 6600: electronic device, 6611: housing, 6612: keyboard, 6613: pointing device, 6614: external connection port, 6615: display portion, 6616: control device, 6800: artificial satellite, 6801: body, 6802: solar panel, 6803: antenna, 6804: planet, 6805: secondary battery, 6807: control device, 7000: storage system, 7001: host, 7001sb: server, 7002: storage control circuit, 7003: storage, 7003md: memory device, 7004: storage area network

1. A semiconductor device comprising:
a first insulator; and
a first layer over the first insulator,
wherein the first layer comprises:
a first oxide semiconductor over the first insulator;
a first conductor on a top surface and a side surface of the first oxide semiconductor and a top surface of the first insulator;
a second conductor on the top surface of the first oxide semiconductor;
a second insulator on the top surface of the first oxide semiconductor, the second insulator between the first conductor and the second conductor in a cross-sectional view;
a third conductor on a top surface of the second insulator;
a fourth conductor on the top surface of the first oxide semiconductor;
a third insulator on the top surface of the first oxide semiconductor, the third insulator between the second conductor and the fourth conductor in the cross-sectional view;
a fifth conductor on a top surface of the third insulator;
a sixth conductor on the top surface and the side surface of the first oxide semiconductor and the top surface of the first insulator;
a fourth insulator on the top surface of the first oxide semiconductor, the fourth insulator between the fourth conductor and the sixth conductor in the cross-sectional view;
a seventh conductor on a top surface of the fourth insulator;
a fifth insulator over a first region of the first conductor;
an eighth conductor over the fifth insulator; and
a ninth conductor over the second conductor, and
wherein the first region and the first insulator overlap each other and the first region and the first oxide semiconductor do not overlap each other.

2. The semiconductor device according to claim 1,
wherein the first layer further comprises:
a second oxide semiconductor over the first insulator;
a tenth conductor on a top surface and a side surface of the second oxide semiconductor and the top surface of the first insulator;
an eleventh conductor on the top surface of the second oxide semiconductor;
a sixth insulator on the top surface of the second oxide semiconductor, the sixth insulator between the tenth conductor and the eleventh conductor in the cross-sectional view;
a twelfth conductor over the sixth insulator; and
a thirteenth conductor over the first conductor and the twelfth conductor.

3. The semiconductor device according to claim 2, further comprising:
a seventh insulator over the first layer; and
a second layer over the seventh insulator,
wherein the second layer comprises a third oxide semiconductor, a fourteenth conductor and an eighth insulator,
wherein the third oxide semiconductor and each of the eighth conductor and the thirteenth conductor overlap each other,
wherein the eighth insulator is on a top surface of the third oxide semiconductor,
wherein the eighth insulator and the eighth conductor overlap each other, and
wherein the fourteenth conductor is over the eighth insulator.

4. The semiconductor device according to claim 3,
wherein each of the first oxide semiconductor, the second oxide semiconductor, and the third oxide semiconductor comprises one or more selected from indium, zinc and an element M, and
wherein the element M is one or more selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, cobalt, magnesium and antimony.

5. A memory device comprising:
the semiconductor device according to claim 1; and
a driver circuit,
wherein the first insulator is over the driver circuit.

6. An electronic device comprising:
the memory device according to claim 5; and
a housing.

7. A semiconductor device comprising:
a first insulator;
a first layer over the first insulator;
a second insulator over the first layer;
a second layer over the second insulator; and
a first conductor,
wherein each of the first layer and the second layer comprises a first oxide semiconductor, a second conductor, a third conductor, a fourth conductor, a fifth conductor, a sixth conductor, a seventh conductor, an eighth conductor, a ninth conductor, a tenth conductor, a fourth insulator, a fifth insulator, a sixth insulator and a seventh insulator,
wherein in each of the first layer and the second layer,
the second conductor comprises a first region on a top surface of the first oxide semiconductor, a second region on a side surface of the first oxide semiconductor, and a third region not overlapping the first oxide semiconductor;
the third conductor is on the top surface of the first oxide semiconductor;
the fourth insulator is on the top surface of the first oxide semiconductor;
the fourth insulator is between the second conductor and the third conductor in a cross-sectional view;
the fourth conductor is on a top surface of the fourth insulator;
the fifth conductor is on the top surface of the first oxide semiconductor;
the fifth insulator is on the top surface of the first oxide semiconductor;
the fifth insulator is between the third conductor and the fifth conductor in the cross-sectional view;
the sixth conductor is on a top surface of the fifth insulator;
the seventh conductor comprises a fourth region on the top surface of the first oxide semiconductor, a fifth region on the side surface of the first oxide semiconductor, and a sixth region not overlapping the first oxide semiconductor;
the sixth insulator is on the top surface of the first oxide semiconductor;
the sixth insulator is between the fifth conductor and the seventh conductor in the cross-sectional view;
the eighth conductor is on a top surface of the sixth insulator;
the seventh insulator is on a first surface of the seventh conductor;
a top surface of the seventh conductor comprises the first surface;
the first oxide semiconductor and the first surface of the seventh conductor do not overlap each other;
the ninth conductor is on a top surface of the seventh insulator; and
the tenth conductor is on a top surface of the fifth conductor,
wherein the second insulator comprises an opening,
wherein the first conductor is in the opening,
wherein the first conductor is on a top surface of the fourth conductor in the first layer, and
wherein a part of the seventh conductor in the second layer is on a top surface of the first conductor.

8. (canceled)

9. (canceled)

10. (canceled)

11. (canceled)

12. (canceled)

13. (canceled)

14. The semiconductor device according to claim 7, further comprising:
a third insulator over the second layer;
a third layer over the third insulator,
wherein each of the first layer, the second layer and the third layer comprises the first oxide semiconductor, the second conductor, the third conductor, the fourth conductor, the fifth conductor, the sixth conductor, the seventh conductor, the eighth conductor, the ninth conductor, the tenth conductor, the fourth insulator, the fifth insulator, the sixth insulator and the seventh insulator, and
wherein the ninth conductor in the second layer and the eighth conductor in the third layer overlap each other.

15. The semiconductor device according to claim 7,
wherein the first oxide semiconductor comprises one or more selected from indium, zinc, and an element M, and
wherein the element M is one or more selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, cobalt, magnesium and antimony.

16. A memory device comprising:
the semiconductor device according to claim 7; and
a driver circuit,
wherein the first insulator is over the driver circuit.

17. An electronic device comprising:
the memory device according to claim 16; and
a housing.

18. A semiconductor device comprising:
a first insulator;
a first layer over the first insulator;
a second insulator over the first layer;
a second layer over the second insulator; and
a first conductor,
wherein each of the first layer and the second layer comprises a first oxide semiconductor, a second conductor, a third conductor, a fourth conductor, a fifth conductor, a sixth conductor, a seventh conductor, an eighth conductor, a ninth conductor, a tenth conductor, a fourth insulator, a fifth insulator, a sixth insulator and a seventh insulator,
wherein in each of the first layer and the second layer,
the second conductor comprises a first region on a top surface of the first oxide semiconductor, a second region on a side surface of the first oxide semiconductor, and a third region not overlapping the first oxide semiconductor;
the third conductor is on the top surface of the first oxide semiconductor;
the fourth insulator is on the top surface of the first oxide semiconductor;
the fourth insulator is between the second conductor and the third conductor in a cross-sectional view;
the fourth conductor is on a top surface of the fourth insulator;
the fifth conductor is on the top surface of the first oxide semiconductor;
the fifth insulator is on the top surface of the first oxide semiconductor;
the fifth insulator is between the third conductor and the fifth conductor in the cross-sectional view;
the sixth conductor is on a top surface of the fifth insulator;
the seventh conductor comprises a fourth region on the top surface of the first oxide semiconductor, a fifth region on the side surface of the first oxide semiconductor, and a sixth region not overlapping the first oxide semiconductor;
the sixth insulator is on the top surface of the first oxide semiconductor;
the sixth insulator is between the fifth conductor and the seventh conductor in the cross-sectional view;
the eighth conductor is on a top surface of the sixth insulator;
the seventh insulator is on a first surface of the seventh conductor;
a top surface of the seventh conductor comprises the first surface;
the first oxide semiconductor and the first surface of the seventh conductor do not overlap each other;
the ninth conductor is on a top surface of the seventh insulator; and
the tenth conductor is on a top surface of the fifth conductor,
wherein the second insulator comprises an opening,
wherein the first conductor is in the opening,
wherein the first conductor is on a top surface of the sixth conductor in the first layer, and
wherein a part of the seventh conductor in the second layer is on a top surface of the first conductor.

19. The semiconductor device according to claim 18, further comprising:
a third insulator over the second layer;
a third layer over the third insulator,
wherein each of the first layer, the second layer and the third layer comprises the first oxide semiconductor, the second conductor, the third conductor, the fourth conductor, the fifth conductor, the sixth conductor, the seventh conductor, the eighth conductor, the ninth conductor, the tenth conductor, the fourth insulator, the fifth insulator, the sixth insulator and the seventh insulator, and
wherein the ninth conductor in the second layer and the eighth conductor in the third layer overlap each other.

20. The semiconductor device according to claim 18,
wherein the first oxide semiconductor comprises one or more selected from indium, zinc, and an element M, and
wherein the element M is one or more selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, cobalt, magnesium and antimony.

21. A memory device comprising:
the semiconductor device according to claim 18; and
a driver circuit,
wherein the first insulator is over the driver circuit.

22. An electronic device comprising:
the memory device according to claim 21; and
a housing.
